(19) United States
(12) Patent Application Publication
(10) Pub. No.: US 2006/0048809 A1
(43) Pub. Date: Mar. 9, 2006

(54) Thermoelectric devices with controlled current flow and related methods

(76) Inventor: O. Raif Onvural, Cary, NC (US)

Correspondence Address: FRANK J. PITA, 1413 CARYWOOD DRIVE, CARY, NC, 27513, US

(21) Appl. No.: 11/223,735

(22) Filed: Sep. 9, 2005

Related U.S. Application Data
(60) Provisional application No. 60/608,329, filed on Sep. 9, 2004.
(60) Provisional application No. 60/622,776, filed on Oct. 28, 2004.

(51) Int. Cl. H01L 35/30; H01L 35/28

(52) U.S. Cl. 136/212; 136/205

(57) ABSTRACT

Thermoelectric devices comprising at least a first conductive material, a first semiconductive material, a second conductive material, and a third conductive material. The second conductive material may be contacting, disposed within, or operably connected to the first semiconductive material. Semiconductive materials may be depleted, undoped, p-doped, or n-doped, nanotubes, nanowires, and others. Conductive materials may be metals, alloys, conductive materials, nanotubes, nanowires, and others. The effective electrical resistance between the first conductive material and the third conductive materials is reduced below the series electrical resistance of the first semiconductive material by design, reducing the associated Joule heating. Peltier cooling and Peltier heating counteract each other within the second conductive material as electrical current flows. Heat exchanged between the first conductive material and the third conductive material creates a temperature differential therebetween. Thermoelectric devices can reversibly heat or cool, and use the Seebeck effect to generate electrical power from thermal energy.

### CROSS REFERENCE TO RELATED APPLICATIONS

This patent application claims the benefit of U.S. provisional application Ser. No. 60/608,329 filed Sep. 9, 2004, the entire contents of which are incorporated by reference herein. Further, this patent application claims the benefit of U.S. provisional application Ser. No. 60/622,776 filed Oct. 28, 2004, the entire contents of which are incorporated by reference herein.

### FIELD OF THE INVENTION

The present invention generally relates to thermoelectric device technology based on the Peltier and Seebeck effects. More particularly, the present invention provides a class of thermoelectric devices with controlled electrical current flow that may be operated as thermoelectric coolers, thermoelectric heaters, or thermoelectric generators, and related methods.

### BACKGROUND OF THE INVENTION

Thermoelectric devices that can convert between electrical energy and thermal energy have been in existence since the early 19th century. Seebeck, a German physicist, created an electrical circuit loop containing two different metals joined at two junctions. Seebeck first discovered that voltage was generated in the loop if there was a temperature differential between the two junctions of those two different metals. This is known as the Seebeck effect wherein thermal energy differentials are used to create electrical energy. Subsequently, a French scientist named Peltier observed that a current flowing in a loop through a junction between two dissimilar conductors induced heating or cooling at the junction, depending on the direction of current flow. The other junction between two dissimilar conductors in the loop exhibited the opposite cooling or heating effect. This is known as the Peltier effect, which is the converse of the Seebeck effect. The Peltier effect transfers thermal energy or heat in response to electrical current flow through junctions between two dissimilar conductors. The direction of electrical current flow determines the direction of heat transfer in a Peltier device. Depending on the direction of current flow, the Peltier thermoelectric device can operate reversibly to provide cooling or heating.

Thermoelectric devices have been developed to take advantage of the Seebeck and Peltier effects. The Seebeck effect was exploited first in thermocouples used for temperature measurements and later used for electrical power generation. Peltier devices operate analogously to reversible heat pumps that can provide cooling or heating as needed. However, useful thermoelectric devices translating thermal energy and electrical energy were not possible until the early 1960s with the development of semiconductor thermocouple materials. These materials were found to produce stronger thermoelectric effects, especially in conjunction with conductors. The semiconductor revolution enabled thermoelectric devices to operate as very reliable albeit still relatively inefficient solid-state heat pumps.

Various hybrid materials and doped semiconductors were created and used seeking to improve efficiency. Superlattice materials were also developed with better conductivity and higher thermal resistance to support Peltier cooling. The CRC Handbook of Thermoelectrics and Thermoelectric Refrigeration by H. J. Goldsmid is a reference containing examples of some of these conventional thermoelectric materials, devices, and technology. Many efforts have been made to improve the efficiency of thermoelectric devices by developing new thermoelectric materials. However, the search for materials, which combine high electrical conductivity, high Seebeck coefficient and low thermal conductivity, did not result in any major breakthroughs. As a result, the efficiency of conventional thermoelectric devices still remains very low even despite all these efforts, especially when compared with the efficiency of other conventional refrigerators, air conditioners, compressors, heat pumps, and the like.

Higher performance semiconductor thermoelectric devices have been required to meet various temperature control needs. Accordingly, efforts were made to manufacture a semiconductor device of smaller size, higher density, and higher integration. As the size of the semiconductor device is made smaller, the amount of heat produced from the device creates problems since this heat had to be dissipated in increasingly smaller die areas. Further, the higher level of integration in these devices within smaller areas causes the hot and cold junctions to be relatively closer together such that thermal conduction problems can adversely affect the heat transfer capability of conventional semiconductor based thermoelectric devices. As such, this need has not been effectively met.

In addition, some thermoelectric devices originally had their electrical current path and their thermal conduction path in series between the hot and cold junctions. These devices operated poorly since the electrical path was thermally shorting the hot and cold junctions together and adding Joule heat. The efficiency of these thermoelectric devices was improved significantly by providing a series electrical path but a parallel thermal path between the hot and cold junctions, as is seen commonly today. Conventional thermoelectric devices still have problems interfacing the electrical path and the thermal path and providing thermal isolation between the hot and cold junctions. Resolving these problems would be advantageous.

Peltier cooling power increases linearly as a function of electrical current. However, Joule heating increases as a function of electrical current squared times the effective series resistance. For a given amount of current, Joule heating presents a formidable problem when trying to cool effectively. Unfortunately, most good electrical conductors are also good thermal conductors for heat transfers. Today's conventional thermoelectric cooling devices have not successfully managed Joule heating vis-à-vis Peltier cooling. A need exists for more effective cooling by managing counterproductive Joule heating.

Thermoelectric technology offers a clean, environmentally friendly, solid state cooling and heating alternative. However, these devices still have relatively low efficiencies in operation. A need exists for more efficient thermoelectric devices with higher Figures of Merit, ZT. Also, it would be advantageous to develop thermoelectric devices that use less exotic materials, less complex types of materials, or fewer types of materials. Further, a need exists to better increase effective Peltier cooling by reducing Joule heating created as current flows through a thermoelectric device. It would be advantageous to better manage the interactions between the thermal path and the electrical path, and to better isolate the hot and cold junctions in thermoelectric devices. As such, the possible applications for modern thermoelectric devices would greatly increase. All readers should note that this Background of the Invention is provided merely for purposes of appreciating the environment, and is not intended to limit the scope of the present invention as defined by the attached claims in any way.

### SUMMARY OF THE INVENTION

The present invention provides a number of embodiments related to thermoelectric technology. Some thermoelectric device embodiments and related method embodiments seeking to address at least some of the above needs while attempting to deliver one or more of the above advantages are provided. Embodiments related to methods of manufacturing and using thermoelectric devices are also included. In general, at least some embodiments of thermoelectric devices provided by the present invention can function interchangeably as coolers, heaters, and electrical generators. Further, embodiments related specifically to thermoelectric cooling devices, thermoelectric heating devices, and thermoelectric power generation devices are also described.

A number of embodiments of the present invention provide thermoelectric devices with controlled and/or guided electric current flow that can increase the effective Peltier cooling by reducing the associated Joule heating. In some embodiments of the present invention, thermoelectric devices are provided in which the effective electrical resistance of the semiconductive material disposed between the hot and cold junctions is reduced below the effective electrical resistance of semiconductive material. Differences in the effective resistances seen along the electrical current path between the hot and cold junctions may also be used to control or direct the current as desired through some thermoelectric device embodiments. In addition, designing the effective electrical and thermal resistances can help reduce Joule heating between the junctions. Further, designing the effective electrical and thermal resistances can be used to better manage the Peltier effect and help improve thermal isolation across a thermoelectric device. Some embodiments can combine electrical current from different sources or divide electric current flow at various points between the hot and cold junctions of a thermoelectric device, seeking to improve thermoelectric device performance. Other embodiments use a variety of types of materials, a variety of physical structures, a variety of thermal configurations, and a variety of electrical configurations in thermoelectric devices. Insulators, conductive segments, and semiconductive segments of thermoelectric devices can be designed to improve the overall thermoelectric operation of thermoelectric devices.

Several embodiments of the present invention provide thermoelectric devices that thermally isolate the hot and cold junctions. For example, this is possible by increasing the distance between the two junctions while reducing the Joule heating therein, by designing the desired thermal conductivity, by designing the desired electrical resistance, and the like. Thermally isolating the hot and cold junctions helps to counteract heat leakage that interferes with Peltier heat transfers between the junctions. Thermoelectric devices according to some embodiments provide intervening structures that allow Peltier heating and Peltier cooling to counteract each other between the hot and cold junctions. Other embodiments include thermoelectric devices containing a variety of intervening structures between the hot and cold junctions that can better support thermoelectric operation therein. While some thermoelectric device embodiments operate as Peltier coolers when electrically powered in one polarity, those embodiments are also operable as Peltier heaters reversibly when electrically powered in the opposite polarity. These thermoelectric device embodiments can also use the Seebeck effect to generate electrical power from ambient thermal energy.

Some embodiments provide a thermoelectric device with electrical current flowing therethrough. In one type of embodiments, the thermoelectric device comprises at least a first conductive material, a first semiconductive material, a second conductive material, and a third conductive material. In another type of embodiment, the thermoelectric device may also comprise a second semiconductive material and additional optional conductive materials. The semiconductive material segments used therein can be made from many types of materials. A variety of types of materials can be used for the conductive material segments as well. Further, the semiconductive materials can also be doped in various ways and can be depleted, undoped, p-doped, or n-doped. The first semiconductive material may be disposed adjacent to and contacting the first conductive material. In addition, the second conductive material may be disposed within, contacting, adjacent to, or operably connected the first semiconductive material. For embodiments without the second semiconductive material, the third conductive material may be disposed adjacent to and contacting the first semiconductive material. In embodiments comprising the second semiconductive material, it could be disposed adjacent to and contacting the second conductive material, the third conductive material, or both. Accordingly, the third conductive material may be disposed adjacent to and contacting the second semiconductive material in these cases.

For the above and other embodiments, the effective electrical resistance between the first conductive material and the third conductive materials can be controllably reduced below the effective series electrical resistances of the first semiconductive material and the second semiconductive material by design as electrical current flows through the conductive materials. Reducing the effective electrical resistance between the first conductive material and the third conductive material can produce correspondingly lower Joule heating therebetween. Thus, the associated Joule heating may be reduced between the first conductive material and the third conductive material as electrical current flows therebetween. In addition, the Peltier cooling and Peltier heating can counteract each other within the second conductive material or the like as electrical current flows therethrough. Thus, the effective Peltier cooling may be increased while Joule heating may be reduced when the thermoelectric device is operated in cooling mode. This is also the case when thermoelectric embodiments are operated as Peltier thermoelectric heaters or Seebeck thermoelectric power generators. Thus, heat can be exchanged between the first conductive material and the third conductive material creating a temperature differential between the first conductive material and the third conductive material as electrical current flows therebetween.

A further embodiment of the present invention provides two or more thermoelectric devices or thermoelectric elements similar to any of the previous embodiments within a thermoelectric assembly. As above, a number of types of materials can be used as conductive material segments and semiconductive material segments in these thermoelectric elements or devices. The semiconductive materials and conductive materials used between the first thermoelectric device and the second thermoelectric devices can be similar or different as desired. Further, the doping used between the first thermoelectric device and the second thermoelectric devices can be similar or different. For example, both thermoelectric devices could use p-doped semiconductive materials or n-doped semiconductive materials. Alternatively one thermoelectric device could use p-doping while the other thermoelectric device could use n-doping. In addition, the third conductive material of the first thermoelectric device and the first conductive material of the second thermoelectric device may be in electrical contact such that electrical current flows between the first thermoelectric device and the second thermoelectric device. Both thermoelectric devices can thus be combined in operation to transfer heat cumulatively. Thus, heat can be exchanged by the first thermoelectric device and the second thermoelectric device between their respective hot and cold junctions. Effective Peltier cooling may be increased while detrimental Joule heating may be reduced when the thermoelectric device is operated in Peltier cooling heat transfer mode. This is also the case when thermoelectric embodiments are operated as Peltier thermoelectric heaters or as Seebeck thermoelectric power generators. Both embodiments with and without the second semiconductive material are provided.

Some embodiments can have various numbers and types of material segments disposed between the hot and cold junctions in a thermoelectric device. Interleaved conductive and semiconductive materials can be designed and arranged in many ways between hot and cold junctions of embodiments. Many different combinations of conductive segments and semiconductive segments, including a large variety of materials and structures, can be used between the junctions. Some embodiments may have various numbers of alternating interleaved conductive materials adjoining semiconductive materials disposed between the opposite junctions in a thermoelectric element or thermoelectric device. Further, interleaved conductive and semiconductive materials, whether alternating or not, can be designed and arranged in many ways between the hot and cold junctions in various embodiments. Various embodiments of thermoelectric devices are provided that describe a several architectures and structures disposed between the conductive materials at the hot and cold junctions respectively. These architectures and structures may be used to reduce electrical resistance, increase thermal isolation, reduce Joule heating, allow Peltier heating and Peltier cooling to counteract each other, and the like.

A number of embodiments use nanotubes, nanowires, nanomaterials, superlattice materials, or other materials for the semiconductive material, conductive material, or for both. The semiconductive and conductive materials can be arranged in various configurations with respect to the direction of electrical current flow, such as in series, in parallel, or in combinations thereof in embodiments. The semiconductive and conductive materials can also be arranged in various configurations, angles, and configurations with respect to the direction of thermal energy flow between the hot and cold junctions. Further, the semiconductive and conductive materials can also be arranged in various configurations, angles, and configurations with respect to the direction of electrical current flow. Interleaved semiconductive material areas adjoining conductive material areas between the hot and cold junctions can help improve thermoelectric performance. These interleaved material areas serve to improve the cooling performance by creating more thermal separation and isolation between the hot and cold junctions. These interleaved areas or material segments can also be configured seeking to separate the electrical current flow path from the thermal energy flow path. Further, the interleaved material areas can allow localized Peltier cooling and Peltier heating to counteract within the interleaved areas between the hot and cold thermal junctions. Also, the intervening material areas may help reduce the associated Joule heating as electrical current flows through the device. Embodiments are provided in which the electrical current path between the hot and cold junctions is separated from the thermal conduction path between the hot and cold junctions through the intervening conductive and semiconductive areas. For example, one way this may be accomplished by providing different effective lengths for the electrical current path and the thermal conduction path between the hot and cold junctions of a thermoelectric device. The electrical current path may be guided through a different path than the path through which heat is conducted by design. A set of embodiments provides a current path shorter than the thermal path, while other embodiments provide a current path longer than the thermal path. In addition, differences in thermal conductivity, electrical resistance, both, or the like in the intervening areas can be used to improve thermoelectric operation by design.

Additional embodiments of thermoelectric devices are provided including means for separating the electrical current path creating Peltier heat exchanges that provide Peltier heating or cooling from the thermal path conducting transferred heat between the hot and cold junctions. Some embodiments include means for conducting electricity and means for semiconducting electricity. Embodiments including means for increasing the distance between the hot and cold junctions while reducing the associated Joule heating occurring between the hot and cold junctions as electrical current flows therebetween are also provided. Further embodiments include means for controllably reducing the effective electrical resistance below that of means for semiconducting electricity disposed between the hot and cold junctions. In addition, some embodiments provide means for controllably counteracting Peltier heating by Peltier cooling between the junctions. Some embodiments of thermoelectric devices provide means for isolating the hot and cold junctions created by Peltier heat exchanges that provide heating or cooling when electrical current flows through the thermoelectric device or through the means for reducing the effective electrical resistance.

Additional embodiments relate to methods of manufacturing and methods of using various thermoelectric device embodiments. Some embodiments describe various methods of productively using thermoelectric devices whether they be in cooling mode, heating mode, or electrical power generation mode. Other embodiments of the present invention provide related methods for manufacturing thermoelectric devices of various embodiments. Among the related methods described are methods for making thermoelectric devices constructed as integrated circuit devices and thermoelectric devices that are assembled from integrated circuit devices and components. The Summary of the Invention is provided herein as an overview of the invention and is not intended to limit the scope of the present invention as defined by the attached claims in any way. Other aspects and features of the present invention will become apparent to those of ordinary skill in the art, upon review of the following description of specific embodiments of the present invention in conjunction with the accompanying figures.

### BRIEF DESCRIPTION OF THE FIGURES

FIGS. 1(a) and 1(b) are diagrams illustrating two high level views of a conventional thermoelectric device and its construction.

FIG. 2 is a diagram illustrating an operational view of a conventional thermoelectric device.

FIG. 3 is a block diagram illustrating the operation of a conventional single stage thermoelectric device.

FIGS. 4(a), 4(b), 4(c), and 4(d) are diagrams illustrating different examples of using angle θ to control the performance of a thermal leg according to some embodiments of the present invention.

FIGS. 5(a) and 5(b) are diagrams illustrating some examples of electric fields operating in a thermal leg, according to some embodiments of the present invention.

FIG. 6 is a diagram illustrating an example of the superposition of electric forces.

FIGS. 7(a), 7(b), and 7(c) illustrate electric field examples with different thermoelectric device structures, according to some embodiments of the present invention.

FIG. 8 is a diagram illustrating an example structure of thermal legs according to some thermoelectric device embodiments of the present invention.

FIGS. 9(a), 9(b), 9(c), and 9(d) are diagrams illustrating some thermoelectric device structure embodiments and thermoelectric thermal leg embodiments according to the present invention.

FIG. 10 is a diagram illustrating an example structure of thermal legs according to some thermoelectric device embodiments of the present invention.

FIGS. 11(a) and 11(b) are diagrams of example thermal leg embodiments and the electrical forces therein according to some embodiments of the present invention.

FIG. 12 is a diagram illustrating an example of current guidance through a series of thermoelectric legs according to some embodiments of the present invention.

FIG. 13 is a diagram illustrating an example of current guidance through thermoelectric legs using different semiconductive materials according to some embodiments of the present invention.

FIG. 14 is a diagram illustrating an example of current guidance through thermoelectric legs using only p-type semiconductive materials according to some embodiments of the present invention.

FIG. 15 is a diagram illustrating an example of current guidance through thermoelectric legs using only n-type semiconductive materials according to some embodiments of the present invention.

FIG. 16 is a diagram illustrating an example of a thermoelectric device having current summing in a thermal leg, according to some embodiments of the present invention.

FIGS. 17(a) and 17(b) are diagrams illustrating possible differences in the possible separation within thermoelectric legs according to some thermoelectric device embodiments of the present invention.

FIG. 18 is a diagram illustrating an example of a thermoelectric leg using nanomaterials according to some embodiments of the present invention.

FIGS. 19(a), 19(b), 19(c), and 19(d) are diagrams illustrating some thermoelectric device structure embodiments and thermoelectric thermal leg embodiments according to the present invention.

FIGS. 20(a), 20(b), and 20(c) are diagrams illustrating some thermoelectric device structure embodiments and thermoelectric thermal leg embodiments according to the present invention.

FIGS. 21(a), 21(b), and 21(c) are diagrams illustrating some thermoelectric device structure embodiments and thermoelectric thermal leg embodiments according to the present invention.

FIGS. 22(a), 22(b), and 22(c) are diagrams illustrating some thermoelectric device structure embodiments and thermoelectric thermal leg embodiments according to the present invention.

FIGS. 23(a), 23(b), and 23(c) are diagrams illustrating some thermoelectric device structure embodiments and thermoelectric thermal leg embodiments according to the present invention.

FIGS. 24(a), 24(b), and 24(c) are diagrams illustrating some thermoelectric device structure embodiments and thermoelectric thermal leg embodiments according to the present invention.

The Brief Description of the Figures above and the following Detailed Description of the Invention are provided for illustrative and descriptive purposes only, and neither is meant to limit the scope of the present invention as defined by the attached claims in any way.

### DETAILED DESCRIPTION OF THE INVENTION

The present invention now will be described more fully hereinafter with reference to the accompanying illustrative figures, in which various embodiments of the invention are shown. This invention may, however, be embodied in many different forms and should not be construed as limited to the embodiments set forth herein. Rather, these embodiments are provided so that this disclosure of the present invention will be thorough and complete, and will fully teach and describe the invention to those skilled in the art. Although specific terms are employed herein, they are used in a generic and descriptive sense only and not for purposes of limiting the scope of the present invention as defined by the attached claims in any way. Some terminology may be defined herein and used to describe forthcoming embodiments of the present invention, in order to teach the present invention to those skilled in the art. Terms not described explicitly in this disclosure should be construed as they would by those skilled in the art. Unless otherwise expressly limited, all terms used herein including technical and scientific terms, whether defined herein or not, are intended to have the broadest possible meaning as understood by one of ordinary skill in the art. It will be further understood that terms not explicitly defined herein should be interpreted as having the broadest possible meaning or meanings found in commonly used dictionaries, consistent with their meaning in the context of the relevant art. Some terms will be explicitly defined herein and used to describe embodiments of the present invention to those skilled in the art. Terms defined explicitly herein should be interpreted as the broader of their definition herein and their dictionary meanings. These defined terms should accordingly be construed according to their broadest possible meaning to skilled artisans in this field of technology.

The Figures are provided for illustrative purposes for teaching purposes and to assist in understanding the present invention, and should not be viewed as precision blueprints or perfectly scaled drawings. In the drawings provided, the dimensions of features or regions may be exaggerated for clarity, readability, or other reasons. Features found in the Figures may not be exactly to scale. The Figures are provided to show example embodiments of the present invention. Thus, embodiments of the present invention should not be construed as limited solely to the particular Figure or Figures illustrated herein but may include variations and deviations from many sources. Like numbers refer to like features or elements throughout. As used herein the term “and/or” includes any and all combinations of one or more of the associated listed items. Further, as used herein the term “at least” includes the number specified plus more than the number specified, unless explicitly limited otherwise.

As used herein, the singular forms “a”, “an” and “the” are intended to include the plural forms as well, unless the context clearly indicates otherwise. It will be further understood that the terms “comprises” or “comprising,” when used in this specification, specify the presence of stated features, steps, operations, elements, and/or components, but do not preclude the presence of one or more additional features, steps, operations, elements, components, and/or combinations thereof. Moreover, terms such as “horizontal”, “vertical” and “perpendicular” indicate general directions or relationships rather than precise 0° or 90° orientations. Ranges and angles are approximate and are provided merely to teach the invention.

Review of Thermoelectric Technology

Thermoelectric technology is based on the Peltier effect and the Seebeck effect, which were discovered in the early 19th century. The Peltier effect occurs when an electrical current flows through two dissimilar conductors. Depending on the material properties of the conductors and the direction of current flow, the junction of the two conductors will either absorb or release thermal energy. Similarly, the Seebeck effect occurs when a temperature gradient is applied to two dissimilar conductors which creates and electrical potential and causes an electrical current to flow.

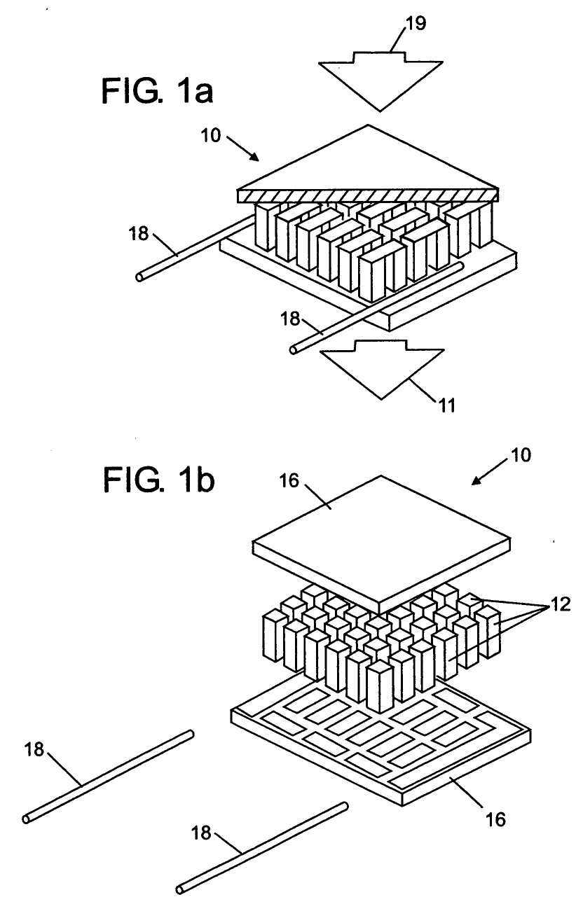

Thermoelectric devices can exploit the Peltier effect and be used for reversibly transferring thermal energy. As such, these devices can provide heating or cooling as electrical current flows through the devices. Today, these thermoelectric devices are constructed using semiconductors and conductors in configurations that utilize the Peltier effect. Some high level views of a typical thermoelectric device 10 are shown in FIGS. 1(a) and 1(b). Thermoelectric devices can be used as Peltier mode devices for transferring heat or thermal energy from one side of the device to the other side of the device. The thermoelectric devices shown in FIGS. 1(a) and 1(b) are constructed by using semiconductors and conductors that produce the Peltier effect. Typically a Peltier device is constructed by using a number of semiconductor pellets in an assembly. Each individual semiconductor pellet such as 12 in FIG. 1(b) is soldered to electrically-conductive material such as conductors 14 shown in FIGS. 1(a) and 1(b). Many metals can be used as conductors, such as plated copper or the like. The Peltier effect occurs between the semiconductor pellet legs and the conductors. The entire pellet and conductor assembly can be interconnected to leading wires such as 18 shown in FIGS. 1(a) and 1(b).

A typical thermoelectric device or module is constructed by electrically connecting a matrix of thermoelectric elements, such as a semiconductor pellet and at least two conductors between a pair of electrically insulating substrates, such as 16 shown in FIG. 1(b). In some cases, the substrates can be constructed from ceramic or other suitable thermoelectric substrate materials known to skilled artisans. The combination of the semiconductor pellet and its associated conductor is also known as a dice by those skilled in the art. In operation, the thermoelectric device creates both a hot-side substrate 11 and a cool-side substrate 19 by transferring thermal energy from one substrate to another as electrical current flows through the device. A typical thermoelectric device requires electrical DC power in operation to produce a net current flow through the thermoelectric elements in one direction. The direction of the current flow determines the direction of heat transfer across the thermoelectric elements. The direction of net, non-zero current flow through the thermoelectric elements determines the function of the thermoelectric device as either a cooler or heater. For example, in FIG. 1(a), driving a current through the device as shown between the plus and minus leading wires will move thermal energy from cold side 19 to hot side 11 such that heat is transferred across the thermoelectric device 10. The thermoelectric module 10 can typically be placed between a load and a sink such as liquid plates, surface plates, or convection heat sinks. The most common type of thermoelectric element is composed of a bismuth-tellurium (Bi₂ Te₃) alloy, for example. The most common type of substrate is alumina (96%), for instance. These materials typically range in thickness from about 0.010 inches (0.25 mm) to about 0.040 inches (1.0 mm).

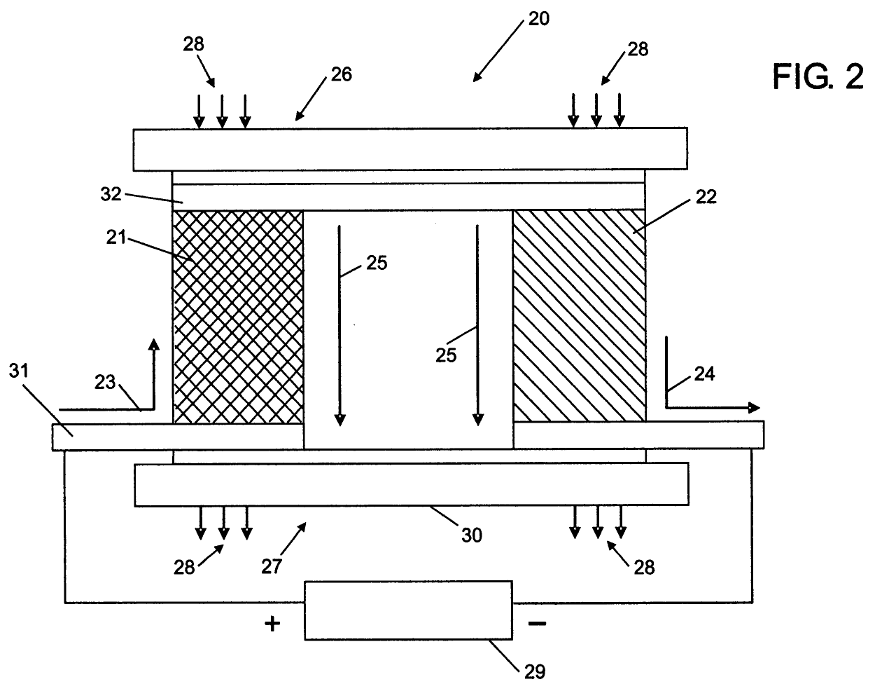

FIG. 2 is used to further describe the operation of a conventional thermoelectric device. A typical thermoelectric device such as 20 is built using n-type semiconductors such as 21 and p-type semiconductors such as 22 (usually Bismuth Telluride) material. Heat or thermal energy 25 is transferred in the direction of charge carrier movement (holes in p-type semiconductors travel as shown by 23 and electrons in n-type semiconductors as shown by 24) throughout the electrical circuit. That is, the charge carriers always travel from the cold side 26 to the hot side 27, and heat collected at the cold side 28 is radiated at the hot side 28 typically through a heat sink such as 30. A leg of a thermoelectric device is defined as the components disposed between the cold side 26 and the hot side 27 comprising one thermal path transferring thermal energy between the hot side and the cold side. As such, a leg typically contains semiconductor material, such as 21 or 22 disposed between two conductive contacts, such as between metal contacts 31 and 32. In an n-type semiconductor material 21, the electrons are the charge carriers employed to move heat using the Peltier effect. Electrons are repelled by the negative pole and attracted by the positive pole of the power supply. With the electrons flowing through the n-type material from bottom to top, heat is absorbed at the bottom junction and actively transferred to the top junction. In a p-type semiconductor material 22 the charge carriers in the material are positive (known as holes). These holes enhance the electrical conductivity of the p-type material, allowing electrons to flow more freely through the material when a voltage is applied. Positive charge carriers are repelled by the positive pole of the DC supply and attracted to the negative pole; thus hole current flows in a direction opposite to that of electron flow. Because it is the charge carriers inherent in the material which convey the heat through the conductor, use of the p-type material results in heat being drawn toward the negative pole of the power supply and away from the positive pole. Use of n-type material results in heat being drawn towards the positive pole of the power supply and away from the negative pole. In addition, as current flows through the device Joule heating is generated due to electrical resistance in the current path, such as through the conductors and semiconductors. This extra heat can counteract the desired transfer of thermal energy from the cold side to the hot side. When operated in Peltier heat transfer mode, the thermoelectric device is powered by electrical device 29 such that it can transfer thermal energy between the cold side 26 and the hot side 27. When operated in Seebeck power generation mode, heat transferred between the cold side 26 and the hot side 27 the thermoelectric device generates electrical power to drive electrical device 29.

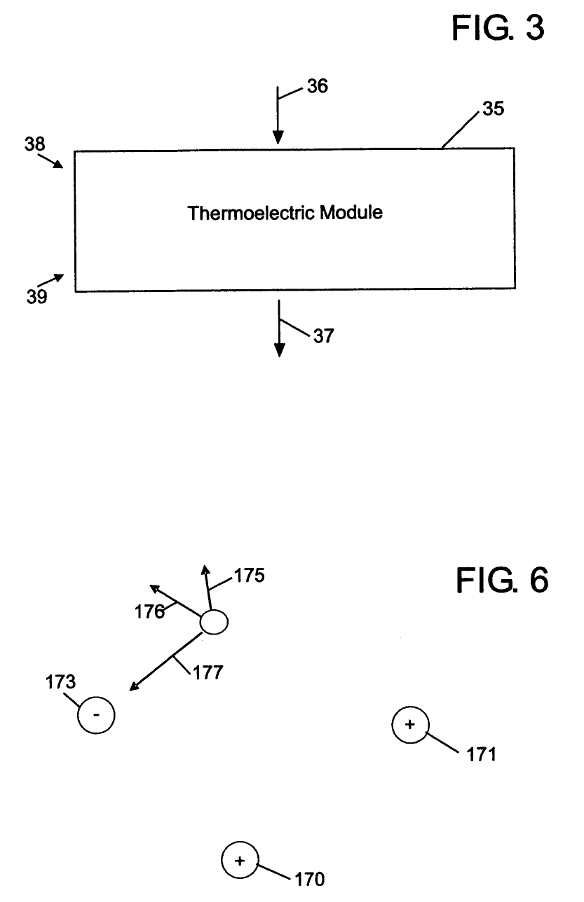

FIG. 3 three illustrates a functional block diagram of a thermoelectric device 35. In functional “black box” terms, the thermoelectric device receives thermal input Q_{c} from the cold side, such as shown by 36 in the Figure. The cold side is at temperature T_{c} such as 38 shown in the Figure, and the hot side is at temperature T_{c} such as 39 shown in the Figure. The thermoelectric device also emits thermal output Qₕ from the cold side, such as shown by 36 in the Figure. Several parameters determine the operation of a thermoelectric device:
m: The number of distinct semiconductor pairs (n-type and p-type) in the device
I: The input current to the device (in amperes)
Vᵢₙ: The input voltage to the device (in volts)
Tₕ: The hot side temperature (K)
T_{c}: The cold side temperature (K)
Q_{c}: The heat input to the device (W)
Qₕ: The heat pumped by the device (W)
Sₙₚ: Seebeck coefficient when the current flows from n-type material to p-type material
Sₚₙ: Seebeck coefficient when the current flows from p-type material to n-type material
S_{T}: Total Seebeck coefficient (S_{T}=Sₙₚ=−Sₚₙ)
Kₙ: Thermal conduction in n-type semiconductor material
Kₚ: Thermal conduction in p-type semiconductor material
Rₙ: Electrical resistance of n-type semiconductor material
Rₚ: Electrical resistance of p-type semiconductor material

Let us better understand the interaction of these parameters in thermoelectric operation. The Resistance of a material, R, is defined as follows:
Rₘₐₜ=resistivity of the material×length of the material/cross sectional area of the material
Contact resistance is the resistance between the semiconductor material, either n-type or p-type semiconductor material, and the associated conductive contacts (commonly made from metal such as copper or aluminum). Contact resistance is determined as follows:
R_{c}=resistivity/cross sectional area of the contact
Hence, the total electrical resistance of a leg R_{T}, a semiconductor material disposed between two metal contacts, is:
R_{T}=2×Rₘₑₜₐₗ+R_{semiconductor}+2×R_{contact}
Similarly, the thermal leakage in a leg from its hot semiconductor-contact junction to its cold semiconductor-contact junction (thermal conduction) depends on the thermal properties of the semiconductor material as follows:

$${K}_{leg} = \frac{cross sectional area}{\begin{matrix}thermal conductivity of semiconductor \times \\ length between hot and cold junctions\end{matrix}}$$

Given the above, the cooling power of a thermoelectric device, or the amount of thermal energy transferred between the hot and cold junctions in Peltier mode, for a given applied electric current I is as follows:
Q_{c}=m{(Sₙₚ×T_{c}×I)−(0.5×I²×(Rₙ+Rₚ))−(Kₙ+Kₚ)×ΔT}
where ΔT is the temperature difference between the hot and cold junctions, i.e., ΔT=Tₕ−T_{c}.

As seen from this formula, the Peltier cooling power is directly proportional to the number of legs, m and the Seebeck constant Sₙₚ. However, the electrical current flowing through the thermoelectric leg used in Peltier mode also generates heat. The Joulian heating effect is proportional to the square of the current times the total resistance of the current path. However, the Peltier cooling effect is proportional to the current. Therefore, as the current increases, the Joule heating dominates the Peltier cooling and causes a loss in net cooling. This cut-off defines the maximum current Iₘₐₓ for the module for a given set of resistance values, since it would not be operating as an effective Peltier device beyond this point.
Iₘₐₓ is calculated by calculating the derivative of Q_{c} with respect to current I which gives:

$$\frac{ⅆ {Q}_{c}}{ⅆ I} = m \times ( {S}_{np} \times {T}_{c} - I \times ( {R}_{n} + {R}_{p} ) )$$

Equating dQ_{c}/dI to zero, we have:

$${I}_{max} = \frac{{S}_{np} \times {T}_{c}}{{R}_{n} + {R}_{p}}$$

Note that Iₘₐₓ is inversely proportional to the resistance of the thermoelectric legs. Usually, the semiconductor portion of a thermoelectric leg has most of the electrical resistance. The resistance of the semiconductor portion of the leg decreases as the length of the semiconductor leg decreases, as the cross sectional area increases, or both. It is noted that the thermal conduction behavior changes opposite to the electrical resistance behavior as we modify the geometry of the semiconductor portion of a leg. In particular, the thermal conductivity increases as the length of the semiconductor leg between the cold junction and hot junction increases, as the cross sectional area decreases, or both.

The Figure of Merit, ZT, of a material at a given temperature T is used to describe the material's performance or effectiveness when used in a thermoelectric device as follows:

$$ZT = \frac{{S}^{2} T}{RK}$$

where S is the Seebeck coefficient of the material, R is the electrical resistance of the material, K is the thermal conductance of the material, and T is the temperature. It is noted that in deriving the figure of merit, it is assumed that the difference between the hot and cold junctions is the length used in their respective calculations. The higher the Figure of Merit, the better the performance of a thermoelectric device. Some skilled in the art believe that a Figure of Merit, ZT equal to 1.0 may be a limiting condition common to all thermoelectric materials. Theoretical attempts to determine such a boundary condition for the dimensionless figure of merit ZT have been unsuccessful so far. There is no known material with ZT>1.0 at any temperature T. However, ZT needs to be much greater than 1.0 in order for thermoelectric devices to be more widely used in commercial applications. There is no known technological reason why ZT cannot be greater than 1.0.

Based on the analysis above, the following observations can be made. First, the cooling power increases as the Seebeck coefficient of the material used to construct thermal legs increases. Second, p-type and n-type silicon have Seebeck coefficients higher than most other materials. Third, the cooling power increases as the number of thermal legs increases. All of these points suggest building thermoelectric devices using a CMOS or existing semiconductor process using standard p-type and n-type silicon semiconductor materials. As an example, if the width of a thermal leg is 2 microns including the distance between two thermal legs, there could be 5,000 thermal legs in one cm width. In contrast, the current thermoelectric devices usually place 127 thermal legs in one square inch since they use the discrete pellet approach. Hence, it should be possible to create thermoelectric devices with more or different thermal legs and correspondingly better Peltier heat transfer performance. Attempts have been made to build integrated circuit based thermoelectric devices. Some of these devices were referred to as micro-Peltier devices.

However, these integrated thermoelectric devices produced very little heat transfer capability and electrical power generation capability. This may be due to the fact that these devices were built similarly to commercially available devices. The distance between hot and cold junctions in currently available commercial devices is approximately 1 mm. As the distance between the hot and cold junctions is reduced in these integrated thermoelectric devices, such as to lengths in microns or thereabouts, unwanted thermal leakage from the hot junction back to the cold junction may become too great to obtain good effective thermal heat transfer performance. As thermoelectric devices are integrated and the hot and cold sides are brought closer together, thermal conduction between the hot and cold junctions presents a problem. On the other hand, when the distance between the hot and cold junctions are increased to reduce the negative impact of unwanted thermal leakage, increased Joule heating due to the higher electrical resistance may become to great to obtain good effective thermal heat transfer performance. In particular, the performance of known silicon based micro-Peltier devices demonstrate a Figure of Merit ZT of around 0.03 at room temperature, which is considerably lower than the Figure of Merit of 0.30 for commercially available Bismuth Telluride based thermoelectric devices. As such, attempts to leverage integrated circuit technologies as applied to thermoelectric devices have not been very successful so far.

An article by Buist and Lau (at http://www.tetech.com/publications/pubs/ICT96RJB.pdf) titled “THEORETICAL ANALYSIS OF THERMOELECTRIC COOLING PERFORMANCE ENHANCEMENT VIA THERMAL AND ELECTRICAL PULSING” investigated the potential cooling advantages of operating a Thermoelectric cooler using pulsed currents provides valuable insights. It states “The cooling enhancement is by virtue of the fact that Peltier cooling is a surface effect and extremely concentrated at the cold junction, whereas, Joule heating is a volume effect and is distributed throughout the volume of the TE pellet. As such, most of the Joule heat takes a longer time to reach the cold plate than the Peltier cooling effect. This phenomenon is theoretically demonstrated by applying a high-current pulse after the minimum steady-state cold plate temperature has been established.” This article supports the proposition that it may be possible to leverage the faster operation of Peltier cooling acting on a surface against the slower effect of Joule heating acting on a volume. This phenomenon makes it easier to have the cooling counteract and/or effectively cancel heating along the span between the hot and cold junctions, such as is provided by the alternating resistance reducer/semiconductive interleaved materials. These serve to increase, control, and direct the electrical current so as to improve Peltier heating while counteracting the effect of Joule heating such that better thermal isolation between the hot and cold junctions is possible. This article supports the premise that Peltier cooling can help counteract Joule heating, and can help isolate the hot and cold junctions of a thermoelectric device through resistance reducers or the like.

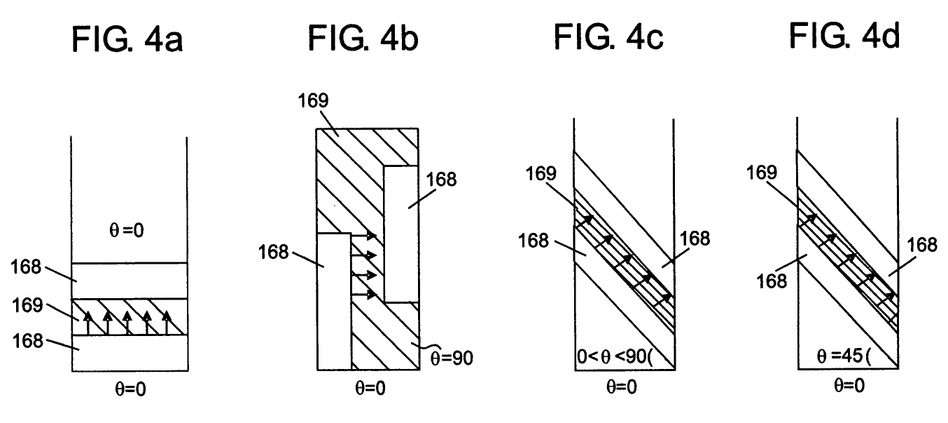

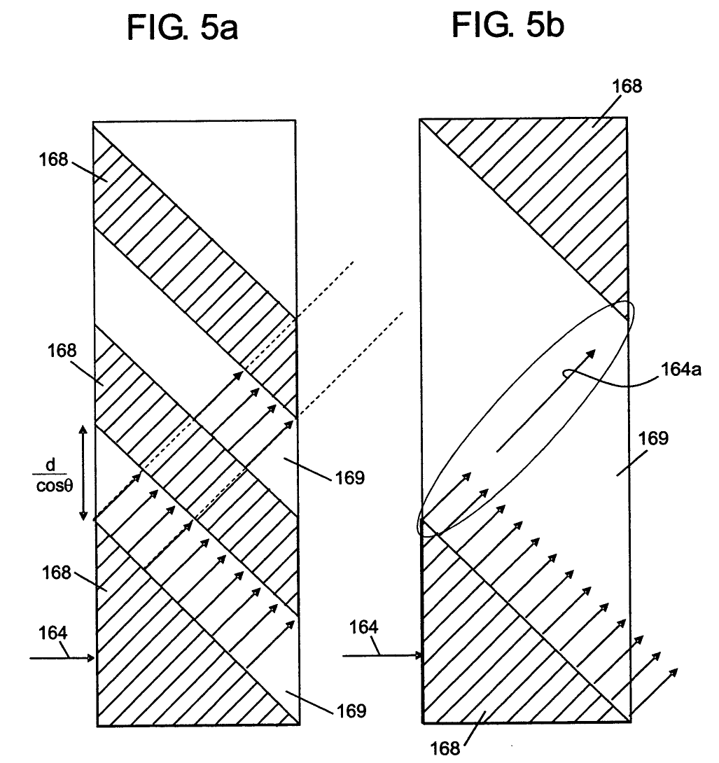

Some thermoelectric device embodiments can be constructed to have a number of thermal legs depending on the width of a leg and the width of the insulator between legs, if any. Referring now to FIG. 4, we note that it is possible to arrange interleaved conductive materials/semiconductive materials within a thermal leg in a number of ways. For instance, placing conductive material 168 and semiconductive material 169 at an angle θ as shown in 4(a) allows increasing the distance between the hot and cold junctions while reducing the resistances of all intervening conductive materials. The conductive material segment 168 above 169 can provide this resistance reducing function as will be described. In particular, the distance between two resistance reducers or between a junction and resistance reducer can be reduced to as little as one lithography distance. For θ=0°, the electrical current flows through the conductive material and semiconductive material in the direction of θ=90° as shown. Furthermore, the resistances of each material can be reduced by increasing the area the current leaves/enters a material. In doing so, however, the current is required to move from one junction to another while increasing the contact surfaces. When θ=0°, the current flow from one resistance reducer to the next is uniformly distributed over the material and uses 100% of the surface. However, as the width of a thermal leg determines the number of thermal legs per unit length, it becomes restricted to a small length. This in turn causes both the electrical and thermal resistances to be very high thereby reducing the cooling performance of the device. If θ=90° as shown in 4(b), then the overlap region between two resistance reducers can be a design parameter to manipulate. The two parameters to trade off are the size of the overlap region and the amount of electrical current flowing from one junction to another. As an example, if the overlap region is 100% then the current moves only horizontally. As the overlap region decreases, the resistances increase. The resistances can be reduced to acceptable levels by increasing the length of a thermal leg. It is noted, however, that as the number of vertical resistance reducers increases the width of a leg increases, thereby reducing the total number of thermal legs possible per unit length. If 0<θ<90 as shown in 4(c), the overlap area between two consecutive resistance reducers is as follows:

$$overlap area = \frac{width of thermal leg}{cos θ} - d tan θ$$

where d is the distance between two resistance reducers (or between a junction and a resistance reducer). It is noted that width of thermal leg divided by cos θ is the width of a resistance reducer. It is noted that we assume the current is uniformly distributed at the source resistance reducer. Let us consider three consecutive resistance reducers (or any combination with one or more junctions) as illustrated in FIGS. 5(a) and 5(b). FIG. 5(a) shows a thermal leg containing conductive material areas 168 interleaved with semiconductive material areas 169. Electrical current 164 enters the bottom junction and flows vertically up as shown. When the current enters the lower junction such as 168 at the bottom, the electric charge distribution at the junction is uniformly distributed. The electrical field generated is perpendicular to its contact surface as shown by the lower set of arrows. However, the overlap area is smaller than its width by “d tan θ” as defined above, which is the contact surface through which the current enters the next resistance reducer. As such, the electric field and the resulting current flow 164(a) as shown in FIG. 5(b). This can also be seen by considering the distance between the two resistance reducers, which can be as large as d/cos θ, whereas it is equal to d over the overlap area. In particular, the current flow in this structure when 0<θ<90 is such that the overlap area decreases as the distance between the hot and cold junctions increase, which means the resistance increases as the current flows through resistance reducers. Note that acute angles between zero and 90 degrees, both positive and negative angles with respect to the horizontal axis are possible. Further, obtuse angles, again both positive and negative angles with respect to the horizontal axis are possible. As yet another example of the many angles that are possible, FIG. 4(d) shows the case where θ=45°.

Next, we will describe one method to address this problem, as illustrated in FIG. 6. This Figure is used to show the superposition of electrical forces. The design approach used is based on creating different electrical fields to guide the current from one material to the next, as it flows from one junction to another in a thermal leg. For presentation purposes, consider the three point charges (two positive charges q1 or 171 and q2 or 172 and one negative charge 173 or q3) and a positive test charge, 174 or q. The total force (electric field) exerted by Fq1 171, Fq2 172, and Fq3 173 on Fq 174 is the vector sum of the individual forces 175, 176, and 177 as shown in the Figure. In this example, the sum of individual forces is given by:

$$\overline{F} = {\overline{F}}_{q1q} + {\overline{F}}_{q2q} + {\overline{F}}_{q3q} = \frac{q}{4 {πɛ}_{0}} ( \frac{{q}_{1}}{{r}_{1}^{2}} {\hat{r}}_{1} + \frac{{q}_{2}}{{r}_{2}^{2}} {\hat{r}}_{2} + \frac{{q}_{3}}{{r}_{3}^{2}} {\hat{r}}_{3} )$$

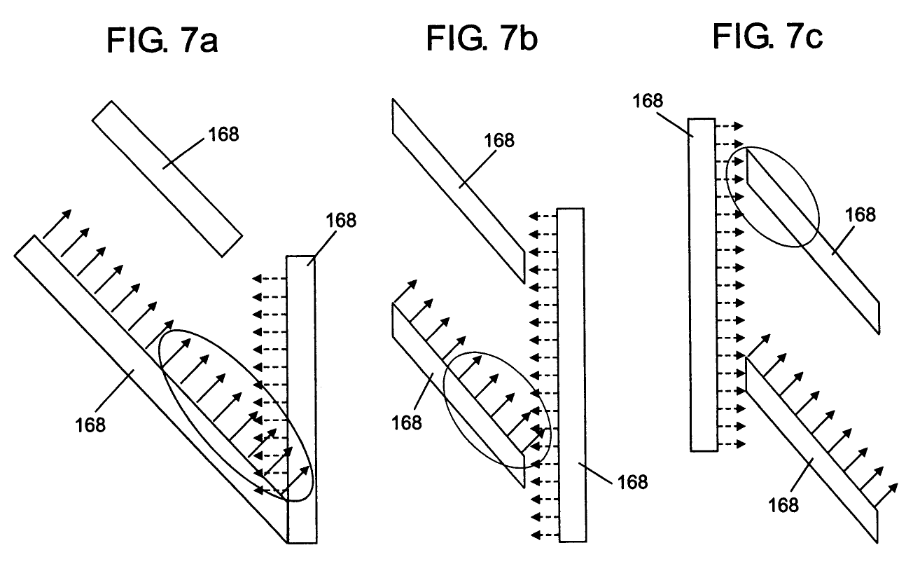

Next, we will use this sum of forces property of the electric field to guide the current across a thermal leg. In particular, consider the example electric fields illustrated in FIG. 7 which shows electric field examples (a), (b), and (c) in different conductive material structures, such as 168. The electric field forces are shown by the arrows in the Figure. In FIGS. 7(a) and 7(b), the charges in the circled areas are not utilized without the vertical bar. Similarly, the circled area in FIG. 7(c) is not charged directly without the vertical bar. Our objective is for the current leave the source bar at the bottom uniformly and the current to enter the top bar uniformly. Vertical bars are used to guide the current towards achieving this objective. In FIGS. 7(a) and 7(b), the charges at the vertical bar exert force horizontally thereby guiding the current from previously unutilized section of the lower bar to be utilized. Similarly, there is a current flowing from the vertical bar to the top bar in FIG. 7(c).

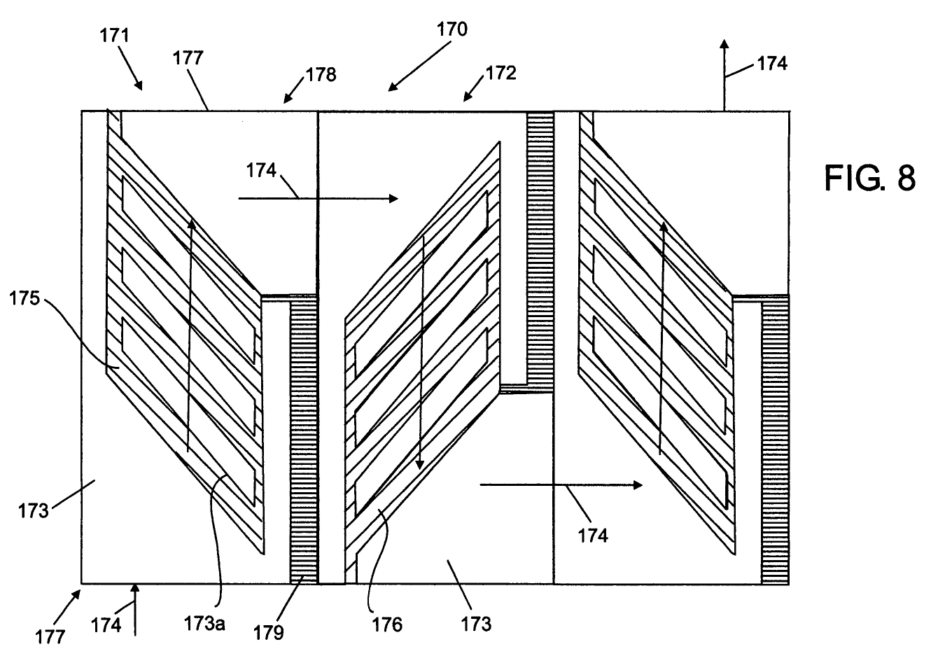

Based on these principles, an example structure of thermal legs with current guidance and current control in a thermal leg is illustrated in FIG. 8. This figure shows a thermoelectric device embodiment 170 containing various interconnected thermal legs, such p-type thermal leg 171 and n-type thermal leg 172. Current 174 is directed through the device as shown by the arrows. Note that electrical current tends to flow more down the path containing less electrical resistance—thus resistances in the current path can be designed so as to direct the current in the desired direction. For example, the resistance of conductive material such as 173 is generally lower than the resistance of p-type semiconductive material such as 175 or the resistance of n-type semiconductive material such as 176. Electrical current 174 entering the hot junction 177 at the bottom is forced to pass through p-type semiconductive material 175 on its path to the cold junction 178 because the semiconductive material is placed in series with the direction of current flow. As such, the current must pass through a series of p-type semiconductive materials 175 and through a series of intervening conductive material segments such as 173(a) on the way to the cold junction 178. Optionally, insulators such as 179 can be used to help steer or direct the current as desired through the device to support thermoelectric functionality. The intervening conductive material segments reduce the effective electrical resistance and can thermally isolate the hot and cold junctions as discussed before. The Electric current flow is directed in the direction of the arrows through the device using differences in electrical resistance between the conductive materials, semiconductive materials and insulators.

Figure of Merit Revisited for Thermoelectric Embodiment Examples of the Present Invention

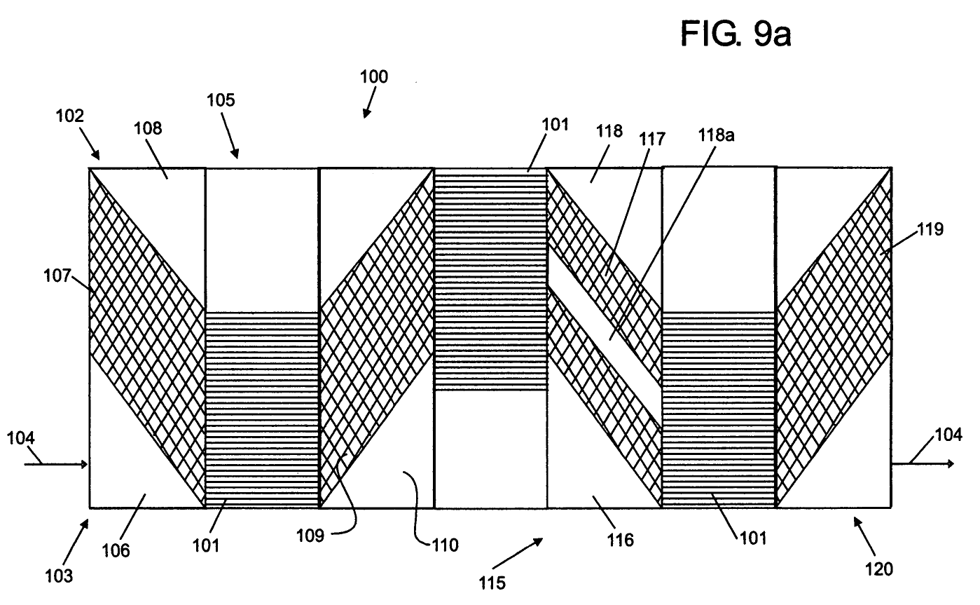

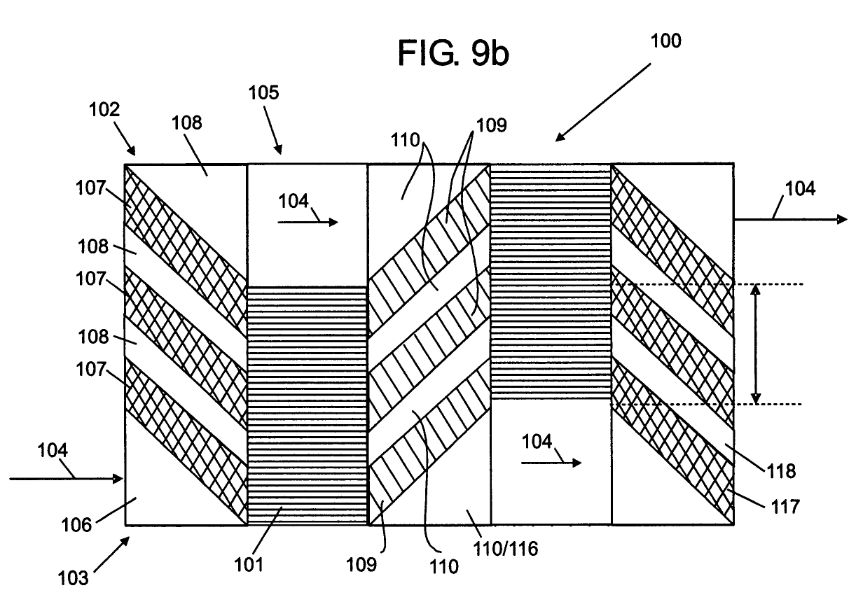

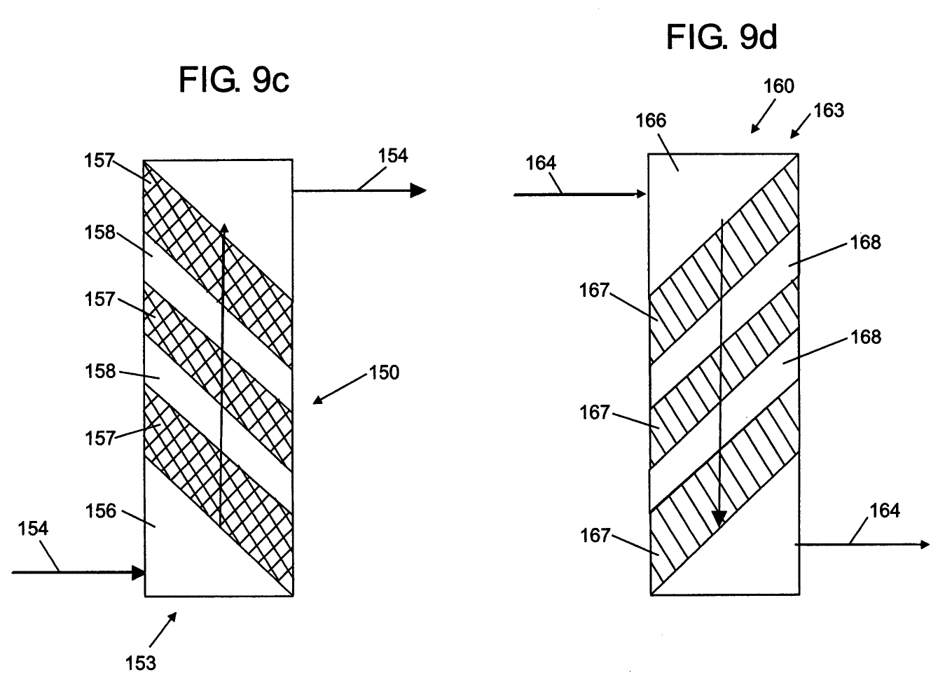

Next, we will illustrate mathematically that the Figure of Merit of the at least some embodiments of the present invention have the potential to be far superior to currently known thermoelectric devices. We will analyze a thermoelectric device similar to that shown in FIG. 9(a) or the like that has at least two thermal legs with p-type and n-type materials. Accordingly, we have:
R: total resistance of one pair of p-type and n-type

$$legs = {ρ}_{n} \frac{{L}_{n}}{{A}_{n}} + {ρ}_{p} \frac{{L}_{p}}{{A}_{p}}$$
K: total thermal conductance of one pair of p-type and n-type

$$legs = {λ}_{n} \frac{{L}_{n}}{{A}_{n}} + {λ}_{p} \frac{{L}_{p}}{{A}_{p}}$$

where (x=n-type or p-type)
ρₓ: electric resistivity of an x-type thermal leg (Ω-m)
λₓ: thermal conductivity of an x-type thermal leg (W/m-° K)
Aₓ: cross sectional area of an x-type thermal leg (m²)
Lₓ: length of an x-type thermal leg (m)
The figure of merit, Z, is given by definition

$$Z = \frac{{S}^{2}}{RK} ,$$

where S is the Seebeck coefficient.
By definition, we have:

$$RK = ( {ρ}_{n} \frac{{L}_{n}}{{A}_{n}} + {ρ}_{p} \frac{{L}_{p}}{{A}_{p}} ) \times ( {λ}_{n} \frac{{A}_{n}}{{L}_{n}} + {λ}_{p} \frac{{A}_{p}}{{L}_{p}} )$$

In the literature, it is assumed that ρₙ=ρₚ, λₙ=λₚ, Aₙ=Aₚ, Lₙ=Lₚ. Then, we have:
RK=4ρₙλₙ and

$$Z = \frac{{S}^{2}}{4 {ρ}_{n} {λ}_{n}}$$

In the proposed architecture, the electric current flows differently than that of the heat leakage from hot junction to cold junction. Hence, the length of the electrical conduction path is different than the lengths of the thermal conduction path. Let us assume that the length in the electrical resistance calculation is rₒLₙ, where rₒ<<1, due to at least some new embodiments. Substituting rₒLₙ in place of Lₙ, in the calculation of R while keeping all other variables the same, the Figure of Merit becomes:

$$Z = \frac{{S}^{2}}{4 {r}_{0} {ρ}_{n} {λ}_{n}}$$

For example, if r₀ is equal to 0.01, then the figure of merit increases 100 fold. This would be the case if the distance between the hot and cold junction is 1 mm (for thermal conduction) whereas the length the electrical current flows is reduced to 10 μm. With this improvement, a thermoelectric device embodiment manufactured with CMOS processing steps could have a figure of merit equal to 100×0.03=3, whereas a thermoelectric device embodiment manufactured with Bismuth Telluride legs could have a figure of merit 100×0.3=30 or so. Thermoelectric performance can thus be improved by making the electrical and thermal path lengths different between the hot and cold junctions in some thermoelectric device embodiments. We can better separate and isolate the hot and cold junctions while allowing localized Peltier cooling to counteract localized Peltier heating as current flows in a controlled and directed manner between the hot and cold junctions of the thermoelectric device. In essence, we are separating the current path from the thermal path between the hot and cold junctions. The electrical current follows a shorter path from one junction to another than the thermal path (i.e., the distance between the two junctions). In doing so, however, it is necessary to counteract the Peltier heating and Peltier cooling at the intermediate structures built using the conductive material that can also reduce the effective resistance. This approach has the potential to increase the figure of merit of any material substantially by utilizing special structures that achieve lower thermal leakage and controlled electrical current flow through a thermoelectric device.

### Embodiments of the Present Invention

Embodiments of the present invention provide thermoelectric devices and related methods attempting to address at least some of the problems noted above. Thermoelectric device embodiments of the present invention seek to apply integrated circuit technology to design thermoelectric devices with higher effective Figures of Merit. In some embodiments, integrated circuit technology may be leveraged to provide a larger number of thermoelectric legs by design and thus improve the overall Figure of Merit. The overall Figure of Merit of a given thermoelectric device embodiment can also be improved by reducing unwanted thermal leakage, by reducing Joule heating, or both within a thermoelectric device. In other embodiments, integrated circuit technology can be used to design thermoelectric devices that attempt to overcome unwanted thermal leakage as the legs of the thermoelectric device are reduced in scale and as the hot and cold junctions are correspondingly brought closer together. Yet other embodiments apply integrated circuit technology to design thermoelectric devices in which the electrical resistance through a leg is lowered seeking to reduce or minimize Joule heating.

Choices of materials used to design the conductive and semiconductive portions of a thermoelectric device embodiment can assist in minimizing unwanted thermal leakage, lowering the effective electrical resistance, or both. For example, the types of materials can be chosen according to their thermal conductivity, electrical resistivity, or both as desired. As such, the thermal conductivity of the conductive and semiconductive portions could be designed by selecting the type of material used in conductive and semiconductive portions of a thermoelectric device embodiment. In addition, the electrical resistivity of the conductive and semiconductive portions can be designed by selecting the type of material used in conductive and semiconductive portions of a thermoelectric device embodiment. It is also possible in the case of semiconductive materials to vary the level of doping as desired to support thermoelectric operation. Further, the geometric design of the conductive or semiconductive portions used in a thermoelectric device embodiment can also support minimizing unwanted thermal leakage, lowering the effective electrical resistance, or both. For instance, geometric parameters such as the cross sectional area, width, depth, and length of conductive or semiconductive portions used in a thermoelectric device embodiment can be chosen to design its thermal conductivity, electrical resistance, or both as needed. Yet further, the physical arrangement of conductive and semiconductive portions, such as whether they are arranged in series, parallel, or combinations thereof, can also be designed to influence thermal conductivity, electrical resistance, or both as desired. In addition, the physical arrangement can seek to separate the electrical current path from the thermal energy path in a thermoelectric leg or thermoelectric device. Those skilled in the art will appreciate that types of materials, geometric dimensions, and the arrangement of the conductive and semiconductive portions of a thermoelectric device embodiment be used in other ways to influence thermal conductivity and electrical resistance by design.

Further, some embodiments of the present invention provide thermoelectric devices with controlled and/or guided current flow that can increase the effective Peltier cooling by reducing the associated Joule heating through design. In addition, some thermoelectric device embodiments are designed to allow Peltier cooling to counteract Peltier heating by using a variety of structures and materials designed to guide electrical current through the span between the hot and cold junctions. At the same time, the electrical resistance between the hot and cold junctions in some embodiments may be reduced by design, thereby lowering the resulting Joule heating. At least some embodiments provide greater physical separation and hence better thermal isolation between the hot and cold junctions, thereby improving thermoelectric device performance through design. Some thermoelectric device embodiments are provided in which the effective electrical resistance of the semiconductive material disposed between the hot and cold junctions is reduced by design below the effective electrical resistance of semiconductive material as electrical current flows through the thermoelectric device. Differences in the effective resistances created by design along the electrical current path between the hot and cold junctions may be used to control or direct the current as desired through some thermoelectric device embodiments seeking improved function.

In essence, the intervening conductive and semiconductive areas help lower the effective resistance to reduce Joule heating while the localized Peltier heating and localized Peltier cooling counteract each other between the hot and cold junctions. As such, the intervening conductive material areas are also known as “resistance reducers” (“rr”). These intervening conductive and semiconductive areas help provide better thermal isolation between the hot and cold junctions as the localized Peltier heating and cooling effects work contrary to each other. Further, the intervening conductive and semiconductive areas also allow better separation between the electrical current path creating Peltier cooling heat exchanges and the thermal path conducting Joule heating and transferred heat. Both electric current and heat flow between the hot and cold junctions. Although the thermal path is separated and made longer than the electrical path, since the resistance is effectively lowered, counterproductive Joule heating may be reduced. The longer thermal path also helps to provide better thermal isolation between the hot and cold junctions since there is greater separation between the hot and cold junctions. As noted, the thermal path can also be shorter or longer than the electrical path by design.

The types of materials used, the geometries used, or both, and the resulting electrical resistances can also be chosen such that Peltier cooling and Peltier heating counteract, or even effectively cancel each other in the intervening structures between the hot junction at the top and the cold junction at the bottom. The intervening structures also help keep the hot junction relatively hotter and the cold junction relatively colder by helping neutralize localized Peltier heating and cooling effects between the hot and cold junctions within the intervening structures. As such, undesired back thermal conduction or leakage between the localized Peltier heating and cooling effect areas can be reduced. Lowering the resulting electrical resistances between the hot and cold junctions can help reduce the associated Joule heating which can better thermally isolate the hot junction at the top from the cold junction at the bottom. Reducing Joule heating helps to curtail undesirable thermal leakage from the hot junction back to the cold junction, which tends to improve the net efficiency of Peltier heating and cooling heat transfers across a device. Note that lowering the effective series resistance helps increase the effective Peltier cooling by allowing more current flow, since Peltier cooling is linearly dependent on current. At the same time the current is increased, we can reduce Joule heating by lowering the electrical resistance. This can be accomplished since Joule heating is created by the square of the current times the lower electrical resistance. The lowered resistance due to the intervening structures can help provide lower Joule heating while the resulting increased current helps provide more effective Peltier cooling, especially given the better thermal isolation between the hot and cold junctions of a thermoelectric device embodiment. As noted, varying the resistances of areas between the hot and cold junctions can help reduce Joule heating, direct the electrical current through a different path than the thermal conduction path, and can provide better thermal isolation between the hot junction and cold junction as Peltier heating and cooling counteract one another.

For a given current flowing through a device, the lower resistance helps reduce the associated Joule heating across the interleaved conductive and semiconductive areas between the hot and cold junctions as shown in FIGS. 9(a) and 9(b). At the same time, Peltier heating and Peltier cooling also counteract each other in the interleaved conductive areas such as 108 and 118(a) shown in these Figures. Heat is exchanged between the first conductive material (or the cold junction at the bottom, for instance) and the third conductive material (or the hot junction at the top, for example) thereby creating a temperature differential therebetween as electrical current flows between the cold junction and the hot junction. Better thermal isolation between the hot and cold end junctions may thereby be created by Peltier heat transfers between the hot and cold junctions when electrical current flows through the intervening conductive and semiconductive areas as shown in FIGS. 9(a) and 9(b).

Accordingly, a set of thermoelectric device embodiments according to the present invention are shown in FIGS. 9(a) and 9(b). A thermoelectric device 100 with electrical current flowing therethrough is provided such that heat may be transferred between the hot side 102 and the cold side 103 of the device embodiment. The thermoelectric device embodiment above comprises a first thermoelectric element 105 and a second thermoelectric element 115. The first thermoelectric element 105 itself comprises at least a first conductive material 106, a first semiconductive material 107, a second conductive material 108, a second semiconductive material 109, and a third conductive material 110. The first semiconductive material 107 may be disposed adjacent to and contacting the first conductive material 106. Further, in some embodiments the second conductive material 108 might be disposed adjacent to and contacting the first semiconductive material 107. In addition, the second semiconductive material 109 can be disposed adjacent to and contacting the second conductive material 108. Lastly, the third conductive material 110 might be disposed adjacent to and contacting the second semiconductive material 109. Similarly, the thermoelectric device embodiment also comprises a second thermoelectric element 115. The second thermoelectric element 115 itself comprises at least a first conductive material 116, a first semiconductive material 117, a second conductive material 118, a second semiconductive material 119, and a third conductive material 120. The first semiconductive material 117 can be disposed adjacent to and contacting the first conductive material 116. Further, the second conductive material 118 may be disposed adjacent to and contacting the first semiconductive material 117. In addition, the second semiconductive material 119 could be disposed adjacent to and contacting the second conductive material 118. In other embodiments, conductive material such as example 118(a) could be disposed within and contacting the first semiconductive material such as shown in 117. Alternatively, in some embodiments the second conductive material may be operably connected to the first semiconductive material. Of course, many other arrangements and interconnections between the second conductive material and first semiconductive material are possible for various other embodiments, Lastly, the third conductive material 120 might be disposed adjacent to and contacting the second semiconductive material 119, as shown in FIG. 9(a). As described herein, a number of permutations and combinations are possible when choosing the semiconductive materials and conductive materials used in segments of each thermoelectric element in various embodiments and how they are arranged and interconnected.

Of course, as shown in FIG. 9(b), a thermoelectric element can have more semiconductive material segments such as various 107 sections shown, more conductive material segments such as various 108 sections shown, or both, such that the number of effective thermoelectric legs can be increased. Similarly, two thermoelectric elements can share conductive material segments, semiconductive material segments, or both, since these elements may interface between two thermoelectric elements. For example in FIG. 4(b), the middle thermoelectric leg shown including areas 109 and 110 could be the second thermoelectric leg of the first thermoelectric element 105 as well as the first thermoelectric leg of the second thermoelectric element 115. Optionally, an insulator such as insulator 101 may be disposed as shown between the first semiconductive material, such as 107 or 117, and the second semiconductive material, such as 109 or 119, of a given thermoelectric element. Further, FIG. 9(b) also illustrates how conductive materials may be disposed contacting a semiconductive material, within a semiconductive material, adjacent to a semiconductive material, operably connected to and semiconductive material, and combinations thereof. There is a lot of flexibility in how conductive materials and semiconductive materials can be interfaced within the scope of the present invention.

Referring back to FIG. 9(a), we note that the third conductive material 110 of the first thermoelectric element 105 and the first conductive material 116 of the second thermoelectric element can be in electrical contact such that electrical current flows therebetween. As skilled artisans will understand, the third conductive material 110 and the first conductive material 116 could optionally be the same conductive material. This option is also shown in FIG. 9(a). Alternatively, the third conductive material of the first thermoelectric element 110 and the first conductive material 116 of the second thermoelectric element could be separate conductive sections but electrically interconnected. In some embodiments, the effective electrical resistance between the first conductive material and the third conductive material of each thermoelectric element may be controllably reduced below the effective series electrical resistances of the respective first semiconductive material and the second semiconductive material therebetween by design as electrical current 104 flows through the respective third conductive materials. Design can be used to as described previously to engineer thermal conductivity and electrical resistance as desired within a thermoelectric element. As noted, the thermal path and the electrical path through a thermoelectric device can be separated to some extent by design. Also by design, the associated Joule heating of each thermoelectric element can be reduced between the first conductive material and the third conductive material in a thermoelectric device as electrical current flows therebetween. Further, Peltier cooling and Peltier heating can be made to counteract each other within the intervening second conductive materials of each thermoelectric element as electrical current flows therethrough. As such, heat is exchanged between the first conductive material and the third conductive material of each thermoelectric element. This creates a temperature differential therebetween as electrical current flows through each thermoelectric element and between the first thermoelectric element and the second thermoelectric element, allowing the device embodiment to transfer heat in Peltier mode operation. As such, device embodiments can reversibly heat or cool depending on the direction of electric current flow.

Electrical resistance variations and placement of insulators across various parts of the structure of thermoelectric device embodiments, such as in conductive and semiconductive materials arranged between the hot and cold junctions, can engineered by design in order to provide better thermoelectric operation. Lower resistance intervening conductive materials may be interleaved between semiconductive material segments or portions, such as shown in FIGS. 9(a) and 9(b). Higher resistance insulators can be used to control and guide the electrical current path. As such, the effective electrical resistance between the first conductive material 106 at the cold junction 103 and the third conductive material 110 may be reduced below the effective series electrical resistances of the first semiconductive material 107 as electrical current flows through the second conductive material 108, for example. The same can occur for the second semiconductive material 109 disposed between conductive areas 108 and 110. In these Figures, for example, the cold junction at the bottom could represent the first conductive material or an electrical contact. Also for instance, the hot junction at the top could represent the third conductive material or a second electrical contact. Intervening conductive materials in FIG. 9(b) such as 108 disposed between the semiconductive materials lower the effective series resistance seen between the cold junction at the bottom and the hot junction at the top of a thermoelectric device. The differences in electrical resistance can be engineered as discussed to control the current path as desired and to provide thermal isolation between the top hot junction and the bottom cold junction in the Figures. Current flowing through the intervening series conductive materials causes Peltier cooling to counteract Peltier heating at various points at which the intervening conductive materials are disposed between the hot junction on top and the cold junction at the bottom. This helps to provide better thermal isolation between the top junction on top and the cold junction at the bottom of a thermoelectric device embodiment. Since the resistance causing Joule heating is also lowered, the same current will create less overall Joule heating as well.

Referring to FIGS. 9(a) and 9(b) further, electrical current 104 enters a thermoelectric device embodiment from the leftmost thermal leg via conductive material 106, which represents the first cold junction. Electric current 104 leaves that thermal leg via conductive material 108, which represents the first hot junction. From the cold junction to hot junction, the current passes vertically through one or more conductive materials, such as conductive material 108 as shown in FIG. 9(b). In addition, the current passes through one or more semiconductive materials, such as semiconductive material 107 also shown. For example, 107 could be a p-type semiconductor material. The Peltier effect occurs at the junction between a conductive material and a semiconductive material. For instance, as electric current leaves the p-type semiconductive material 107, it causes cooling at the junction. In contrast, current entering a p-type semiconductive material causes heating at the junction. Similarly, the current enters the second thermal leg from its hot junction and leaves the leg from its cold junction. From the hot junction to cold junction, the current passes through one or more conductive materials, such as conductive material 110 as shown in FIG. 9(b). In addition, the current passes through one or more semiconductive materials, such as semiconductive material 109 also shown. For example, 109 could be n-type semiconductor material. Every time current leaves n-type semiconductive material 109, it causes heating, whereas current entering n-type semiconductive material causes cooling at the junction. The Peltier effect occurs at the junctions between the semiconductor materials, such as p-type or n-type, and electrically conductive materials such as Aluminum for example or the like, as will be discussed. The Peltier heating and cooling can counteract, and hopefully cancel each other, within conductive material sections as discussed.

As shown in FIG. 9(b), one or more bands of conductive materials may be placed between the hot and cold junctions in a thermal leg of a thermoelectric device embodiment. It is possible to alternate bands of semiconductive materials 107 with bands of conductive materials 108 within a thermal leg as shown. As such, the bands of interleaved conductive material work to reduce the effective electrical resistance of the semiconductive materials disposed between the hot and cold junctions in a thermal leg. We also refer to these bands of interleaved conductive materials as “resistance reducers” (“rr”). Another example of a resistance reducer is shown by 118(a) in FIG. 9(a). Resistance reducers are possible since the electrical resistance of a conductive material is typically considerably lower than the electrical resistance of a semiconductive material. For example, a conductive material could be a metal or other highly conductive material while semiconductive materials might be silicon or some other semiconductor material. Of course, the semiconductive materials could be depleted, undoped, p-type doped, or n-type doped, for example. As a further example, the semiconductive materials might be lightly doped, moderately doped, or highly doped as well. However, the conductor typically will have a lower electrical resistance.

### Additional Embodiments of the Present Invention

Next we will discuss a number of additional thermoelectric device embodiments according to the present invention. These additional embodiments are related to FIGS. 9(a) and 9(b) and subsequent Figures. To refresh our recollection, the earlier embodiments in FIG. 9(a) described a thermoelectric device 100 with electrical current flowing therethrough such that heat may be transferred between the hot side 102 and the cold side 103 of a device embodiment. The thermoelectric device embodiment above comprises a first thermoelectric element 105 and a second thermoelectric element 115. The first thermoelectric element 105 itself comprises at least a first conductive material 106, a first semiconductive material 107, a second conductive material 108, a second semiconductive material 109, and a third conductive material 110. The first semiconductive material 107 can be disposed adjacent to and contacting the first conductive material 106. Further, the second conductive material 108 may be disposed adjacent to and contacting the first semiconductive material 107. In addition, the second semiconductive material 109 could be disposed adjacent to and contacting the second conductive material 108. Lastly, the third conductive material 110 might be disposed adjacent to and contacting the second semiconductive material 109. Per the above discussion, we note that conductive material may be disposed contacting a semiconductive material, within a semiconductive material, adjacent to a semiconductive material, operably connected to and semiconductive material, and in combinations thereof. Similarly, the thermoelectric device embodiment also comprises a second thermoelectric element 115. The second thermoelectric element 115 itself comprises at least a first conductive material 116, a first semiconductive material 117, a second conductive material 118, a second semiconductive material 119, and a third conductive material 120. The first semiconductive material 117 can be disposed adjacent to and contacting the first conductive material 116. Further, the second conductive material 118 may be disposed adjacent to and contacting the first semiconductive material 117. Alternatively or in addition, second conductive material 118(a) may be disposed within and contacting the first semiconductive material 117 as shown in FIG. 9(a). In addition, the second semiconductive material 119 could be disposed adjacent to and contacting the second conductive material 118. Lastly, the third conductive material 120 might be disposed adjacent to and contacting the second semiconductive material 119, also as shown in FIG. 9(a). Since the third conductive material of the first thermoelectric element and the first conductive material of the second thermoelectric element may be in electrical contact, as such electrical current can flow therebetween. In addition, the effective electrical resistance between the first conductive material and the third conductive material of each thermoelectric element may be controllably reduced below the effective series electrical resistances of the respective first semiconductive material and the second semiconductive material by design as electrical current flows through the respective third conductive materials. The associated Joule heating of each thermoelectric element can be reduced between the first conductive material and the third conductive material as electrical current flows therebetween. Further, the Peltier cooling and Peltier heating counteract each other within the second conductive materials of each thermoelectric element as electrical current flows therethrough. As such, heat or thermal energy may be exchanged between the first conductive material and the third conductive material of each thermoelectric element. This creates a temperature differential therebetween as electrical current flows through each thermoelectric element and between the first thermoelectric element and the second thermoelectric element.

In a related embodiment, one of the first semiconductive material and the second semiconductive material of one thermoelectric element can function as the other of the first semiconductive material and the second semiconductive material for another thermoelectric element. In other words, semiconductive materials may be shared and function as parts of two different thermoelectric devices. For example, the semiconductive material that comprises a second leg of a first thermoelectric device could also operate as the first leg of a second thermoelectric device, since thermoelectric devices can be arranged in series electrically but in parallel for thermal heat transfers. Similarly, in another embodiment one of the first conductive material, second conductive material, and the third conductive material of one thermoelectric element can function as the other of the first conductive material, second conductive material, and the third conductive material for another thermoelectric element. Again, conductive materials may be shared and function as parts of two different thermoelectric devices. For example, the conductive material that comprises the second conductive material of one leg could also operate as the second conductive material of an adjacent leg. Further, the conductive material that comprises the third conductive material of one leg could also operate as the first conductive material of an adjacent leg.

Some embodiments demonstrate variations with respect to the first or second semiconductive materials used in a thermal leg or in a thermoelectric device. For example, the first semiconductive material of a thermal leg may comprise a single area of semiconductive material that can contact conductive material, such as the first or second conductive materials as described herein. In addition, the first semiconductive material can comprise two semiconductive material areas of the same type each contacting conductive materials, such as the first conductive material or second conductive material. Further, the first semiconductive material may comprise two semiconductive areas of different types, such as an area of p-type material and an area of n-type material. As before, each semiconductive area may contact conductive materials such as the first or second conductive materials. The examples above apply equally to second semiconductive material areas or other semiconductive material areas used in various embodiments. The semiconductive material areas can also be in contact with, disposed within, or operably connected to semiconductive areas as described herein. Of course, other permutations and combinations not described above are possible, as will be understood by those of skill in the art.

Another set of embodiments further describe some options with respect to the characteristics of the semiconductive materials used in thermoelectric devices. For example, at least one of the first semiconductive material and second semiconductive material could be subjected to p-doping, n-doping, depletion, or no doping at all. In some cases, the first semiconductive materials of the first thermoelectric element and the second thermoelectric element are similarly doped, such as both being subjected to p-doping, n-doping, depletion, or no doping at all. Alternatively, the first semiconductive materials of the first thermoelectric element and the second thermoelectric element could be subjected to different doping, such as different permutations and combinations of p-doping, n-doping, depletion, or no doping. In further embodiments, two or more semiconductive materials could be arranged electrically in various ways. For instance, at least one of the first semiconductive material and second semiconductive material could be arranged in series with the direction of the electrical current flowing between the first conductive material and the third conductive material within a thermoelectric device. For example, two semiconductive material areas comprising the first or second semiconductive material areas as described above could be arranged electrically in series. However, at least one of the first semiconductive material and second semiconductive material could also be arranged in parallel with the direction of the electrical current flowing between the first conductive material and the third conductive material. As a further example, two semiconductive material areas comprising a semiconductive material area as described above could be arranged electrically in parallel, or in combinations of series and parallel circuit elements. Or course, it is possible to arrange different semiconductive elements in series and in parallel, as those skilled in the art will appreciate. In some cases, whether the semiconductive materials are arranged in series or in parallel, it may possible to provide an insulator disposed between and electrically isolating the first semiconductive material and second semiconductive material as electrical current flows between the first conductive material and the third conductive material in a thermoelectric device. The placement of insulators can help guide the electrical current through the thermoelectric device as desired, as known by skilled artisans.

As discussed, many different types of materials could be used as semiconductive material for thermoelectric device embodiments. Useful materials include nanotubes, carbon nanotubes, nanowires, silicon nanowires, nanomaterials, nanostructures, and the like. In addition, Bismuth, Boron, Silicon, Silicon-On-Insulator, Germanium, Arsenic, Antimony, Tellurium, Polonium, Silicon-Germanium, Bi2Te3, and superlattice materials could also be used. Similarly, a large number of materials could be used as conductive material for thermoelectric device embodiments. Among materials that could be used nanotubes, carbon nanotubes, nanowires, silicon nanowires, nanomaterials, nanostructures, and the like. Flexible conductive materials, conductive plastics, conductive polymers, and superlattice materials could also be used. Further, Aluminum, Copper, Tin, Palladium, Gold, Silver, Titanium, Tungsten, Iron, Cobalt, Nickel, Zinc, Molybdenum, Cadmium, Mercury, Hafnium, Tantalum, Gallium, Indium, Thallium, Lead, Bismuth, and alloys thereof are other conductive material options. Regarding the conductive materials, the third conductive material of the first thermoelectric element and the first conductive material of the second thermoelectric element could be one single conductive material interconnecting the first thermoelectric element and the second thermoelectric element. Alternatively, the third conductive material of the first thermoelectric element and the first conductive material of the second thermoelectric element could be separate but electrically interconnected conductive materials. In addition, for some embodiments the intervening materials between the first conductive material and the third conductive material of at least one of the first thermoelectric element and the second thermoelectric element of the thermoelectric device could increase thermal isolation therebetween while reducing the associated Joule heating as electrical current flows therebetween, such as by reducing the electrical resistance between the hot and cold junctions. In some cases, the electrical current path between the first conductive material and the third conductive material of at least one of the first thermoelectric element and the second thermoelectric element of the thermoelectric device is separated from the thermal conduction path between the first conductive material and the third conductive material of at least one of the first thermoelectric element and the second thermoelectric element by the intervening materials therebetween. Separating the electrical current path from the thermal conduction path helps improve thermoelectric device performance.

In a different set of thermoelectric device embodiments, at least one of the first thermoelectric element and the second thermoelectric element of a thermoelectric device may further comprise a second semiconductive material, a fourth conductive material, and optionally a fifth conductive material. The second semiconductive material may be depleted, undoped, p-doped, or n-doped. The second semiconductive material may be any of the types of materials described herein. Further, the second semiconductive material can be disposed adjacent to and contacting the third conductive material at one edge of the second semiconductive material. The fourth conductive material may be disposed adjacent to, contacting, within, or operably connected to the second semiconductive material as discussed above. The optional fifth conductive material may be disposed adjacent to and contacting another edge of the second semiconductive material. The second semiconductive material, the fourth conductive material, and the fifth conductive material can be selected, designed, and configured in any of the ways described above for the other semiconductive and conductive materials described herein. In some cases, the second semiconductive material, the fourth conductive material, and optionally the fifth conductive material may be disposed electrically in series with the first semiconductive material and its related conductive material areas. Further, the second semiconductive material and its respective conductive material may be disposed thermally in parallel with the first semiconductive material area and its corresponding conductive material areas. The effective electrical resistance between the first conductive material and the fourth or fifth conductive material of the respective thermoelectric element may be controllably reduced below the effective series electrical resistances of the first semiconductive material or the second semiconductive material by design as electrical current flows through between the respective conductive materials. In addition, the Peltier cooling and Peltier heating can counteract each other within the respective conductive materials as electrical current flows therethrough. As such, heat may be exchanged between the conductive materials at the respective hot and cold junctions creating a temperature differential therebetween as electrical current flows therebetween.

In some embodiments, the first semiconductive material and second semiconductive material of at least one of the first thermoelectric element and the second thermoelectric element of the thermoelectric device may be similarly doped with one of p-doping, n-doping, depletion, and no doping. For this case, the doping is similar. However, there may also be differences in doping or in the types of materials used as described. In other embodiments, the first semiconductive material and the second semiconductive material of at least one of the first thermoelectric element and the second thermoelectric element of a thermoelectric device may be differently doped with at least two of p-doping, n-doping, depletion, and no doping. Various axes and positional relationships are possible as noted herein. For some alternative embodiments, at least one of the first thermoelectric element and the second thermoelectric element of at least one of the first thermoelectric element and the second thermoelectric element of the thermoelectric device, an edge of the first conductive material opposite to the first semiconductive material runs along a first horizontal axis. An edge of the third conductive material opposite to the second semiconductive materials runs along a second horizontal axis, and wherein the first horizontal axis and second horizontal axes are substantially parallel. Further, in some embodiments at least one of the first thermoelectric element and the second thermoelectric element of at least one of the first thermoelectric element and the second thermoelectric element of the thermoelectric device, the first semiconductive material, the second conductive material, and the second semiconductive material can each be disposed parallel to a third axis having an angular relationship with the first and second horizontal axes. The angular relations ship can be a substantially parallel relationship with the first and second horizontal axes, a substantially perpendicular relationship with the first and second horizontal axes, an obtuse angular relationship with the first and second horizontal axes, or an acute angular relationship with the first and second horizontal axes.

Another set of embodiments describe thermal leg embodiments according to the present invention. One such embodiment comprises a thermoelectric device with electrical current flowing therethrough that contains at least a first conductive material, a first semiconductive material, a second conductive material, and a third conductive material. Optionally, a second semiconductive material, fourth conductive material, fifth conductive material, or combinations of may also be provided in related embodiments. The first semiconductive material may be disposed adjacent to and contacting the first conductive material. Further, the second conductive material can be disposed within, adjacent to, contacting, or operably connected to the first semiconductive material. In addition, the second semiconductive material could be disposed adjacent to and contacting the second conductive material. Lastly, the third conductive material may be disposed adjacent to and contacting the second semiconductive material. In embodiments comprising the second semiconductive material, it could be disposed adjacent to and contacting the third conductive material, the fourth conductive material, the fifth conductive material, or combinations thereof. Further, the fourth conductive material could be disposed adjacent to, disposed within, contacting, or operably connected to the second semiconductive material. The fifth conductive material may be disposed adjacent to and contacting the second semiconductive material. The effective electrical resistance between the first conductive material and the third conductive materials is controllably reduced below the effective series electrical resistances of the first semiconductive material and the second semiconductive material by design as electrical current flows through the third conductive material. Also, the associated Joule heating is reduced between the first conductive material and the third conductive material as electrical current flows therebetween. In operation, the Peltier cooling and Peltier heating counteract each other within the second conductive material as electrical current flows therethrough. Accordingly, heat is exchanged between the first conductive material and the third conductive material creating a temperature differential between the first conductive material and the third conductive material as electrical current flows therebetween.

For the above embodiments, at least one of the first semiconductive material and second semiconductive material may be subjected to p-doping, n-doping, depletion, or no doping. In addition, the first semiconductive material and second semiconductive material could be similarly doped and both be subjected to p-doping, n-doping, depletion, or no doping. In contrast, the first semiconductive material and second semiconductive material might be differently doped from the group of doping profiles consisting of p-doping, n-doping, depletion, and no doping. As previously, different types of materials can be used. At least one of the first semiconductive material and second semiconductive material could be made from materials selected from the group consisting of nanotubes, carbon nanotubes, nanowires, silicon nanowires, nanomaterials, nanostructures, Bismuth, Boron, Silicon, Silicon-On-Insulator, Germanium, Arsenic, Antimony, Tellurium, Polonium, Silicon-Germanium, Bi2Te3, superlattice materials, and the like. Analogously, at least one of the first conductive material, the second conductive material, and the third conductive material might be made from materials selected from the group consisting of nanotubes, carbon nanotubes, nanowires, silicon nanowires, nanomaterials, nanostructures, flexible conductive materials, conductive plastics, conductive polymers, superlattice materials, Aluminum, Copper, Tin, Palladium, Gold, Silver, Titanium, Tungsten, Iron, Cobalt, Nickel, Zinc, Molybdenum, Cadmium, Mercury, Hafnium, Tantalum, Gallium, Indium, Thallium, Lead, Bismuth, alloys thereof, and the like.

In some cases, at least one of the first semiconductive material and second semiconductive material could be arranged in series with the direction of the electrical current flowing between the first conductive material and the third conductive material. However, in other cases at least one of the first semiconductive material and second semiconductive material might be arranged in parallel with the direction of the electrical current flowing between the first conductive material and the third conductive material. Of course, these materials could be arranged to be both in series and in parallel with the direction of electrical current flowing through the conductive materials. For any or all of the preceding cases, an insulator can optionally be disposed between and electrically isolating the first semiconductive material and second semiconductive material as electrical current flows between the first conductive material and the third conductive material. Insulators can be used to help control and guide current flow as desired. For some embodiments, the intervening materials between the first conductive material and the third conductive material can increase thermal isolation therebetween while reducing the associated Joule heating as electrical current flows therebetween. Optionally, the electrical current path between the first conductive material and the third conductive material can be separated from the thermal conduction path between the first conductive material and the third conductive material by the intervening materials. Again in other cases, an edge of the first conductive material opposite to the first semiconductive material may run along a first horizontal axis. Further, an edge of the third conductive material opposite to the second semiconductive materials could run along a second horizontal axis, such that the first horizontal axis and second horizontal axes are substantially parallel. Further, the first semiconductive material, the second conductive material, and the second semiconductive material could each be disposed parallel to a third axis having an angular relationship with the first and second horizontal axes selected from the group consisting of a substantially parallel relationship with the first and second horizontal axes, a substantially perpendicular relationship with the first and second horizontal axes, an obtuse angular relationship with the first and second horizontal axes, and an acute angular relationship with the first and second horizontal axes.

For another series of embodiments, the thermoelectric device further comprises a second semiconductive material, a fourth conductive material, and a fifth conductive material. The fourth semiconductive material could be disposed adjacent to and contacting the third conductive material of a thermoelectric at a first edge of the semiconductive material, while the fourth conductive material may be disposed within, adjacent to contacting, or operably connected to the second semiconductive material. The fifth conductive material may be disposed adjacent to and contacting the second semiconductive material at a second edge thereof. The effective electrical resistance between the third conductive material and the fifth conductive material can be controllably reduced below the effective series electrical resistances of the second semiconductive material by design of the fourth conductive material as interfaced to the second semiconductive material, as electrical current flows through the third conductive material and the fifth conductive material. In addition, the Peltier cooling and Peltier heating counteract each other within the fourth conductive material as electrical current flows therethrough. As such, heat can be exchanged between the third conductive material and the fifth conductive material thereby creating a temperature differential therebetween as electrical current flows therebetween. As before, in some cases the second semiconductive material could be subjected to p-doping, n-doping, depletion, or no doping. Further, in some embodiments at least one of the first semiconductive material or the second semiconductive material could be created from nanotubes, carbon nanotubes, nanowires, silicon nanowires, nanomaterials, nanostructures, Bismuth, Boron, Silicon, Silicon On Insulator, Germanium, Arsenic, Antimony, Tellurium, Polonium, Silicon-Germanium, Bi2Te3, or superlattice materials. As discussed before, other types of materials can also be used. Also, in some embodiments an edge of the third conductive material opposite to the second semiconductive material runs along a first horizontal axis and an edge of the fifth conductive material opposite to the second semiconductive material runs along a second horizontal axis. As such, the first horizontal axis and second horizontal axes are substantially parallel. For other cases, the first semiconductive material, the second conductive material, the second semiconductive material, and the fourth conductive material could each disposed parallel to a third axis having an angular relationship with the first and second horizontal axes. The angular relationship may be selected from the group consisting of a substantially parallel relationship with the first and second horizontal axes, a substantially perpendicular relationship with the first and second horizontal axes, an obtuse angular relationship with the first and second horizontal axes, and an acute angular relationship with the first and second horizontal axes.

The present invention provides yet another set of thermoelectric device embodiments. A thermoelectric device with electrical current flowing therethrough is provided. The thermoelectric device contains at least first means for conducting electricity, first means for semiconducting electricity, second means for conducting electricity, second means for semiconducting electricity, and also third means for conducting electricity. The first means for semiconducting electricity could be operably connected to the first means for conducting electricity. In addition, the second means for conducting electricity may be operably connected to the first means for semiconducting electricity. Further, the second means for semiconducting electricity might be operably connected to the second means for conducting electricity. Also, the third means for conducting electricity can be operably connected to the second means for semiconducting electricity. The embodiment further comprises means for controllably reducing the effective electrical resistance between the first means for conducting electricity and the third means for conducting electricity below the effective series resistances of the first means for semiconducting electricity and the second means for semiconducting electricity by design as electrical current flows therethrough. Lastly, the embodiment also comprises means for controllably counteracting the Peltier heating by the Peltier cooling as electrical current flows through the means for controllably reducing the effective electrical resistance. The means used in these embodiments are further described in the description of comparable embodiments wherein elements instead of means were used in the device embodiments.

In another set of thermoelectric device embodiments provided by the present invention, various means are also employed. For these embodiments, a thermoelectric device is provided with electrical current flowing therethrough. The thermoelectric device comprising at least a first thermoelectric element and a second thermoelectric element. The first thermoelectric element includes at least first thermoelectric element, including at least first means for conducting electricity, first means for semiconducting electricity, second means for conducting electricity, second means for semiconducting electricity, and third means for conducting electricity. The first means for semiconducting electricity may be operably connected to the first means for conducting electricity. In addition, the second means for conducting electricity could be operably connected to the first means for semiconducting electricity. Further, the second means for semiconducting electricity might be operably connected to the second means for conducting electricity. Lastly, the third means for conducting electricity can be operably connected to the second means for semiconducting electricity. Next, the second thermoelectric element is described. Similarly, the first thermoelectric element includes at least first thermoelectric element, including at least first means for conducting electricity, first means for semiconducting electricity, second means for conducting electricity, second means for semiconducting electricity, and third means for conducting electricity. As before, the first means for semiconducting electricity may be operably connected to the first means for conducting electricity. Similarly, the second means for conducting electricity could be operably connected to the first means for semiconducting electricity. In addition, the second means for semiconducting electricity might be operably connected to the second means for conducting electricity. Further, the third means for conducting electricity can be operably connected to the second means for semiconducting electricity. These embodiments may also provide means for controllably reducing the effective electrical resistance and means for controllably counteracting the Peltier heating by the Peltier cooling. The means for controllably reducing can reduce the effective electrical resistance between the first means for conducting electricity and the third means for conducting electricity of at least one thermoelectric element below the effective series resistances of the corresponding first means for semiconducting electricity and the corresponding second means for semiconducting electricity by design as electrical current flows therethrough. Also, the means for controllably counteracting the Peltier heating by the Peltier cooling as electrical current flows through the means for controllably reducing the effective electrical resistance can provide this function. As before, the means used in these embodiments are further described in the description of comparable embodiments wherein elements instead of means were used in embodiments.

A number of metalloids, semiconductors, or other substrates can be used in various thermoelectric embodiments as semiconductive materials. Metalloids have properties of both metals and non-metals. Some of the metalloids, such as silicon and germanium, are semiconductors. As such, these metalloids can carry an electrical charge under special conditions, which makes these materials useful for creating thermoelectric devices. A viable semiconductive material is a material that is capable of carrying electrical charge in various amounts as needed with a given conductivity, which has an appropriate Seebeck coefficient to support the desired thermoelectric operation, or both. The viable semiconductive materials that can be used can vary according to the desired thermoelectric device embodiment and the application. Different types of materials may be chosen to provide suitable conductivity, Seebeck coefficients, or both as may be needed for a particular thermoelectric device embodiment. Examples of some metalloids that can be used in the present invention include but are not limited to Boron, Silicon, Silicon-On-Insulator), Germanium, Arsenic, Antimony, Tellurium, Polonium, and the like. Hybrid substrates and materials such as Silicon-Germanium and the like may also be used. Nanotubes may also be used since they can be grown semiconductive. Nanowires, nanomaterials, and nanostructures can also be used as semiconductive materials in device embodiments. The reader is referred to Table 1 “Materials and Properties”, for some example materials that may be used as semiconductive materials. This Table provides Resistivity, Seebeck coefficient, and Figure of Merit information for examples of some materials that can be used in thermoelectric device embodiments of the present invention. Of course there are other types of materials having suitable Resistivity, Seebeck coefficient, and Figure of Merit for use in various embodiments.

The semiconductive materials used can be processed and configured in a number of ways in different thermoelectric device embodiments. Depending on the design and structure of the thermoelectric device embodiment, these materials can have various associated parameters. For example, these materials can be doped similarly or differently as required to support thermoelectric effects in a given thermoelectric device embodiment. Either or both of these materials can be depleted, undoped, p-doped, or n-doped. If a material is doped, it can be lightly doped, moderately doped, or highly doped again as required to support the Peltier or Seebeck effects within a thermoelectric device embodiment. The reader is referred to Table 2 and Table 3 for some examples of doping levels and the corresponding resistivity of semiconductive materials that could be used in some embodiments of the present invention. For instance, Table 2 illustrates various doping concentrations that might be used for n-type silicon doping, and the anticipated resistivity. Table 3 shows various example doping concentrations that could be used for p-type silicon doping, and the expected resistivity. As discussed, many other substrate materials and a large number of doping profiles, even including depleted and undoped materials, may be used as needed for a particular thermoelectric device embodiment.

TABLE 1
Materials and Properties

| | Resistivity | Seebeck Coefficient | Figure of Merit |
|---|---|---|---|
| Material | (1/Ω-cm) | (μV/K) | Z/K |
| Bi2Te3 (polycrystal) | 1000 | 200 | 3.0e−3 |
| SiGe (p) 400K | 758 | 144 | 3.3e−4 |
| SiGe (n) 400K | 990 | −136 | 4.1e−4 |
| Al | 366300 | −1.66 | 4.2e−7 |
| Au | 440529 | 1.94 | 5.4e−7 |
| Bi (polycrystal) | 9091 | −72 | 5.9e−4 |
| Co | 160256 | −30.8 | 1.5e−4 |
| Cr | 77519 | 21.8 | 4.1e−5 |
| Cu | 580000 | 1.83 | 4.8e−7 |
| Eu | 11111 | 24.5 | 4.8e−5 |
| Ge (thin film) n | 1.45 | −548 | 6.8e−7 |
| Ge (thin film) p | 12 | 420 | 3.3e−6 |
| In | 119474 | 1.68 | 4.2e−7 |
| InAs n | 500 | −180 | 2.7e−5 |
| InAs p | 500 | 200 | 8.0e−5 |
| Ir | 100200 | 0.86 | 9.2e−8 |
| Ni | 138889 | −19.5 | 5.9e−5 |
| Pb | 48426 | −1.05 | 1.5e−7 |
| Sb (polycrystal) | 28570 | 41 | 2.0e−4 |
| Si n 300K | 372 | −400 | 4.5e−5 |
| Si p 300K | 286 | 450 | 4.0e−5 |
| Te (annealed) | 154 | 274 | 1.0e−4 |
| Te (polycrystal) | 5.3 | 526 | 1.3e−5 |
| Ti | 23810 | 9.1 | 9.1e−6 |

Resistivity and Seebeck properties of different materials (Thermoelectric Power Factor for Electrically Conductive Polymers, A. Shakouri and S. Li, Proceedings of International Conference on Thermoelectrics, Baltimore, Maryland, Sept. 1999)

The selection of the types of semiconductive materials used may vary within a thermoelectric device or between various thermal legs or thermoelectric devices used in an embodiment. For example, the first semiconductive material could be undoped in the first thermoelectric device and the first semiconductive material in the second thermoelectric device could be p-doped. For instance, both first semiconductive materials in the first and second thermoelectric devices could similarly be n-doped or n-doped. Further, the first semiconductive material could be p-type doped semiconductive material while the second semiconductive material could be n-type doped semiconductive material. As such the semiconductive materials used may be the same or similar across two thermoelectric legs or devices in some embodiments. These are but a few of a large number of permutations and combinations that are possible for the selection of semiconductive materials that can be used in thermoelectric device embodiments.

TABLE 2
N-Type Silicon Resistivity Versus Doping

| Resistivity (ohm-cm) | Doping (cm⁻³) |
|---|---|
| 0.0001 | 1.60E+21 |
| 0.001 | 7.38E+19 |
| 0.01 | 4.53E+18 |
| 0.1 | 7.84E+16 |
| 1 | 4.86E+15 |
| 10 | 4.45E+14 |
| 100 | 4.27E+13 |
| 1000 | 4.20E+12 |
| 10000 | 4.00E+11 |

Source: VirginiaSemi Databook

TABLE 3
P-Type Silicon Resistivity Versus Doping

| Resistivity (ohm-cm) | Doping (cm⁻³) |
|---|---|
| 0.0001 | 1.20E+21 |
| 0.001 | 1.70E+20 |
| 0.01 | 8.49E+18 |
| 0.1 | 2.77E+17 |
| 1 | 1.46E+16 |
| 10 | 1.34E+15 |
| 100 | 1.33E+14 |
| 1000 | 1.30E+13 |
| 10000 | 1.30E+12 |

Source: VirginiaSemi Databook

Next, we discuss the types of materials that may be used as conductive materials in thermoelectric device embodiments. Many types of metals and conductors that can be used, either as the conductive Material shown in diagrams and illustrations, as electrical contacts, or as electrical interconnects for embodiments of thermoelectric devices. These metals and conductors may be relatively rigid such as formed or deposited metals, or can also be relatively flexible such as flexible conductive materials, conductive plastics, and conductive polymers. Aluminum, Copper, Tin, Palladium, Gold, Silver, Titanium, Tungsten, Iron, Cobalt, Nickel, Zinc, Molybdenum, Cadmium, Mercury, Hafnium, Tantalum, Gallium, Indium, Thallium, Lead, Bismuth, and the like are merely examples of what metals and conductors may be used. Alloys of these and other metals in combination may be used as well. In addition, nanotubes can be used since nanotubes can also be conductive. Nanowires, nanomaterials, and nanostructures having suitable characteristics can also be used as conductive materials in some device embodiments.

It is helpful if the material to be selected as a conductive material has sufficient electrical conductivity, an appropriate Seebeck coefficient, or both. As such, these parameters can be selected to support a given thermoelectric device embodiment or thermoelectric application. In some cases, the compatibility of the metal or conductor used as a conductive material with semiconductor manufacturing processes may be a consideration for determining what might be used in a given thermoelectric device embodiment. At times, applying a given metal or conductor within thermoelectric device embodiments may require a suitable Seebeck coefficient, acceptable electrical conductivity, along with manufacturing process compatibility. Of course, flexible materials such as polymers and plastics can also be used if they have the required conductivity, Seebeck coefficient, both, or other attributes. The reader is referred to Table 1 above labeled “Materials and Properties” for some examples of the types of materials that could be used as conductive material in thermoelectric device embodiments. Many materials not listed could also be chosen to provide suitable conductivity, Seebeck coefficients, or both as needed for a particular thermoelectric device embodiment. Further, other materials, alloys, combinations of materials, and other compositions can be used to make thermoelectric device embodiments within the scope of the present invention.

We note that the metals and conductors used as conductive material may be the same, similar, or different, depending on their expected function within a thermoelectric device embodiment and depending on the structure and operation of a particular thermoelectric device embodiment. For example, a conductive material may be chosen solely for their Seebeck or Peltier thermoelectric effects. Further, a conductive material can be selected based on their performance as contacts, vias, or interconnect. For instance, a conductive material could be chosen for their electrical conductivity, for instance. As noted, the compatibility of the metal and conductor with semiconductor fabrication or other manufacturing or assembly processes could be all or part of the selection criteria as well. It may be possible to select the same metal or conductor to provide two or more different functions in an embodiment. Also, it may be necessary to select similar or different metals or conductors as needed for a device embodiment.

For some embodiments, an insulator such as 101 shown in FIGS. 9(a) and 9(b) may be required between thermal legs in a thermoelectric device. For other embodiments in which semiconductive elements are arranged either in series or in parallel with the direction of electrical current flow through the device, an insulator might be used to electrically isolate semiconductive elements. Many known insulators can be used, including but not limited to Silicon Dioxide (SiO₂), various dielectrics used in semiconductor manufacturing, other insulators used in semiconductor fabrication, other types of dielectrics, and the like. For example, undoped, depleted, or lightly doped n-type or p-type semiconductor material could also be used as an insulator. The insulator should have relatively lower conductivity, hence relatively higher resistivity, than the conductive or semiconductive materials used in some thermoelectric device embodiments. Insulators may be used in thermoelectric embodiments so as to oppose charge carrier transport. For example, the resistivity of some common insulators is as follows: glass has a resistivity of approximately 1×1012 (ohm-m), mica has a resistivity of approximately 9×1013 (ohm-m), fused quartz has a resistivity of approximately 5×1016 (ohm-m). In contrast, heavily doped semiconductors and conductors have the relatively lower resistivities as seen in Tables 1-3 above. The insulator used may vary depending on the structure of a given thermoelectric device embodiment, depending on the semiconductor or manufacturing process used, or both. In addition, some thermoelectric device embodiments do not require the use of an insulator given their structure and architecture. As noted, insulators can help control and guide the electric current through a device embodiment by design of the current path or paths.

It is noteworthy that embodiments of the present invention allow the use of more types of materials for thermoelectric applications than previously possible since the use of the intervening resistance reducers allow control and direction of electrical current flow. Hence, these are used to partly reduce the total resistance, and thereby reduce Joule heating, as the current flows through a thermoelectric leg. In addition, the intervening resistance reducers help isolate the hot and cold junctions as Peltier cooling effects and Peltier heating effects counteract each other within a resistance reducer. The dimensions and materials used for resistance reducers can be chosen such that the heat and cold generated at these materials as the current enters and leaves due to Peltier effect counteract each other. With proper design, it should be possible to have the heat and cold effectively cancel each other. In any case, having the Peltier cooling and Joule heating counteract each other provides better performance by isolating the hot and cold junctions to prevent heat from leaking back to the cold junction. In addition, this allows greater separation between the hot and cold junctions which also helps improve their thermal isolation to prevent thermal leakage back.

Next, we refer to an example of a first thermal leg, such as the thermal leg 150 shown in FIG. 9(c) to explain more about the operation of the resistance reducers of some thermoelectric device embodiments. Electric current 154 flows from the cold junction 153 through conductive material 156, which could serve as a contact for example. For the thermal leg in this Figure, we assume that the semiconductive material is p-type material. As the current enters a first semiconductive material such as 157 from a conductive material such as 156, it causes cooling at the junction with conductive material 156. The electric current also causes heating as it leaves the first semiconductive material 157 and enters the first resistance reducer 158, which can be a second conductive material similar to 156. Similarly, as current leaves the first resistance reducer 158 and enters the next semiconductive material 157 it also causes cooling at the junction. Accordingly, one junction of the resistance reducer is cooled while the other junction of the resistance reducer is heated given Peltier heating and Peltier cooling. For instance, the lower junction between the first resistance reducer 158 and the first semiconductive material 157 is hot, while the upper junction between the first semiconductive material 157 and the next semiconductive material 157 is cold. Since the conductive material is likely to have a lower electrical resistivity than semiconductive material, using it between the hot and cold junctions reduces the total resistance seen by the electric current as it flows from one junction to another. In essence, this is an example of what the resistance reducers contribute to thermoelectric operation. Since we would like to use the cooling power at the cold junction to cool an external device, it is important that the heat generated at a resistance reducer due to Peltier effect does not leak back to the cold junction. This may be achieved by counteracting or canceling this generated Peltier heat with the Peltier cooling power generated at the resistance reducer as the current leaves the resistance reducer, which requires its dimensions, material, or both, to be chosen in a specific way as discussed so we can control resistance and electrical current flow. Controlling resistance and electrical current flow can influence both Peltier cooling/heating and Joule heating. It is possible to interleave semiconductive materials and conductive materials to allow Peltier cooling to counteract Peltier heating and/or Joule heating as heat is transferred by charge carriers between the hot and cold junctions, possibly even with additional input current being provided to the resistance reducers. A series of resistance reducers, each with a hot junction and a cold junction disposed between the hot and cold junctions of the thermoelectric device can help prevent heat leakage back from the hot junction to the cold junction of the thermoelectric device. This helps the performance of a thermoelectric device. In addition, the lower resistance results in less Joule heating. It is also possible to use Peltier cooling to help counteract Joule heating, Peltier heating, or both.

Next, we refer to an example of a second thermal leg, such as the thermal leg 160 shown in FIG. 9(d) to explain more about the operation of the resistance reducers of some thermoelectric device embodiments. Electric current 164 flows from the hot junction 163 through conductive material 166, which could serve as a contact for example. For the thermal leg in this Figure, we assume that the semiconductive material is n-type material. As the current enters a first semiconductive material such as 167 from a conductive material such as 166, it causes heating at the junction with conductive material 166. The electric current also causes cooling as it leaves the first semiconductive material 167 and enters the first resistance reducer 168, which can be a second conductive material similar to 166. Similarly, as current leaves the first resistance reducer 168 and enters the next semiconductive material 167 it also causes heating at the junction. Accordingly, one junction of the resistance reducer is heated while the other junction of the resistance reducer is cooled. For instance, the upper junction between the first resistance reducer 168 and the first semiconductive material 167 is cold, while the lower junction between the first semiconductive material 167 and the next semiconductive material 167 is hot. Since the conductive material is likely to have a lower electrical resistivity than semiconductive material, using it between the hot and cold junctions reduces the total resistance seen by the electric current as it flows from one junction to another. In essence, this is an example of what the resistance reducers contribute to thermoelectric operation. Thus, we may have some number of resistance reducers disposed between the hot and cold junctions of a thermoelectric device—each having its own hot junction and cold junction. Resistance reducers operate to lower the effective resistance of semiconductive material, whether the material is p-type or n-type. Resistance reducers can also be used to help guide electric current through a thermoelectric device.

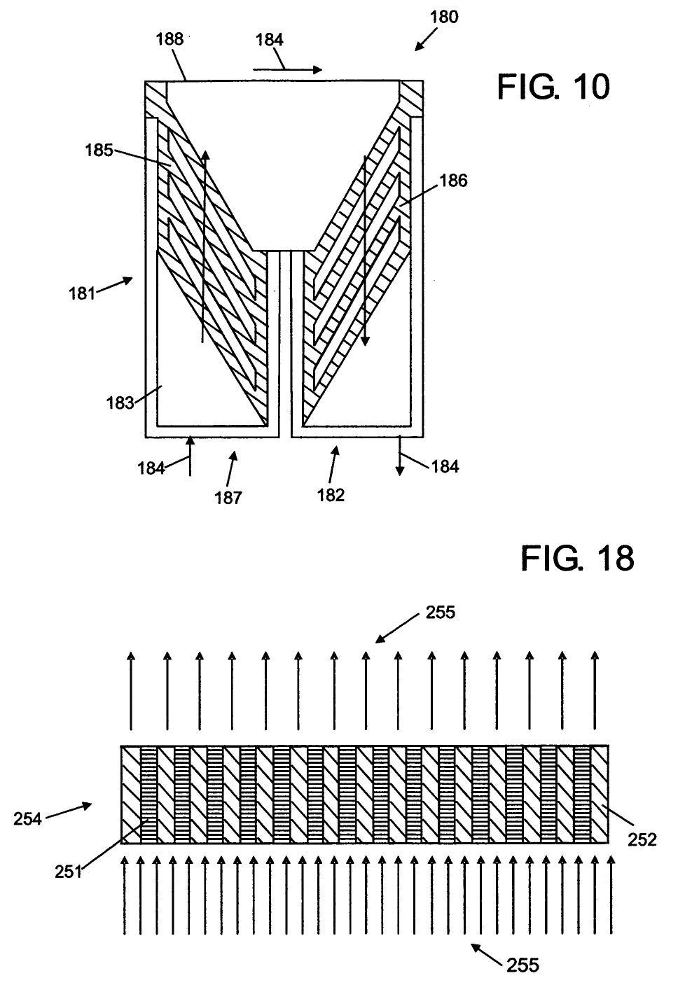

There are many other possible ways in which electrical current can be controlled and directed through a thermoelectric device embodiment still within the scope of the present invention, as those skilled in the art will understand. As another example, we will refer to some thermoelectric device embodiments such as 180 shown in FIG. 10. This figure shows a thermoelectric device 180 containing various interconnected thermal legs, such the left p-type thermal leg 181 and the right n-type thermal leg 182. Current 184 is directed through the device as shown by the arrows. For example, the resistance of conductive material such as 183 is generally lower than the resistance of p-type semiconductive material such as 185 or the resistance of n-type semiconductive material such as 186. Electrical current 184 entering the hot junction 187 at the bottom is forced to pass through p-type semiconductive material 185 on its path to the cold junction 188 at top because the semiconductive material is placed in series with the direction of current flow. The current can also flow down through n-type semiconductive material such as 186 and exit the right thermal leg at the bottom as shown. For this example, the differences in electrical resistance between conductive and semiconductive materials are also used to control and direct the current without the needing an insulator. Of course, an insulator can be used to help control and guide current.

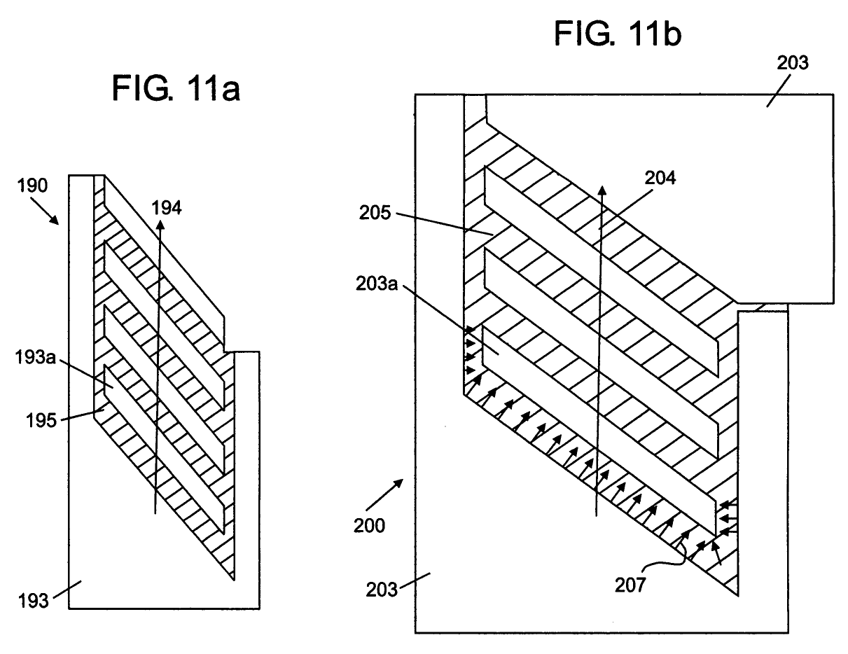

FIGS. 11(a) and 11(b) describe two other families of thermoelectric device embodiments. FIG. 11(a) shows a view of a thermal leg 190 containing controlled and directed electric current flow 194. The current is directed through conductive material 193 having a lower resistance than semiconductive material 195. In addition, the electrical current passes through semiconductive material 195 and intervening conductive material 193(a). This pattern is repeated along the span of the thermal leg, thus lowering the effective resistance seen by the current and directing the current flow vertically as shown. FIG. 11(b) is used to illustrate the operation of electric forces that assist thermoelectric operation in some embodiments of the present invention. Thermal leg 200 has electrical current 204 flowing vertically through the leg. In particular, the current flows into conductive material 203, through semiconductive material 205, through another conductive material 203(a) operating as a resistance reducer. The current flow though the alternating and interleaved conductive/semiconductive material segments is repeated as shown. The resulting electric field forces are shown by the arrows labeled 207. The electric field is always perpendicular to the surface and the total electrical force at a point is the vector some of all individual force vectors generated by each charge, as shown. The charge may be oriented as shown in the Figure by the force vectors. Note that the least resistance path through this interleaved structure is a function of the material used, its doping if any, its length, and its cross sectional area. We can design the resistances of the conductive and semiconductive segments to controllably guide the current through the leg as desired. Note that as the current 204 flows up vertically through the device, the voltage drop increases as well since more resistance is encountered by the current flowing through the interleaved conductive/semiconductive areas.

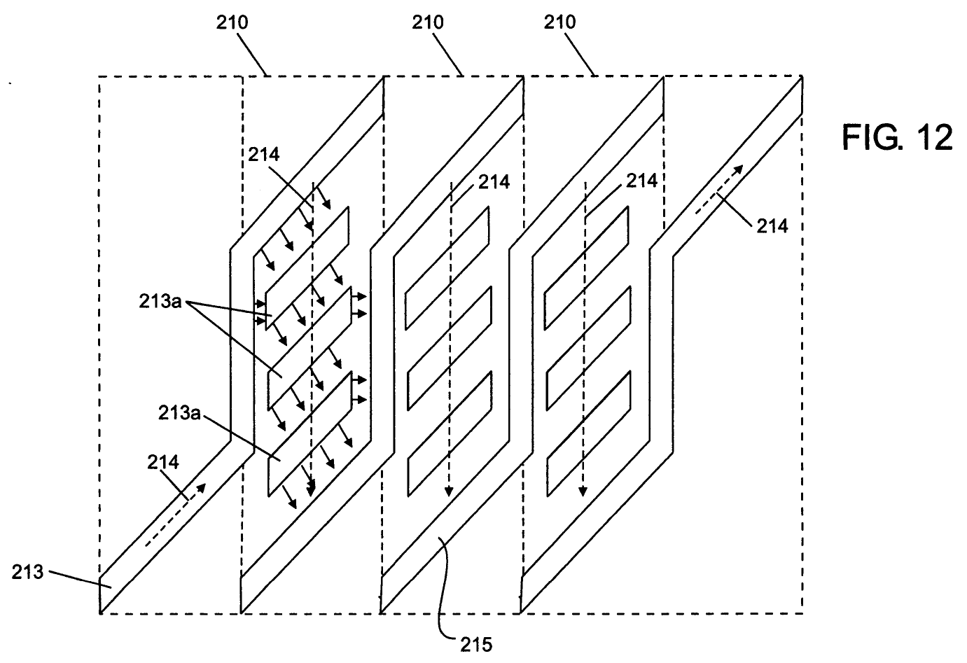

FIG. 12 shows that there are many creative ways to leverage electric forces and differences in electrical resistance for controlling and guiding current through thermoelectric legs and devices. Also, by controlling and guiding the electrical current, additional types of thermoelectric structures may be created and used. The Figure shows a series of similar thermal legs such as 210. Using this serpentine arrangement, it is possible to create a thermoelectric device using thermal legs that have similar semiconductive materials. As described, conventional thermoelectric devices use legs that have alternating types of semiconductive materials. For example, a leg having n-type semiconductive material would be connected serially electrically and parallel thermally to another leg having p-type semiconductive material therein. In this Figure, we note that current 214, shown by the dashed arrow for readability, enters the first thermal leg such as 210. Electric forces such as 217 are summed as noted above, resulting in electric current 214 flowing vertically down the first and leftmost leg 210. The current passes through semiconductive material 217 and through other intervening conductive segments/resistance reducers such as 213(a). The current ultimately reaches another serpentine conductive material 215 that guides the current to the next leg as shown. It is noted that with this structure, thermoelectric operation is achieved using thermal legs having similar semiconductive material segments such as 217. That is, for these embodiments the semiconductive materials used could all be p-type or they could all be n-type yet still support thermoelectric operation.

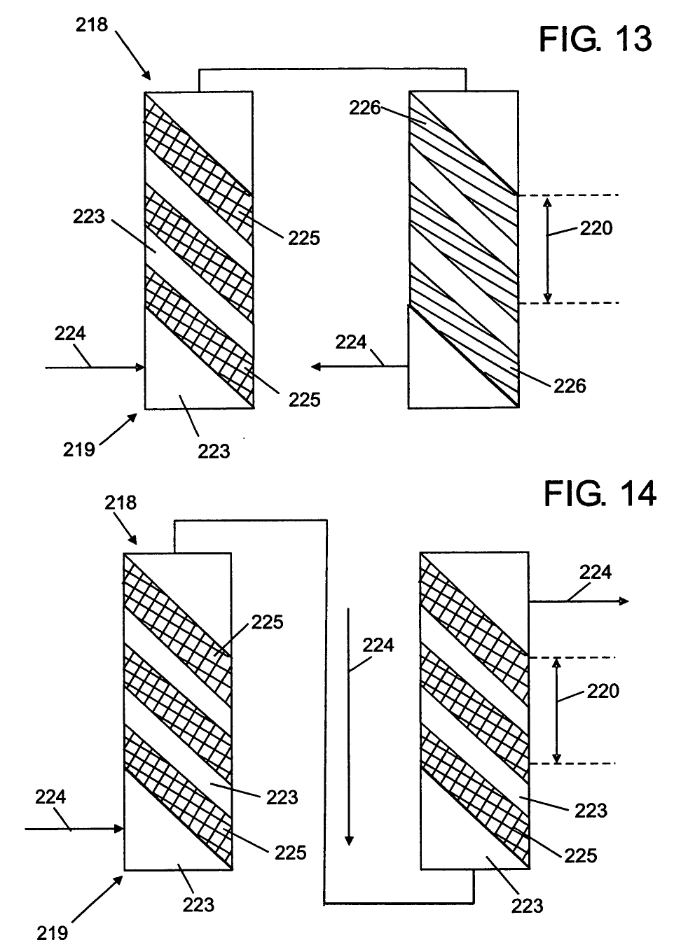

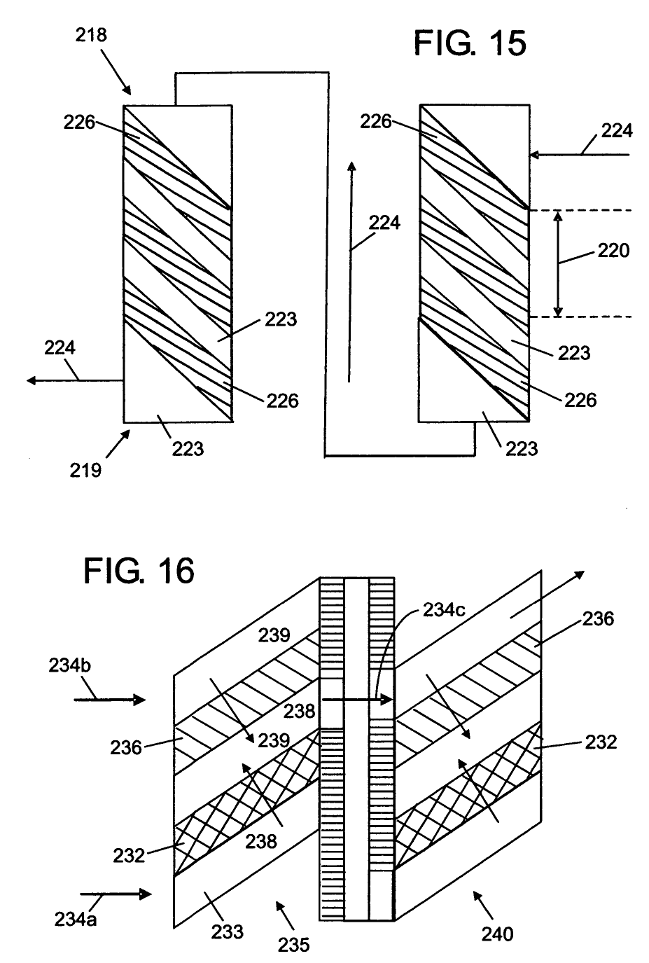

FIGS. 13, 14, and 15 help us elaborate this feature of some thermoelectric device embodiments. For these Figures, the hot side of the thermal legs is shown as 218, while the cold side is shown as 219. The distance between the hot and cold sides or junction is shown as 220. Electrical current 224 flows through the various thermal legs as shown by the arrows. P-type semiconductive material is represented by 225, while n-type semiconductive material is represented by 226. Further, the conductive material is shown as 223 in the Figures. FIG. 13 illustrates an example in which adjacent thermal legs use p-type and n-type semiconductive material segments. In this Figure, the differently semiconductive legs are connected in parallel thermally yet serially electrically as shown. FIG. 14 shows an example in which adjacent thermal legs use only p-type semiconductive materials. For this Figure, the similarly p-type semiconductive legs are connected in parallel thermally, but daisy chained electrically as shown. FIG. 15 illustrates an example in which only n-type semiconductive materials are used. Comparably, the similarly n-type semiconductive legs are connected in parallel thermally, but daisy chained electrically as shown. The direction of electrical current flow obviously differs between solely p-type and solely n-type thermoelectric embodiments. By modifying how adjacent thermal legs are interconnected, both electrically and thermally, it is possible to create thermoelectric devices using various types of semiconductive materials as per the above.

As noted, at least some thermoelectric device embodiments control the flow of electric current to assist thermoelectric operation. FIG. 16 illustrates an example of a thermoelectric device having current summing in a thermal leg, according to some embodiments of the present invention. A left thermal leg 235 and a right thermal leg 240 are shown. Current 234(a) enters the left thermal leg 235 at the bottom cold junction 238 through conductive material 233 at the bottom. Similarly, current 234(b) enters the left thermal leg 235 at the top hot junction 239 through conductive material 233 at the top. Current 234(a) enters semiconductive material 232, which could be p-type material for example, as shown by the rising arrow through 232. In addition, current 234(b) enters semiconductive material 236, which could be n-type material for example, as shown by the descending arrow through 236. As current 234(a) enters the bottom of the conductive material segment in the middle, that is the conductive material shown disposed between semiconductive materials 232 and 236, a hot junction is created at the bottom of the middle conductive segment. Also, as current 234(b) enters the top of the conductive material segment in the middle, a cold junction is created at the top of the middle conductive segment. As such, Peltier cooling and Peltier heating counteract each other in the middle conductive material. At the same time, a hot junction 239 is created at the top of the left thermal leg and a cold junction 238 is created at the bottom of the thermal leg. Currents 234(a) and 234(b) are summed electrically in the middle conductive material and exit into the right thermal leg 240 as combined current 234(c). Similar Peltier effects may occur in the right thermal leg as the current flows through conductive materials and semiconductive materials. The combined electric current could be split, as shown by the two arrows leaving the top conductive material segment in the right thermal leg 240. Thus, it is possible to create many series, parallel, and combination electrical connections between conductive and semiconductive materials used within and between thermal legs to support thermoelectric operation in various thermoelectric embodiments of the present invention. It is also possible to divide electric current instead of summing it as needed to help support thermoelectric device operation.

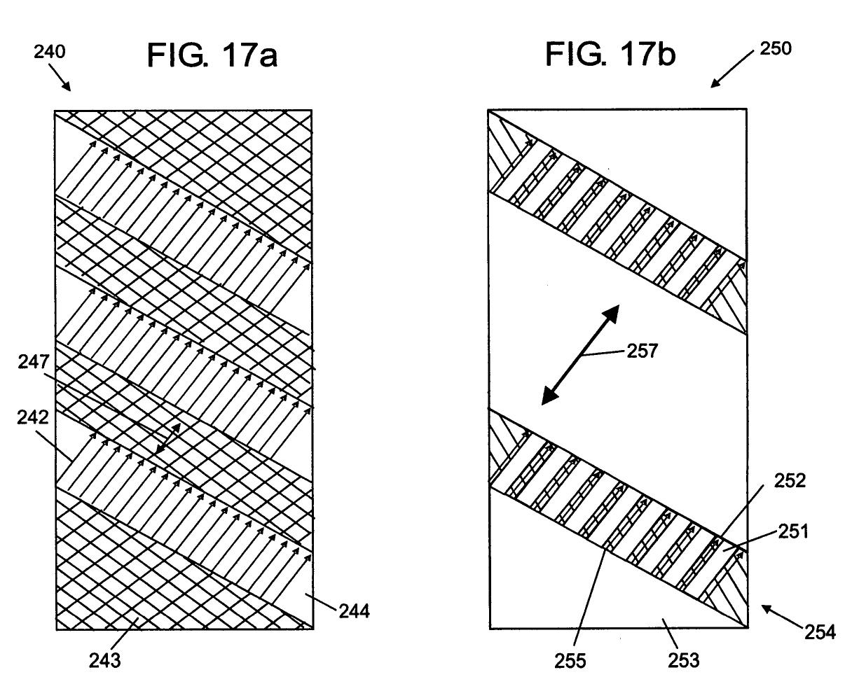

It is also possible to create improved thermal leg embodiments and thermoelectric device embodiments by leveraging nanotechnology developments. FIGS. 17(a) and 17(b) are diagrams illustrating possible differences in the separation possible within thermoelectric legs according to some thermoelectric device embodiments of the present invention. FIG. 17(a) shows a thermoelectric leg embodiment 240 similar to some previously described. Thermal leg 240 contains various conductive material segments such as 243. In addition, the thermal leg contains various semiconductive material segments such as 244. The electric current flows through the semiconductive segments as shown by arrows 242. The possible separation 247 is determined by trading off the increase in thermal isolation against the increased electrical resistance. Ideally, it helps thermoelectric operation to increase the separation and resulting thermal isolation between the hot and cold junctions of the device. One way to accomplish this is by increasing the size of the conductive materials between the junctions. To optimize thermal isolation, the length of the conductive material segments can be defined to allow the Peltier cooling and Peltier heating in the conductive segment to counteract each other and hopefully effectively cancel. Peltier cooling generated by the current as it enters the conductive material will counteract the Peltier heating generated by the current leaving the conductive material, if the semiconductive material areas were p-type for example. However, increasing the size of the conductive material areas also increases electrical resistance, which produces counterproductive Joule heating. Thus it seems logical to increase the size of the conductive material segments to improve thermal isolation since they generally have lower electrical resistance than semiconductive material segments. However, as noted there are limitations in how large the separation 247 could be given the tradeoff and the need to support effective thermoelectric function. It would help thermoelectric function to manage the increase in resistance while providing better thermal isolation.

It is also possible to improve thermal isolation by selecting materials with higher thermal resistance, and hopefully not correspondingly higher electrical resistance. In recent years, researchers have illustrated that the thermal conductivity of certain nanomaterials changes as their thickness goes down to nanometers. Using this phenomenon, we can increase the length of the conductive material using nanomaterials as the semiconductive material while allowing the Peltier heating and Peltier cooling at the two edges of the conductive material runner to counteract each other. This is illustrated by FIG. 17(b) which illustrates an example of a thermoelectric leg embodiment using nanomaterials that can provide a larger separation. Nanomaterials including carbon nanotubes, other nanotubes, silicon nanowires, other nanowires, other nanostructures, others described before, and the like may be used. This Figure shows an example thermal leg 250 including conductive material areas such as 253. The semiconductive area 254 can include one or more nanomaterial semiconductive segments such as 252, optionally isolated by insulating segments such as 251. It is possible to arrange a number of interleaved nanomaterial areas and insulating areas either in series or in parallel. For example, the nanomaterials areas and insulating areas in FIG. 17(b) are placed electrically in parallel such that electrical current 255 flows through semiconductive area 254.

In particular, if the thermal conductivity of conductive material x is k(x), x=1, 2, 3, then the length of conductive material can be proportional to k(3)/k(1) and k(3)/k(2). Without loss of generality, let us assume that the width of the insulating segments 251 and nanomaterial semiconductive segments 252 are the same, equal to w, and w is on the order of 10's of nanometers or thereabouts. This would cause the electrical resistance of the semiconductive area 254 to double, since the width of the material through which the current can flow has been reduced by half. However, given the characteristics of the nanomaterials, the thermal resistance of the semiconductive area 254 is increased, depending on the value of w. That would mean that the length of the conductive material areas such as 253 that connect two semiconductive areas such as 254 can be increased by w times. At the same time, this allows the Peltier heating and Peltier cooling to counteract each other within the conductive material while not increasing the electrical resistance unacceptably. This flexibility can then be used to improve thermal isolation between the hot and cold junctions while managing the total electrical resistance of a thermal leg. FIG. 18 illustrates a zoomed in view of an example thermoelectric leg embodiment using nanomaterials. As those skilled in the art will appreciate, there are many other permutations and combinations possible that leverage nanomaterials in various embodiments according to the present invention. Note that electrical current 255 flows through semiconductive area 254 as shown as it encounters the nanomaterial semiconductive segments such as 252 in parallel and electrically isolated by insulating areas such as 251.

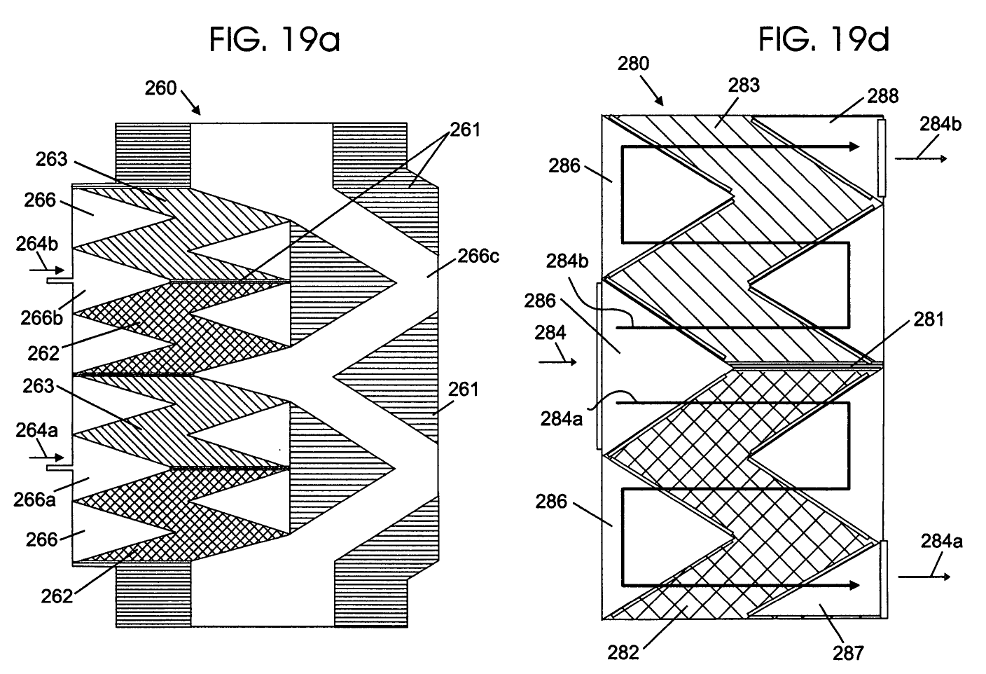

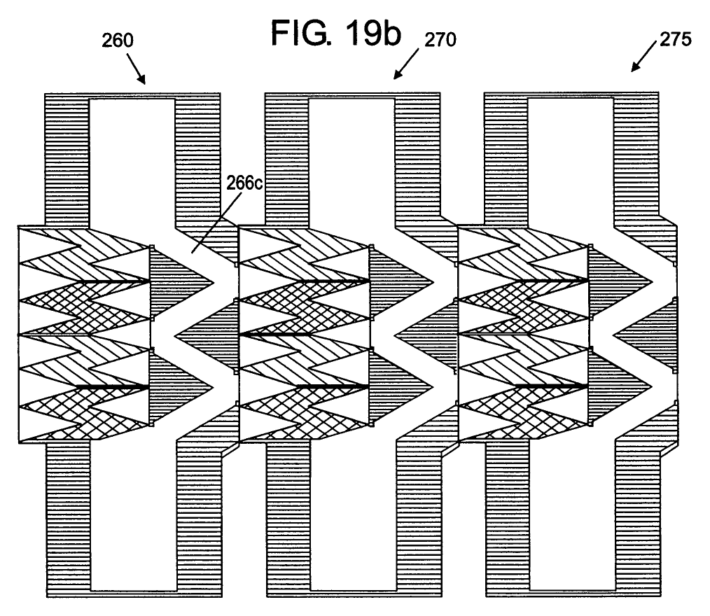

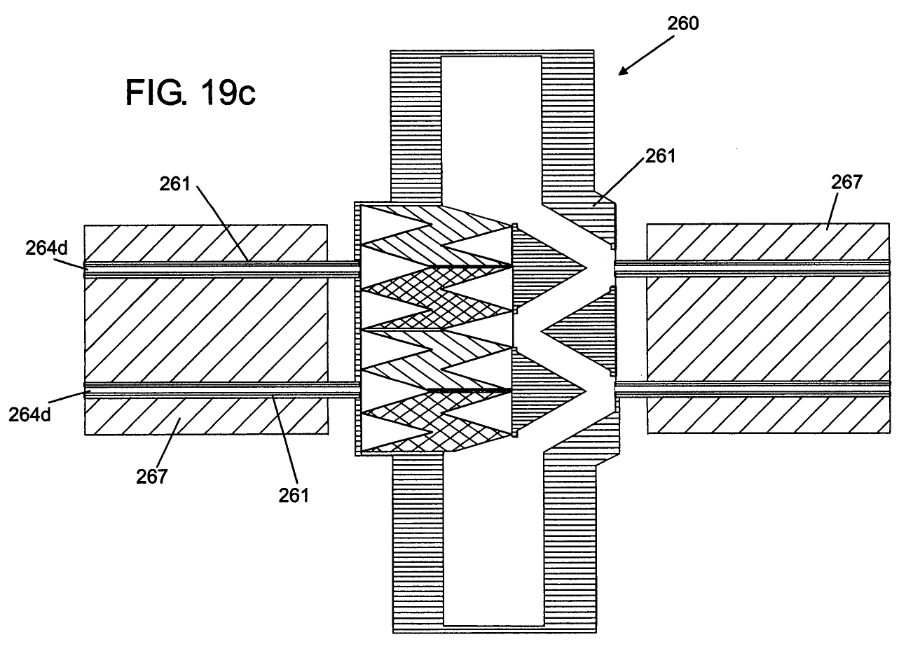

FIGS. 19(a), 19(b), 19(c), and 19(d) illustrate some thermoelectric device structure embodiments and thermoelectric thermal leg embodiments according to the present invention. First, FIG. 19(a) illustrates a thermoelectric leg embodiment 260 which has guided and controlled electrical current flow through the leg. Conductive material segments, such as 266, 266(a), 266(b), and similarly designated conductive material areas are shown. Electrical currents, such as 264(a) and 264(b), enter the thermal leg in parallel from the left through conductive material segments in at least two points, such as through conductive material segments 266(a) and 266(b) respectively as shown. Insulators such as 261 and similarly designated insulating areas can be used to electrically isolate the different semiconductive material areas. In addition, the placement of the insulators as shown can cause each incoming current to divide, such as how current 264(a) is caused to split and enter p-type semiconductive material area 262 and n-type semiconductive material area 263 adjacent to conductor 264(a), for example. The placement of the relatively high resistance insulator 261 can help guide the current from the conductive material and cause it to divide and enter the respective split semiconductive material areas. The current can divide in accordance with the respective resistances presented to the current by the p-type semiconductive material areas, n-type semiconductive material areas, and conductive material areas, as those skilled in the art will appreciate. Once current passes through the respective semiconductive areas such as 262 and 263, the respective currents may enter another conductive material area such as 266(c) and recombine therein. As shown in FIG. 19(b), the recombined currents exiting thermal leg 260 can then enter into the next thermal leg 270 and later into the third thermal leg such as 275. As such, the thermoelectric effects can be integrated as currents flow between adjacent thermal legs. Within each thermal leg, the currents first divide in the semiconductive material areas and then recombine in the conductive areas leading to an adjacent thermal leg. In FIG. 19(c), we also illustrate the interconnections to and from thermal leg 260, such as with wires 264(d) made of conductive material. In addition, a surface conductive pad such as 267 is shown. The two surface pads connected to the left thermal leg and to the right thermal leg are used to apply electrical power to the thermal legs in Peltier mode operation. FIG. 19(d) shows a thermoelectric leg 280 having a different current routing structure than described above. Here, current 284 enters from the left as shown, and divides into currents 284(a) and 284(b) as shown. The currents enter conductive areas 286 as shown. Thereafter, currents 284(a) and 284(b) enter into p-type semiconductive area 282 and n-type semiconductive area 283 respectively. They each follow the serpentine path through the respective conductive and semiconductive areas and exit as currents 284(a) and 284(b) at the hot junction 287 and cold junction 288 respectively. Note that insulator 281 electrically isolates and separates the respective n-type and p-type semiconductive areas and causes the currents to flow as shown. In essence, the design of the resistances of the conductive areas, semiconductive areas, and insulators are used to control and guide electric currents through various thermoelectric leg embodiments.

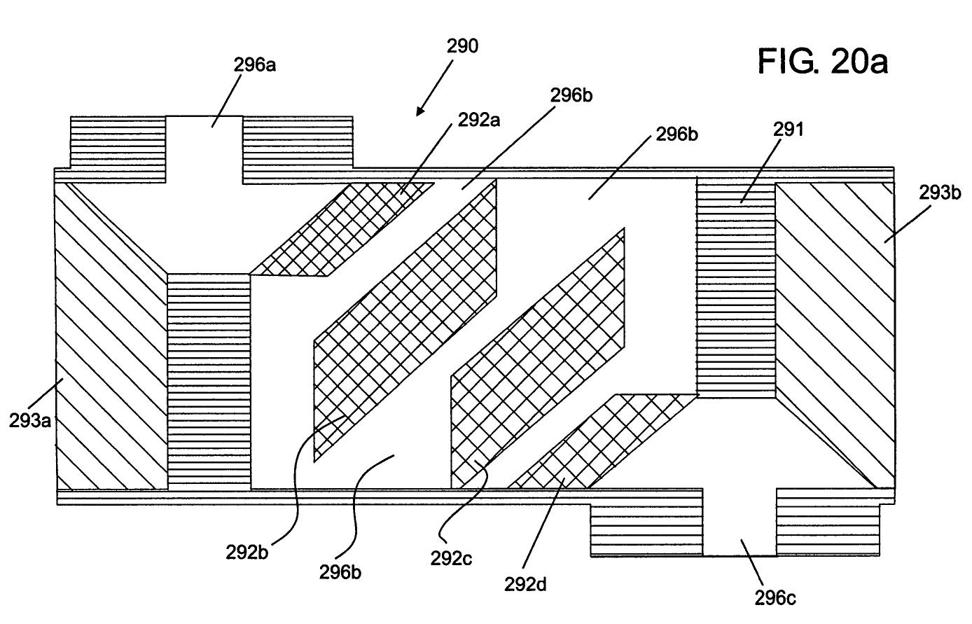

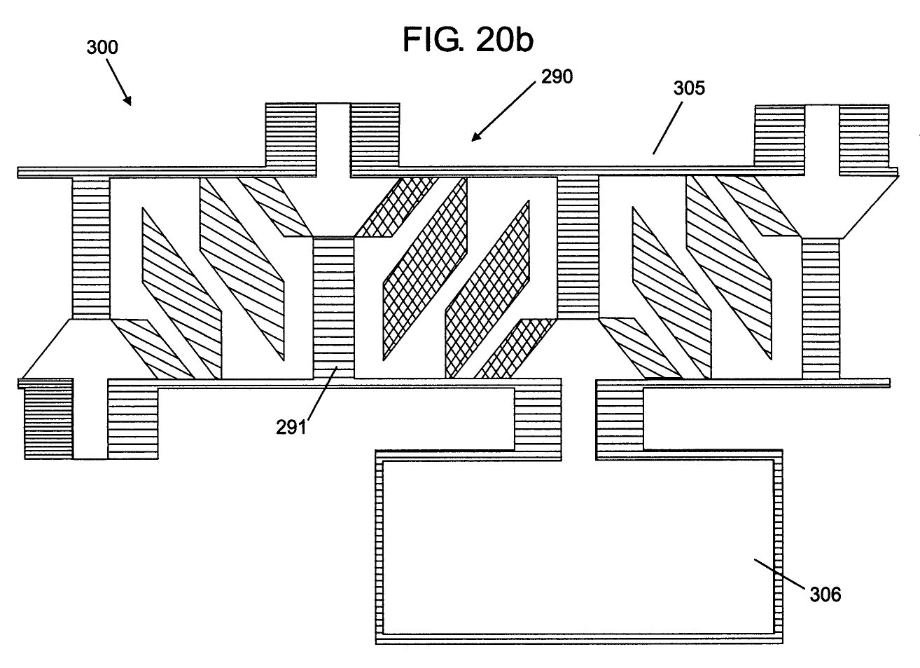

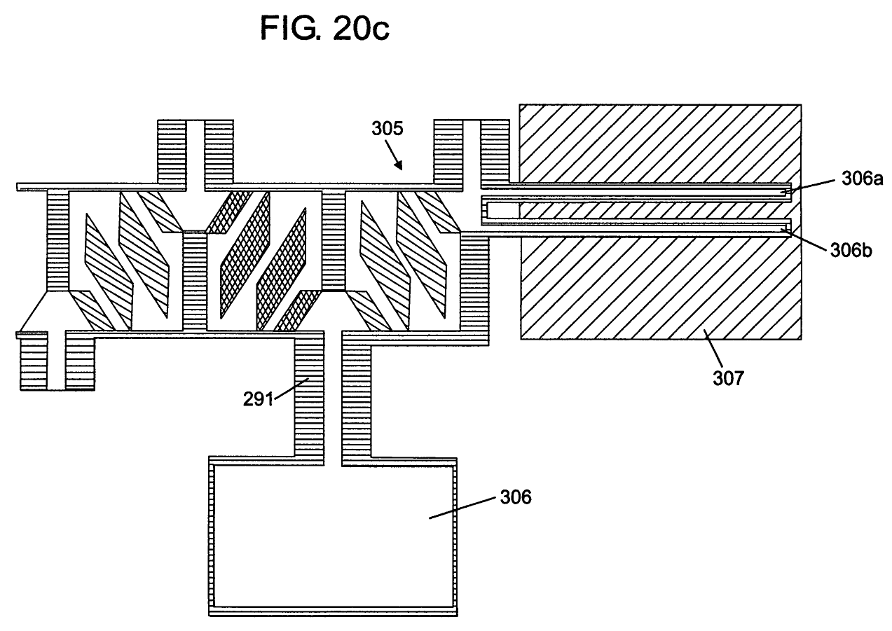

FIGS. 20(a), 20(b), and 20(c) show some thermoelectric device structure embodiments and thermoelectric thermal leg embodiments according to the present invention. FIG. 20(a) illustrates a thermoelectric leg embodiment 290 which has guided and controlled electrical current flow through the leg. Conductive material segments, such as 296(a), 296(b), and 296(c) are shown. Electrical current can enter the top conductive material area 296(a). The current will divide according to the respective resistances through the electric paths through n-type semiconductive material 293(a) and p-type semiconductive material 292(a), and flow accordingly. The current through p-type semiconductive material 292(a) will flow through alternating conductive material segments 296(b) and p-type semiconductive material segments 292(b)-(d), eventually reaching conductive material segment 296(c). Insulator 291 is disposed as shown, used to separate the respective semiconductive areas of different types, and used to help control and guide the current through the structure by design. FIG. 20(b) illustrates one possible interconnection between alternating thermoelectric leg embodiments such as thermal leg 290 that includes p-type semiconductive material therein, and thermal legs 300 and 305 each including n-type semiconductive material therein. In addition, a relatively large conductive material pad 306 may be used to increase the conductive area of the junction of the thermal leg connected thereto to help better transfer thermal energy into and out of the thermal leg. In FIG. 20(c), we also illustrate the interconnections to and from thermal leg 305, such as with wires 306(a) and 306(b) made of conductive material. In addition, a surface conductive pad such as 307 and relatively large conductive material pad 306 are shown. The two surface pads connected to the left thermal leg and to the right thermal leg are used to apply electrical power to the thermal legs in Peltier mode operation as noted. The relatively larger conductive pads help with thermal energy transfers as described.

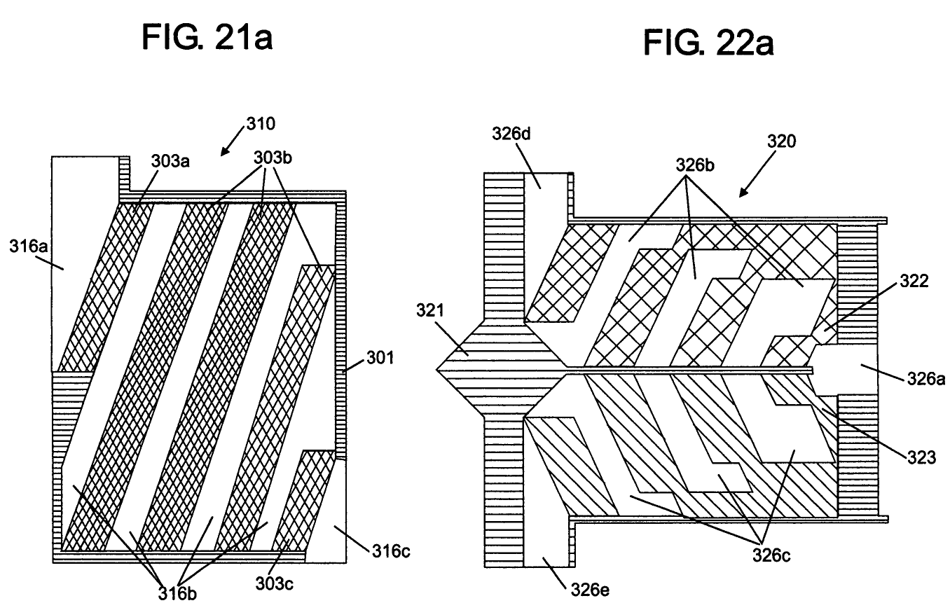

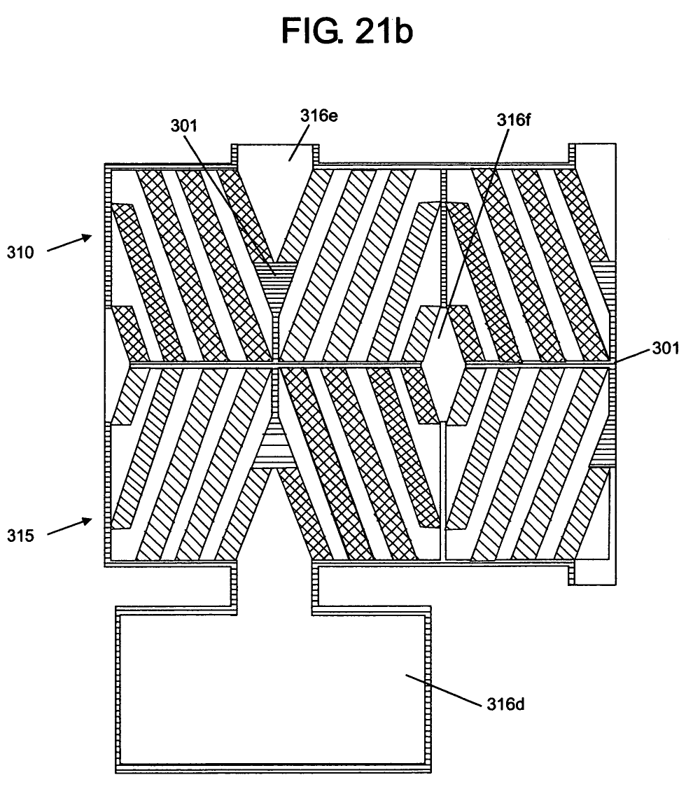

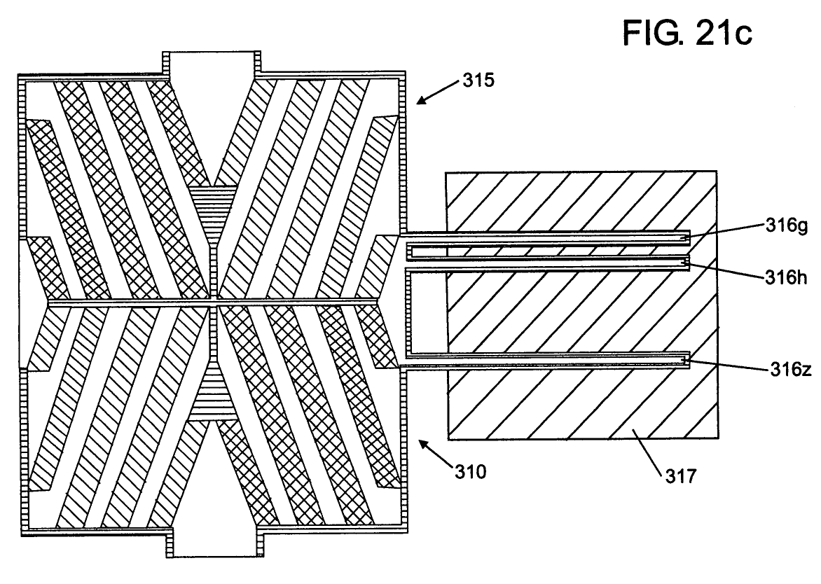

FIGS. 21(a), 21(b), and 21(c) show some thermoelectric device structure embodiments and thermoelectric thermal leg embodiments according to the present invention. FIG. 21(a) illustrates a thermoelectric leg embodiment 310 which has guided and controlled electrical current flow through the leg. Conductive material segments, such as 316(a), 316(b), and 316(c) are shown. Electrical current can enter the top conductive material area 316(a). The current will flow through the alternating p-type semiconductive material segments 303(a), 303(b), and 303(c) interleaved with conductive material segments 316(b). Eventually the current reaches conductive material segments 316(c) and can exit thermal leg 310. Insulator 301 electrically isolates the interfaces of the thermal leg and supports current flow as described. The design of the resistances of the conductive areas, semiconductive areas, and insulators are used to control and guide electric currents through various thermoelectric leg embodiments. FIG. 21(b) illustrates one possible interconnection between alternating thermoelectric leg embodiments such as thermal legs 310 including p-type semiconductive material therein, and thermal legs 315 including n-type semiconductive material therein. Note that the current can enter conductive area 316(e) at the top. The current can divide and flow through the parallel n-type material area to the right and through the p-type material area to the left as discussed before. Further, the currents can recombine at conductive material segments like 316(d) or 316(f). In addition, a relatively large conductive material pad 316(d) is used as described above for thermal heat transfers. In FIG. 21(c), we also illustrate the interconnections to and from thermal leg 315, such as with wires 316(g) and 316(h) made of conductive material. Also shown is an interconnection to thermal leg 310, such as with wire 316(i) made of conductive material. In addition, a surface conductive pad such as 317 is shown used for supplying power in Peltier mode as described.

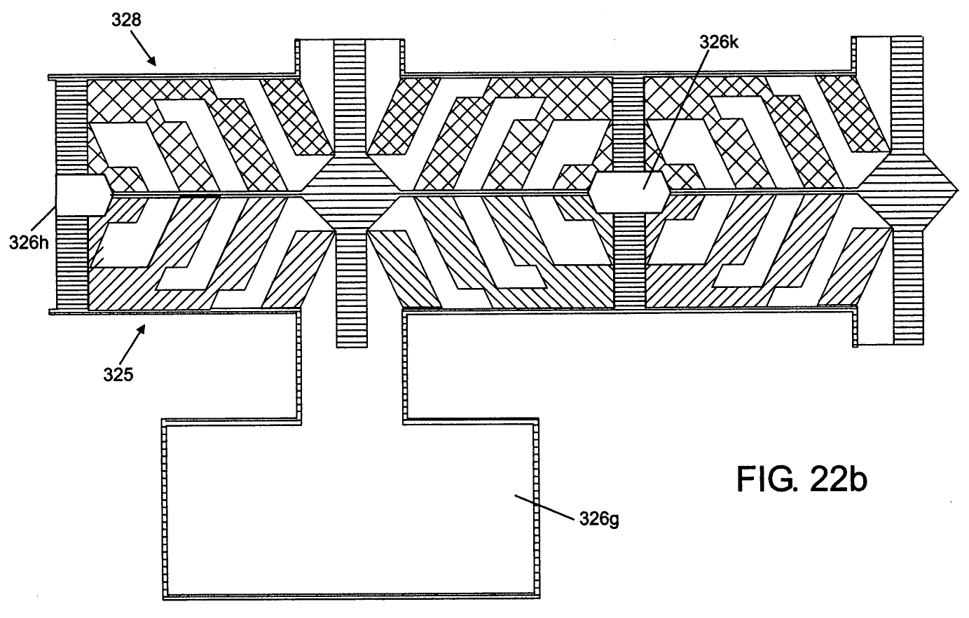

FIGS. 22(a), 22(b), and 22(c) show some thermoelectric device structure embodiments and thermoelectric thermal leg embodiments according to the present invention. FIG. 22(a) illustrates a thermoelectric leg embodiment 320 which has guided and controlled electrical current flow through the leg. Conductive material segments, such as 326(a)-326(e). Electrical current can enter the rightmost conductive material area 326(a). The current will divide and flow in parallel to the bottom through parallel n-type material areas such as 323 and to the top through p-type material areas such as 322 as discussed before. Each current will pass through alternating conductive material segments such as 326(b) and 326(c) and the interleaved semiconductive material areas 322 and 323 respectively. Insulator 321 electrically isolates the interfaces between semiconductive areas in the thermal leg and supports current flow as described. Eventually the divided currents exit the structure through conductive materials 326(d) and 326(e). FIG. 22(b) illustrates one possible interconnection between alternating thermoelectric leg embodiments such as thermal legs 328 including p-type semiconductive material therein, and thermal legs 325 including n-type semiconductive material therein. Note that the current can enter conductive area 326(h) from the left as shown. The current can divide and flow through the parallel n-type material area and p-type material area as discussed before. The currents from the top and bottom thermal leg structures combine at some conductive areas such as 326(h) and 326(k). Areas such at these are places at which the hot and cold junctions are in close proximity and cancel each other thermally. This helps in isolating the hot and cold junctions of the thermal leg structures such as 326(d) and 326(e) from each other. In addition, a relatively large conductive material pad 326(g) is used as discussed above. In FIG. 22(c), we also illustrate an interconnection to thermal leg 320, such as with wire 326(i) made of conductive material. In addition, insulator 321 and a surface conductive pad such as 327 as per above are shown.

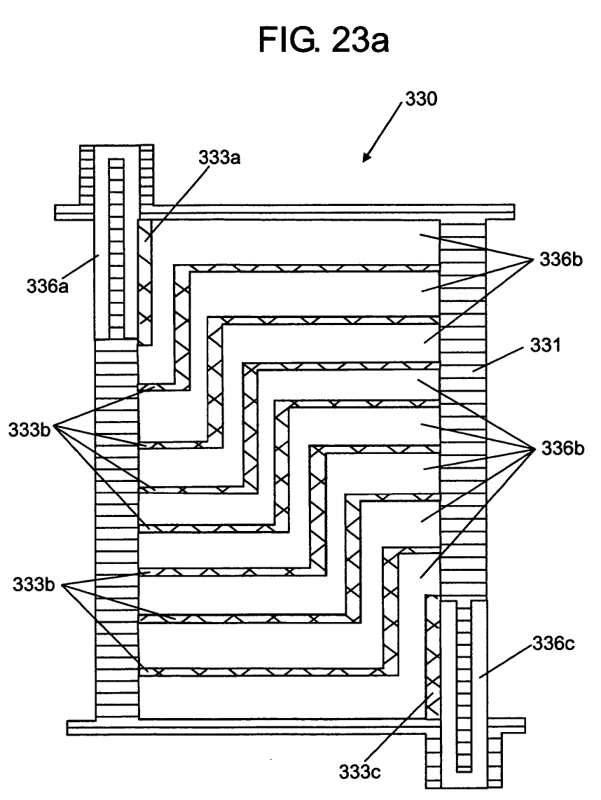

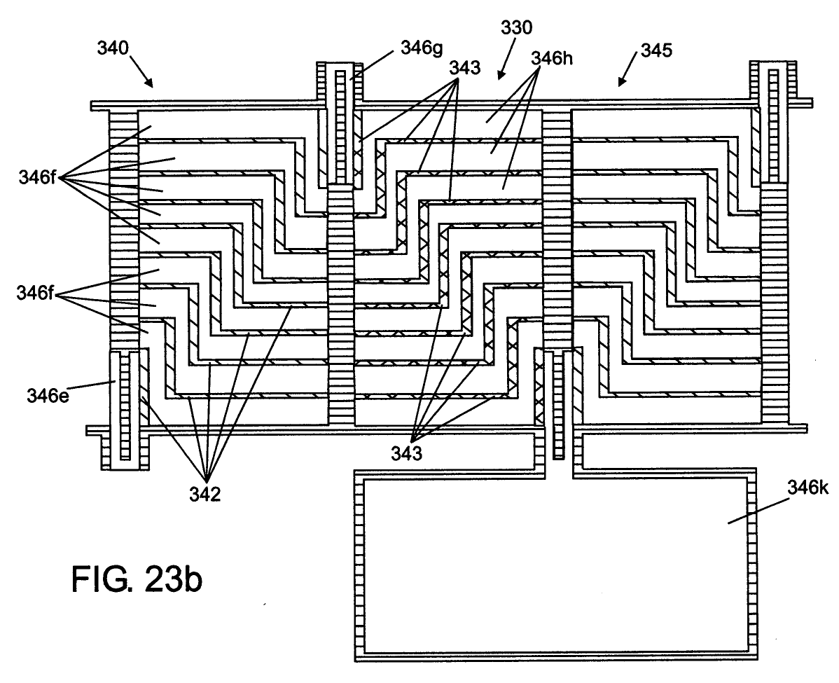

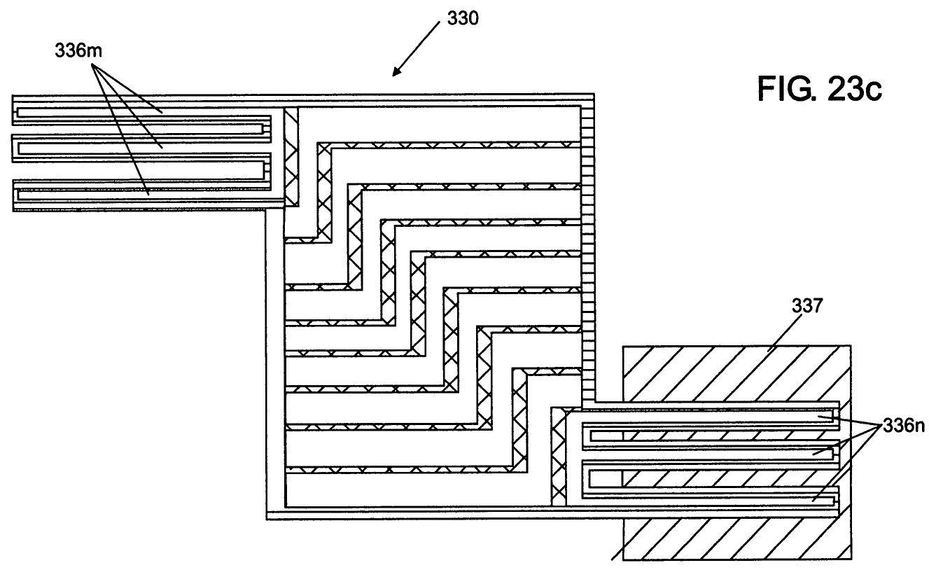

FIGS. 23(a), 23(b), and 23(c) show some thermoelectric device structure embodiments and thermoelectric thermal leg embodiments according to the present invention. FIG. 23(a) illustrates a thermoelectric leg embodiment 330 which has guided and controlled electrical current flow through the leg. Conductive material segments, such as 336(a), 336(b), and 336(c) are shown. Electrical current can enter the top conductive material area 316(a). The current will flow through the alternating p-type semiconductive material segments 333(a), 333(b), and 333(c) interleaved with conductive material segments 336(b). Eventually the current reaches conductive material segments 336(c) and can exit thermal leg 330. Insulator 331 electrically isolates the interfaces of the thermal leg and supports current flow as described. The design of the resistances of the conductive areas, semiconductive areas, and insulators are used to control and guide electric currents through various thermoelectric leg embodiments. FIG. 23(b) illustrates one possible interconnection between alternating thermoelectric leg embodiments such as thermal legs 330 including p-type semiconductive material therein, and thermal legs 340 and 345 adjacent to 330 at the sides including n-type semiconductive material therein. Note that the current can enter conductive area 346(e) at the left through thermal leg 340. The current can flow through the alternating n-type semiconductive material areas such as 342 and conductive material areas such as 346(f). Further, the current can enter the adjacent p-type thermal leg 330 through conductive material segment like 346(g). The current can then flow through the alternating p-type semiconductive material areas such as 343 and conductive material areas such as 346(h). As such, this can be repeated between adjacent thermal legs as shown. In addition, a relatively large conductive material pad 316(k) is used as previously discussed. In FIG. 23(c), we also illustrate the interconnections to and from p-type thermal leg 330, such as with wires 336(m) and 336(n) made of conductive material. In addition, a surface conductive pad such as 337 as noted previously is shown.

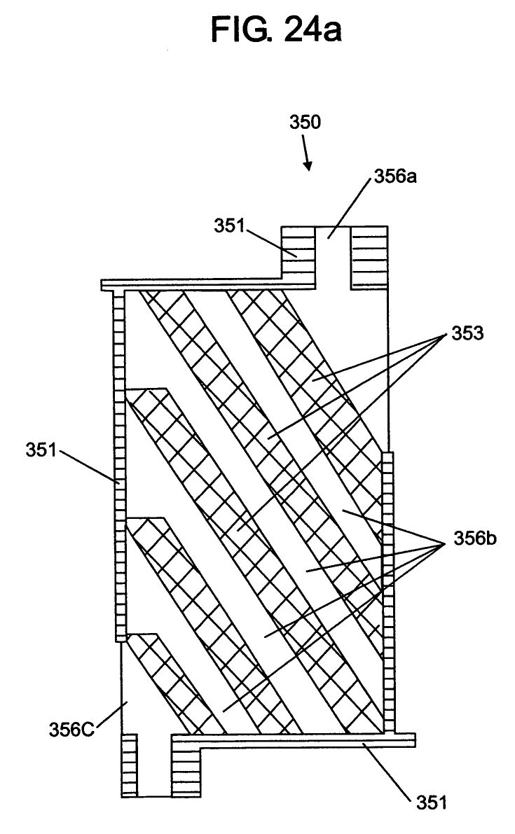

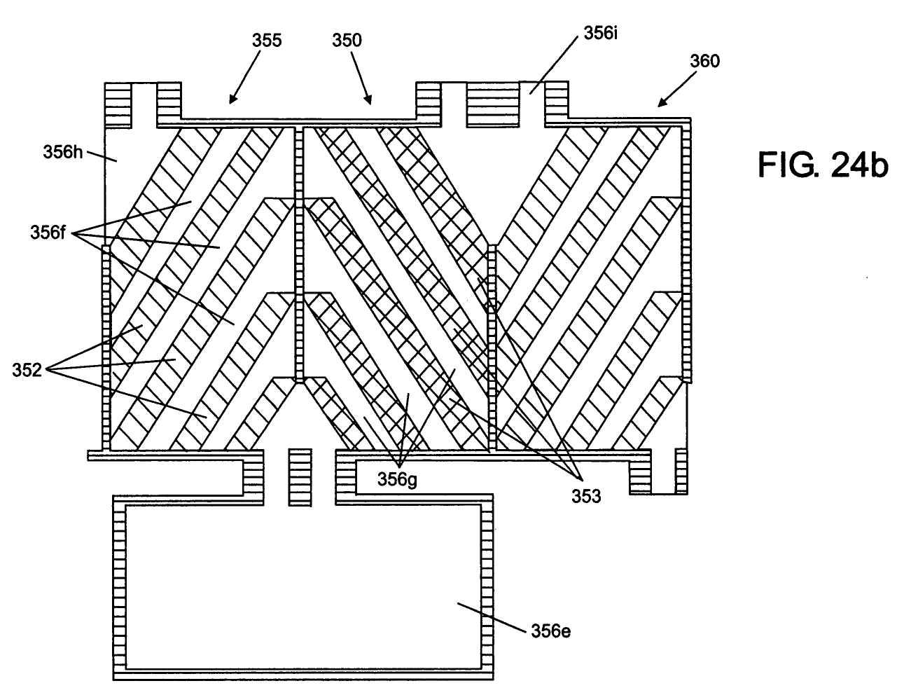

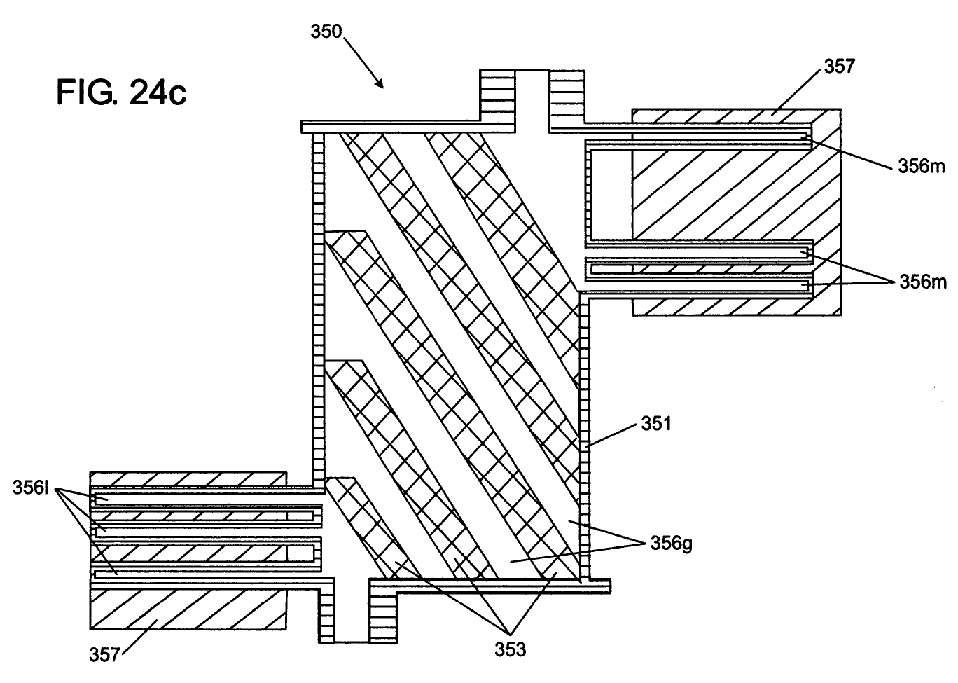

FIGS. 24(a), 24(b), and 24(c) show some thermoelectric device structure embodiments and thermoelectric thermal leg embodiments according to the present invention. FIG. 24(a) illustrates a thermoelectric leg embodiment 350 which has guided and controlled electrical current flow through the leg. Conductive material segments, such as 356(a), 356(b), and 356(c) are shown. Electrical current can enter the top conductive material area 356(a). The current will flow through the alternating p-type semiconductive material segments 353 interleaved with conductive material segments 356(b). Eventually the current reaches conductive material segments 356(c) and can exit thermal leg 350. Insulator 351 electrically isolates the interfaces of the thermal leg and supports current flow as described. The design of the resistances of the conductive areas, semiconductive areas, and insulators are used to control and guide electric currents through various thermoelectric leg embodiments. FIG. 24(b) illustrates one possible interconnection between alternating thermoelectric leg embodiments such as thermal legs 350 including p-type semiconductive material therein, and thermal legs 355 and 360 adjacent to 350 including n-type semiconductive material therein. Note that the current can enter conductive area 356(e) at the bottom near thermal legs 350 and 355. As such, the current can divide and flow into thermal leg 355 and thermal leg 350. Current into thermal leg 355 flows to the left and up through the alternating n-type semiconductive material areas such as 352 and conductive material areas such as 356(f). Current into thermal leg 350 flows to the right and up through the alternating p-type semiconductive material areas such as 353 and conductive material areas such as 356(g). Further, the current can leave n-type thermal leg 355 through conductive material segment like 356(h). In addition, the current can leave p-type thermal leg 350 through conductive material segment 356(i). Current from adjacent n-type thermal leg 360 can combine with current from p-type thermal leg 350 at conductive material segment 356(i). Of course, for any examples providing electrical current flow, the direction of current flows can be reversed. For example, a point at which currents are summed as current flows therethrough in one direction can become a point at which currents are divided as the direction of the current is reversed and current flows therethrough in the opposite sense. In addition, a relatively large conductive material pad 356(e) is used for thermal reasons as discussed. In FIG. 24(c), we also illustrate the interconnections to and from p-type thermal leg 350, such as with wires 336(l) and 336(m) made of conductive material. In addition, a surface conductive pad such as 357 such as previously discussed is shown.

Seebeck Electrical Power Generation Embodiments

Generally, all embodiments of thermoelectric legs, structures, elements, and devices provided above can function interchangeably as coolers, heaters, and electrical power generators. This is due in large part to the relationship between the Peltier effect and the Seebeck effect. In addition, thermoelectric structures useful for heating or cooling applications using the Peltier effect are typically also well suited structurally for electrical power generation using the Seebeck effect. Embodiments of the present invention can use the Peltier theory for any application in which a temperature gradient is required to be generated from electrical energy, such as for heating or cooling applications. In addition, embodiments of the present invention can also use the Seebeck theory for any application in which electrical energy is to be generated from a temperature gradient, such as for DC power generation applications. As such, thermoelectric device embodiments of the present invention can operate as Peltier coolers, Peltier heaters, or Seebeck electrical power generators. Peltier mode or Seebeck mode can occur depending on whether a thermoelectric device is being driven by thermal energy or electrical energy. Thermoelectric device embodiments subjected to a thermal temperature gradient between the hot and cold junctions can be used to generate electrical power between terminals connected to the hot and cold junctions through the Seebeck effect. The polarity of electrical current flow is determined by the direction of thermal energy flowing through a thermoelectric device. Conversely, thermoelectric device embodiments can provide heating or cooling between the hot and cold junctions when electrical current flows between the hot and cold junctions. Similarly, thermoelectric device embodiments can heat or cool reversibly by reversing the direction of the electrical current flowing through a given thermoelectric device embodiment.

Thermoelectric device embodiments can be operated to convert thermal energy gradients across the thermoelectric device into electrical power. As such, thermoelectric devices can operate as generators of DC electricity. The basic principle behind thermoelectric power generation is based on the heat flow from the hot junction to the cold junction in the absence of any applied electrical potential or voltage. In particular, the heat flux entering from the hot side, in other words the heat source, and the portion of the heat flux exiting the cold side, in other words the heat sink, create a potential difference between the hot and cold sides equal to
V=S*ΔT=I*R
where,
   ΔT=Th−Tc;
   Th: is the hot side temperature,
   Tc: is the cold side temperature,
   S: is the Seebeck coefficient,
   V: is the voltage generated,
   I: is the electric current, and
   R: is the electrical resistance.

The net electrical power produced by a thermoelectric device being driven by a thermal gradient across its hot and cold junctions as described can be transferred to an electrical load. The load may be connected between terminals connected to the hot side and cold side of a thermoelectric device. The electrical power delivered to an external load such as Rₑₓₜ and is equal to W=I²*Rₑₓₜ. The induced electrical current creates Joule heating as it flows through resistances in thermoelectric devices operating in Seebeck power generation mode, just as Joule heating is created during Peltier heating and cooling operation. The heat flux q entering the cold side junction of a thermoelectric device equals the heat absorbed by the Peltier junction, SITh, plus the heat flux into the hot junction of the thermoelectric device, since in Seebeck operation the heat source is applied to the cold junction and heat is transferred to the hot junction as electric power is generated across a load connected between the hot and cold junctions. As such, the heat flux entering the thermoelectric device is:
q=SITh−(0.5)I²*Rᵢₙₜ+K*ΔT,
where
   R: is the internal resistance of the device.
   K: is the thermal conduction of the semiconductor material times the thermal resistance of the thermal leg
      KΔT=thermal conductivity×cross sectional area/length×ΔT=the heat flux due to conduction from the hot junction to the cold junction through the thermoelectric device. The internal and external resistances added together comprise the total electrical resistance, Rₜₒₜ=Rᵢₙₜ+Rₑₓₜ. Hence, the electrical current, I, is the Peltier voltage divided by the total device resistance:
      I=SΔT/(Rᵢₙₜ+Rₑₓₜ)
      Joule heating created by the electric current decreases the performance of the device in Seebeck power generation mode since it reduces the temperature differential that can be obtained between the hot and cold junctions of a thermoelectric device. The greater the temperature differential, the greater the electrical power that can be generated thermoelectrically. Joule heating can reduce the potential electrical power that can be generated by a thermoelectric device operating in Seebeck mode. Similar to Peltier heating and cooling modes, reducing the internal or effective electrical resistance of a thermal leg and the effective electrical resistance of thermoelectric device improves the overall efficiency of the thermoelectric device.

A first set of Seebeck power generation embodiments will be described. A thermoelectric device embodiment with thermal energy flowing therethrough comprises at least a first conductive material, a first semiconductive material, a second conductive material, and a third conductive material. As before, the device may optionally further comprise a second semiconductive material and at least a fourth conductive material. The first semiconductive material can be disposed adjacent to and contacting the first conductive material. Further, the second conductive material could be disposed adjacent to, contacting, or operably connected to the first semiconductive material. The third conductive material can be disposed adjacent to and contacting at least one of the first semiconductive material and the second semiconductive material. In addition, an optional second semiconductive material may be disposed adjacent to and contacting the third conductive material. Further, the fourth conductive material could be disposed adjacent to, contacting, or operably connected to the second semiconductive material. Optionally, a fifth conductive material might be disposed adjacent to and contacting the second semiconductive material. One of the first conductive material and the third conductive material could contain more thermal energy than the other of the first conductive material and the third conductive material. As such, thermal energy could flow from the hotter of the first and third conductive materials to the cooler of the first and third conductive materials. The effective electrical resistance between the first conductive material and the third conductive materials can be controllably reduced below the effective series electrical resistances of the first semiconductive material and optionally the second semiconductive material by design as thermal energy flows through the second conductive material. Further, the associated Joule heating may be reduced between the first conductive material and the third conductive material as thermal energy flows therebetween. Reducing Joule heating reduces the interference with the thermal energy flowing between the hot and cold junctions which can help improve thermoelectric operation. Yet further, the Peltier cooling and Peltier heating may counteract each other by design within the second conductive material as thermal energy flows therethrough. As such, electrical energy may be generated between the first conductive material and the third conductive material by the Seebeck effect due to the temperature differential between the first conductive material and the third conductive material as thermal energy flows therebetween. The direction of electrical current flow generated depends on the direction of thermal energy flow between the first conductive material and the third conductive material. Means for function embodiments related to the above are also provided.

Another set of Seebeck power generation embodiments is also provided by the present invention. These Seebeck embodiments comprise a thermoelectric device with thermal energy flowing therethrough. The thermoelectric device includes at least a first thermoelectric element and a second thermoelectric element. Further, the each thermoelectric element itself includes at least a first conductive material, a first semiconductive material, a second conductive material, and a third conductive material. As before, the device may optionally further comprise a second semiconductive material and at least a fourth conductive material. The first semiconductive material can be disposed adjacent to and contacting the first conductive material. Further, the second conductive material could be disposed adjacent to, contacting, or operably connected to the first semiconductive material. The third conductive material can be disposed adjacent to and contacting at least one of the first semiconductive material and the second semiconductive material. In addition, an optional second semiconductive material may be disposed adjacent to and contacting the third conductive material. Further, the fourth conductive material could be disposed adjacent to, contacting, or operably connected to the second semiconductive material.

Optionally, a fifth conductive material might be disposed adjacent to and contacting the second semiconductive material. One of the first conductive material and the third conductive material could contain more thermal energy than the other of the first conductive material and the third conductive material. The third conductive material of the first thermoelectric element and the first conductive material of the second thermoelectric element can be in electrical contact such that thermal energy flows therebetween. In addition, the effective electrical resistance between the first conductive material and the third conductive material of each thermoelectric element can be controllably reduced below the effective series electrical resistances of the respective first semiconductive material and the second semiconductive material by design as thermal energy flows through the respective third conductive materials. Thus, the associated Joule heating of each thermoelectric element may be reduced between the first conductive material and the third conductive material as thermal energy flows therebetween. Similarly, the Peltier cooling and Peltier heating may counteract each other within the second conductive materials of each thermoelectric element as thermal energy flows therethrough. As such, electrical energy can be generated between the first conductive material and the third conductive material of each thermoelectric element due to a thermal temperature differential therebetween as thermal energy flows through each thermoelectric element and between the first thermoelectric element and the second thermoelectric element. As before, means for function embodiments related to the above are also provided. The large number of other Peltier mode thermoelectric device embodiments described herein above can also be used as Seebeck power generation mode embodiments.

Example Manufacturing Process Steps for Some Thermoelectric Device Embodiments

Embodiments of the present invention can be created using manufacturing methods suitable for CMOS or integrates circuit fabrication. However, other manufacturing technologies and methods, including MEMS processes, self assembly, assisted assembly, assisted self assembly, or the like can also be used to create thermoelectric device embodiments.

Those skilled in the art are referred to Table 4 which describes example manufacturing process steps for some thermoelectric device embodiments according to the present invention:

TABLE 4
Sample Manufacturing Process Steps*

| | |
|---|---|
| 1. | Starting wafer SOI, n-type, silicon thickness = 2μ, resistivity = |
| | 10-15 Ω-cm |
| 2. | RCA clean |
| 3. | Oxidation (20 nm) |
| 4. | Spin photoresist |
| 5. | Photolithography (define legs) |
| 6. | Wet etch oxide in 10:1 BOE |
| 7. | Reactive ion etch silicon down to SiO₂ |
| 8. | Strip photoresist |
| 9. | Strip oxide |
| 10. | RCA clean |
| 11. | Oxidation (20 nm) |
| 12. | Spin photoresist |
| 13. | Photolithography (define n+ regions) |
| 14. | Ion implant phosphorous (Dose 1E16 cm⁻², energy = 200 keV) |
| 15. | Strip photoresist |
| 16. | Spin photoresist |
| 17. | Photolithography (define p+ regions) |
| 18. | Ion implant BF₂ (Dose 1E16 cm⁻², energy = 200 keV) |
| 19. | Strip photoresist |
| 20. | RCA clean |
| 21. | Furnace anneal (drive in dopants) |
| 22. | Wet etch oxide |
| 23. | Back door etch |
| 24. | Deposit aluminum (at least 1 μm . . . the thicker the better) |
| 25. | Spin photoresist |
| 26. | Photolithography (define metal) |
| 27. | Etch aluminum |
| 28. | Strip photoresist |
| 29. | Forming gas anneal |

*Example manufacturing process for an alternating n-type and p-type thermoelectric device embodiment including aluminum resistance reducers, SOI substrate, with p+ and n+ doped semiconductive regions.

For the example process above, we start with a suitable substrate. For instance, here we select an SOI wafer, n-type semiconductor, having the thickness and resistivity shown in the Table above. Next, we could use the RCA process or some other suitable cleaning process for cleaning the n-type SOI wafer. The wafer could then be processed to grow an oxide thickness as desired, for example 20 nanometers here. Wet, dry or other known silicon oxidation processes could be used. Subsequently, we could spin coat photoresist onto the n-type SOI wafer, again using known processes and photoresist materials. Then we could use a photolithographic or other lithographic process to define the thermal legs of a thermoelectric device. We may then wet etch the oxide layer, such as in a 10:1 BOE (Buffered Oxide Etch) or another suitable wet etch process. Reactive ion etching or the like could be used to etch silicon down to SiO₂. Then we could strip off the photoresist and strip off the oxide using conventional processes. This may be followed by another RCA cleaning or some other suitable cleaning process. Next, the wafer could again be processed to grow an oxide of a given thickness, say for example 20 nanometers here. After, we could again spin coat photoresist onto the n-type SOI wafer, as before using known processes and photoresist materials. We could then use a photolithographic or other lithographic process to define the n+ regions of a thermoelectric device. In addition, we could use existing tools and processes to ion implant phosphorous into the wafer, for example using a dose of 1E16 cm-2 at an energy of approximately 200 keV or thereabouts. Next, we would again strip off the photoresist as described.

Thereafter, we could again spin coat photoresist onto the n-type SOI wafer, as before using known processes and photoresist materials. We could then use a photolithographic or other lithographic process to define the p+ regions of a thermoelectric device. Further, we could use existing tools and processes to ion implant BF₂ into the wafer, for example by using a dose of 1E16 cm-2 at an energy of approximately 200 keV or thereabouts. Afterwards, we could strip off the photoresist and use an RCA cleaning or other suitable cleaning process on the wafer as previously described. Next, we could use a suitable annealing process, such as furnace annealing or the like, to drive in the applied dopants. We could then wet etch the oxide and back door etch the wafer. Also, we could then deposit aluminum to some thickness of at least 1 μm on the wafer. Of course, the thicker the aluminum the better since it would help lower the resistances of the conductive areas which help improve thermoelectric performance. Afterwards, we could spin on photoresist and use photolithography or some other lithographic process to define the metal or conductive material areas, both as per above. Then we could etch the aluminum and strip off the photoresist. Finally, we could use forming gas or some other annealing process for the annealing the aluminum. Of course, other processes and other process steps may be used in place or in addition to the above for building thermoelectric devices.

More discussion of an example thermoelectric device manufacturing process follows. The semiconductor wafer selected for the device can be either n-type or p-type. A number of p-n-p isolations as well as oxide isolation areas may be used to route the electrical current within a thermal leg and between legs by design as desired. For some embodiments, the device manufacturing process starts by selecting a p-type semiconductor wafer. In some other embodiments, the device manufacturing process starts by selecting an n-type semiconductor wafer. The resistivity of the n-layer can be as high as practical to provide relatively high electrical resistance for the thermal legs created on the wafer. In addition, p-type material may be implanted to serve as the first level of isolation. The p-type layer may be as thick as possible to allow building legs that are as deep as possible and have a relatively lower electrical resistance. Isolation trenches may be built to isolate thermal legs from each other electrically and isolate areas within a thermal leg where alternating p-type doping and n-type doping may be implanted. These trenches can be filled with a material having a relatively high resistivity such as an oxide or a nitride. Each thermal leg may then be doped as needed, depending on the structure being built within the legs, such as conductive areas and semiconductive areas. In particular, the Seebeck coefficient of silicon decreases as the doping level increases. Similarly, the electrical resistivity of silicon decreases as the doping level increases. This can be used to reduce the electrical resistance of the silicon in doped areas. Additionally, the contact resistance between conductive material areas and silicon or semiconductive material regions may be reduced as needed. In some cases, the contact resistance between the conductive materials and semiconductive materials may be reduced as much as possible.

In some thermoelectric devices embodiments, by design we may seek to minimize the contact resistance, optimize the Seebeck coefficient, reduce the effective electrical resistance, or combinations thereof. It may be possible to reduce the contact resistance by doping the silicon or semiconductive regions that contact the metal or conductive material regions to the highest doping concentration possible, thereby reducing the effective electrical resistance of contacts. The high doping concentration region can be implanted as thin as possible whereas the rest of the silicon or semiconductive region may be doped with a lower doping concentration. This may be determined by optimizing the Seebeck coefficient and the effective electrical resistance of silicon. A challenge arises when two thermal legs are connected to each other via metal or conductive areas. The interconnection areas of the thermal legs require high metal connectivity since we seek to minimize the electrical resistance. At times given the structure of some thermoelectric device embodiments, one edge of this metal or conductive region may contact p-type semiconductor material whereas the other edge may contact n-type semiconductor material. Due to the implanting and annealing processes that may be required to develop these regions, the processing should be done carefully seeking to prevent parts of thermal legs from being both p-doped and n-doped such that parts of a thermal leg may undesirably function as a p-n diode. If isolation trenches are used trying to address this problem, or if top metal connectivity is used to address this problem, the resistance of the electrical connections between thermal legs can increase, thereby negatively affecting the performance of the thermal leg and the thermoelectric device.

Note that thermoelectric device embodiments or their components can also be manufactured using this process or many other known semiconductor manufacturing processes. For example, MEMS or a variety of other types of manufacturing processes used to create circuits, devices, and/or electromechanical systems can be used herein. Thermoelectric device embodiments or their components can optionally thereafter be constructed or assembled into stand alone thermoelectric devices and higher level assemblies such as thermoelectric coolers, thermoelectric heaters, and thermoelectric power generators. Further, thermoelectric device embodiments or their components conventional semiconductor, materials, tools, and technologies. Other embodiments of thermoelectric devices or their components can be made from components made by semiconductor manufacturing processes that are thereafter assembled into higher level thermoelectric devices. Further embodiments of thermoelectric devices or their components can also e made from novel materials, processes, tools, and technologies. For example, nanomaterials, nanomanufacturing processes, tools, and technologies can also be used.

Many modifications and other embodiments of the present invention will come to mind to one skilled in the art to which this invention pertains having the benefit of the teachings presented in the foregoing descriptions and the associated figures. Therefore, it is to be understood that the invention is not to be limited to the specific embodiments disclosed and that modifications and other embodiments are intended to be included within the scope of the appended claims. In addition, those skilled in the art will appreciate that various features and aspects of the above disclosed embodiments, whether preferred or not, may be combined to create a number of other related embodiments that are still within the scope of the present invention. As noted, the above written description of the present invention is meant to disclose and fully describe the present invention, and is not meant to limit or narrow the present invention defined by the following claims. Although specific terms are employed herein, they are used in a generic and descriptive sense only and not for purposes of limiting the scope of the present invention in any way.

What is claimed is:

1. A thermoelectric device with electrical current flowing therethrough, comprising;
a first thermoelectric element, including at least,
a first conductive material;
a first semiconductive material, disposed adjacent to and contacting the first conductive material at a first edge thereof;
a second conductive material, disposed within and contacting the first semiconductive material;
a third conductive material, disposed adjacent to and contacting the first semiconductive material at a second edge thereof;
a second thermoelectric element, including at least,
a first conductive material;
a first semiconductive material, disposed adjacent to and contacting the first conductive material at a first edge thereof;
a second conductive material, disposed within and contacting the first semiconductive material;
a third conductive material, disposed adjacent to and contacting the first semiconductive material at a second edge thereof;
wherein the third conductive material of the first thermoelectric element and the first conductive material of the second thermoelectric element are in electrical contact such that current flows therebetween;
wherein the effective electrical resistance between the first conductive material and the third conductive material of each thermoelectric element is controllably reduced below the effective series electrical resistances of the respective first semiconductive materials by design of the respective second conductive elements as electrical current flows from the respective first conductive materials and the respective third conductive materials;
wherein the associated Joule heating of each thermoelectric element is reduced between the first conductive material and the third conductive material as electrical current flows therebetween; and
wherein the Peltier cooling and Peltier heating counteract each other within the second conductive materials of each thermoelectric element as electrical current flows therethrough;
such that heat is exchanged between the first conductive material and the third conductive material of each thermoelectric element creating a temperature differential therebetween as electrical current flows through each thermoelectric element and between the first thermoelectric element and the second thermoelectric element.

2. The thermoelectric device of claim 1, wherein the first semiconductive material of one thermoelectric element can function as the first semiconductive material of another thermoelectric element.

3. The thermoelectric device of claim 1, wherein at least one of the first semiconductive materials of a thermoelectric element comprise semiconductive materials selected from the group consisting of a single semiconductive material area contacting the respective second conductive material, two semiconductive material areas of the same type each contacting the respective second conductive material, and two semiconductive material areas of different types each contacting the respective second conductive material.

4. The thermoelectric device of claim 1, wherein at least one of the first conductive material, the second conductive material, and the third conductive material of one thermoelectric element can function as the other of the first conductive material, the second conductive material, and the third conductive material for another thermoelectric element.

5. The thermoelectric device of claim 1, wherein at least at least one of the first semiconductive materials of the thermoelectric elements is doped selected from the group consisting of p-doping, n-doping, depletion, and no doping.

6. The thermoelectric device of claim 1, wherein the first semiconductive materials of the first thermoelectric element and the second thermoelectric element are similarly doped selected from the group consisting of p-doping, n-doping, depletion, and no doping.

7. The thermoelectric device of claim 1, wherein the first semiconductive materials of the first thermoelectric element and the second thermoelectric element are differently doped with at least two of p-doping, n-doping, depletion, and no doping.

8. The thermoelectric device of claim 1, wherein at least one of the first semiconductive materials of the thermoelectric elements comprises at least two separate semiconductive areas arranged in series with respect to the direction of the electrical current flowing between the respective first conductive material and the third conductive material.

9. The thermoelectric device of claim 1, wherein at least one of the first semiconductive materials of the thermoelectric elements comprises at least two separate semiconductive areas isolated electrically from each other and arranged in with parallel with respect to the direction of the electrical current flowing between the first conductive material and the third conductive material.

10. The thermoelectric device of claim 9, further comprising an insulator disposed between and electrically isolating the at least two separate semiconductive material as electrical current flows between the first conductive material and the third conductive material.

11. The thermoelectric device of claim 1, wherein at least one of the first semiconductive material of the first thermoelectric element and the first semiconductive material of the second thermoelectric element are made from material selected from the group consisting of nanotubes, carbon nanotubes, nanowires, silicon nanowires, nanomaterials, nanostructures, Bismuth, Boron, Silicon, Silicon On Insulator, Germanium, Arsenic, Antimony, Tellurium, Polonium, Silicon-Germanium, Bi₂Te₃, and superlattice materials.

12. The thermoelectric device of claim 1, wherein at least one of the first conductive material of the first thermoelectric element, the first conductive material of the second thermoelectric element, the second conductive material of the first thermoelectric element, the second conductive material of the second thermoelectric element, the third conductive material of the first thermoelectric element, and the third conductive material of the second thermoelectric element are made from materials selected from the group consisting of nanotubes, carbon nanotubes, nanowires, silicon nanowires, nanomaterials, nanostructures, flexible conductive materials, conductive plastics, conductive polymers, superlattice materials, Aluminum, Copper, Tin, Palladium, Gold, Silver, Titanium, Tungsten, Iron, Cobalt, Nickel, Zinc, Molybdenum, Cadmium, Mercury, Hafnium, Tantalum, Gallium, Indium, Thallium, Lead, Bismuth, and alloys thereof.

13. The thermoelectric device of claim 1, wherein the third conductive material of the first thermoelectric element and the first conductive material of the second thermoelectric element are constructed as from the group consisting of one single conductive material area interconnecting the first and second thermoelectric elements and two separate but electrically interconnected conductive material areas interconnecting the first and second thermoelectric elements.

14. The thermoelectric device of claim 1, wherein the intervening materials between the first conductive material and the third conductive material of at least one of the first thermoelectric element and the second thermoelectric element of the thermoelectric device increase thermal isolation between the conductive materials while reducing the associated Joule heating as electrical current flows therebetween.

15. The thermoelectric device of claim 1, wherein the electrical current path between the first conductive material and the third conductive material of at least one of the first thermoelectric element and the second thermoelectric element of the thermoelectric device is separated from the thermal conduction path between the first conductive material and the third conductive material of at least one of the first thermoelectric element and the second thermoelectric element by the intervening materials between the conductive materials.

16. The thermoelectric device of claim 1, wherein for at least one of the first thermoelectric element and the second thermoelectric element, an edge of the first conductive material opposite to the respective first semiconductive material runs along a first horizontal axis, wherein an edge of the third conductive material opposite to the respective first semiconductive material runs along a second horizontal axis, and wherein the first horizontal axis and second horizontal axes are substantially parallel.

17. The thermoelectric device of claim 16, wherein for at least one of the first thermoelectric element and the second thermoelectric element the respective first semiconductive material is disposed parallel to a third axis having an angular relationship with the first and second horizontal axes selected from the group consisting of a substantially parallel relationship with the first and second horizontal axes, a substantially perpendicular relationship with the first and second horizontal axes, an obtuse angular relationship with the first and second horizontal axes, and an acute angular relationship with the first and second horizontal axes.

18. The thermoelectric device of claim 1, wherein at least one of the first thermoelectric element and the second thermoelectric element of the thermoelectric device further comprises;
a second semiconductive material, disposed adjacent to and contacting the third conductive material at a first edge thereof;
a fourth conductive material, disposed within and contacting the second semiconductive material;
a fifth conductive material, disposed adjacent to and contacting the second semiconductive material at a second edge thereof;
wherein the effective electrical resistance between the third conductive material and the fifth conductive material of the respective thermoelectric element is controllably reduced below the effective series electrical resistance of the second semiconductive material by design of the fourth conductive material as electrical current flows from the third conductive material to the fifth conductive material; and
wherein the Peltier cooling and Peltier heating counteract each other within the fourth conductive material as electrical current flows therethrough;
such that heat is exchanged between the third conductive material and the fifth conductive material creating a temperature differential therebetween as electrical current flows therebetween.

19. The thermoelectric device of claim 18, wherein at least one of the first semiconductive materials and second semiconductive materials comprise semiconductive materials selected from the group consisting of a single semiconductive material area contacting the respective second conductive material, two semiconductive material areas of the same type each contacting the respective second conductive material, and two semiconductive material areas of different types each contacting the respective second conductive material.

20. The thermoelectric device of claim 18, wherein the first semiconductive material and the second semiconductive material of at least one of the first thermoelectric element and the second thermoelectric element of the thermoelectric device are similarly doped with one of p-doping, n-doping, depletion, and no doping.

21. The thermoelectric device of claim 18, wherein at least one first semiconductive material of a thermoelectric element and at least one second semiconductive material of a thermoelectric element are differently doped with at least two of p-doping, n-doping, depletion, and no doping.

22. The thermoelectric device of claim 18, wherein for at least one of the first thermoelectric element and the second thermoelectric element, an edge of the third conductive material opposite to the respective second semiconductive material runs along a first horizontal axis, wherein an edge of the fifth conductive material opposite to the respective second semiconductive material runs along a second horizontal axis, and wherein the first horizontal axis and second horizontal axes are substantially parallel.

23. The thermoelectric device of claim 22, wherein for at least one of the first thermoelectric element and the second thermoelectric element the respective second semiconductive material is disposed parallel to a third axis having an angular relationship with the first and second horizontal axes selected from the group consisting of a substantially parallel relationship with the first and second horizontal axes, a substantially perpendicular relationship with the first and second horizontal axes, an obtuse angular relationship with the first and second horizontal axes, and an acute angular relationship with the first and second horizontal axes.

24. A thermoelectric device with electrical current flowing therethrough, comprising;
a first conductive material;
a first semiconductive material, disposed adjacent to and contacting the first conductive material at a first edge thereof;
a second conductive material, disposed within and contacting the first semiconductive material;
a third conductive material, disposed adjacent to and contacting the first semiconductive material at a second edge thereof;
wherein the effective electrical resistance between the first conductive material and the third conductive materials is controllably reduced below the effective series electrical resistance of the first semiconductive material by design of the second conductive material as electrical current flows from the first conductive material to the third conductive material;
wherein the associated Joule heating is reduced between the first conductive material and the third conductive material as electrical current flows therebetween; and
wherein the Peltier cooling and Peltier heating counteract each other within the second conductive material as electrical current flows therethrough;
such that heat is exchanged between the first conductive material and the third conductive material creating a temperature differential between the first conductive material and the third conductive material as electrical current flows therebetween.

25. The thermoelectric device of claim 24, wherein the first semiconductive material comprises a semiconductive material selected from the group consisting of a single semiconductive material area contacting the respective second conductive material, two semiconductive material areas of the same type each contacting the respective second conductive material, and two semiconductive material areas of different types each contacting the respective second conductive material.

26. The thermoelectric device of claim 24, wherein the first semiconductive material is doped selected from the group consisting of p-doping, n-doping, depletion, and no doping.

27. The thermoelectric device of claim 24, wherein the first semiconductive material is made from material selected from the group consisting of nanotubes, carbon nanotubes, nanowires, silicon nanowires, nanomaterials, nanostructures, Bismuth, Boron, Silicon, Silicon On Insulator, Germanium, Arsenic, Antimony, Tellurium, Polonium, Silicon-Germanium, Bi₂Te₃, and superlattice materials.

28. The thermoelectric device of claim 24, wherein at least one of the first conductive material, the second conductive material, and the third conductive material are made from materials selected from the group consisting of nanotubes, carbon nanotubes, nanowires, silicon nanowires, nanomaterials, nanostructures, flexible conductive materials, conductive plastics, conductive polymers, superlattice materials, Aluminum, Copper, Tin, Palladium, Gold, Silver, Titanium, Tungsten, Iron, Cobalt, Nickel, Zinc, Molybdenum, Cadmium, Mercury, Hafnium, Tantalum, Gallium, Indium, Thallium, Lead, Bismuth, and alloys thereof.

29. The thermoelectric device of claim 24, wherein the first semiconductive material comprises at least two separate semiconductive areas arranged in series with respect to the direction of the electrical current flowing between the first conductive material and the third conductive material.

30. The thermoelectric device of claim 24, wherein the first semiconductive material comprises at least two separate semiconductive areas isolated electrically from each other and arranged in parallel with respect to the direction of the electrical current flowing between the first conductive material and the third conductive material.

31. The thermoelectric device of claim 30, further comprising an insulator disposed between and electrically isolating the at least two separate semiconductive areas within the first semiconductive material as electrical current flows between the first conductive material and the third conductive material.

32. The thermoelectric device of claim 24, wherein the intervening materials between the first conductive material and the third conductive material increase thermal isolation therebetween while reducing the associated Joule heating as electrical current flows between the conductive materials.

33. The thermoelectric device of claim 24, wherein the electrical current path between the first conductive material and the third conductive material is separated from the thermal conduction path between the first conductive material and the third conductive material by the intervening materials between the conductive materials.

34. The thermoelectric device of claim 24, wherein an edge of the first conductive material opposite to the first semiconductive material runs along a first horizontal axis, wherein an edge of the third conductive material opposite to the first semiconductive material runs along a second horizontal axis, and wherein the first horizontal axis and second horizontal axes are substantially parallel.

35. The thermoelectric device of claim 34, wherein the first semiconductive material is disposed parallel to a third axis having an angular relationship with the first and second horizontal axes selected from the group consisting of a substantially parallel relationship with the first and second horizontal axes, a substantially perpendicular relationship with the first and second horizontal axes, an obtuse angular relationship with the first and second horizontal axes, and an acute angular relationship with the first and second horizontal axes.

36. The thermoelectric device of claim 24, wherein the thermoelectric device further comprises;
a second semiconductive material, disposed adjacent to and contacting the third conductive material at a first edge thereof;
a fourth conductive material, disposed within and contacting the second semiconductive material;
a fifth conductive material, disposed adjacent to and contacting the second semiconductive material at a second edge thereof;
wherein the effective electrical resistance between the third conductive material and the fifth conductive materials is controllably reduced below the effective series electrical resistance of the second semiconductive material by design of the fourth conductive material as electrical current flows from the third conductive material to the fifth conductive material; and
wherein the Peltier cooling and Peltier heating counteract each other within the fourth conductive material as electrical current flows therethrough;
such that heat is exchanged between the third conductive material and the fifth conductive material creating a temperature differential therebetween as electrical current flows therebetween.

37. The thermoelectric device of claim 36, wherein one at least of the first semiconductive material and the second semiconductive material comprise semiconductive materials selected from the group consisting of a single semiconductive material area contacting the respective second conductive material, two semiconductive material areas of the same type each contacting the respective second conductive material, and two semiconductive material areas of different types each contacting the respective second conductive material.

38. The thermoelectric device of claim 36, wherein at least one of the first semiconductive material and second semiconductive material are doped selected from the group consisting of p-doping, n-doping, depletion, and no doping.

39. The thermoelectric device of claim 36, wherein the first semiconductive material and the second semiconductive material are similarly doped selected from the group consisting of p-doping, n-doping, depletion, and no doping.

40. The thermoelectric device of claim 36, wherein the first semiconductive materials and the second semiconductive material are differently doped with at least two of p-doping, n-doping, depletion, and no doping.

41. The thermoelectric device of claim 36, wherein at least one of the first semiconductive material and the second semiconductive material are made from materials selected from the group consisting of nanotubes, carbon nanotubes, nanowires, silicon nanowires, nanomaterials, nanostructures, Bismuth, Boron, Silicon, Silicon On Insulator, Germanium, Arsenic, Antimony, Tellurium, Polonium, Silicon-Germanium, Bi₂Te₃, and superlattice materials.

42. The thermoelectric device of claim 36, wherein an edge of the third conductive material opposite to the second semiconductive material runs along a first horizontal axis, wherein an edge of the fifth conductive material opposite to the second semiconductive material runs along a second horizontal axis, and wherein the first horizontal axis and second horizontal axes are substantially parallel.

43. The thermoelectric device of claim 42, wherein the second conductive material is disposed parallel to a third axis having an angular relationship with the first and second horizontal axes selected from the group consisting of a substantially parallel relationship with the first and second horizontal axes, a substantially perpendicular relationship with the first and second horizontal axes, an obtuse angular relationship with the first and second horizontal axes, and an acute angular relationship with the first and second horizontal axes.

44. A thermoelectric device with electrical current flowing therethrough, comprising;
first means for conducting electricity;
first means for semiconducting electricity, operably connected to the first means for conducting electricity at a first edge thereof;
second means for conducting electricity, operably connected to the first means for semiconducting electricity;
third means for conducting electricity, operably connected to the first means for semiconducting electricity at a second edge thereof;
means for controllably reducing the effective electrical resistance between the first means for conducting electricity and the third means for conducting electricity below the effective series resistances of the first means for semiconducting electricity by design of the second means for conducting electricity as electrical current flows therethrough, and
means for controllably counteracting the Peltier heating by the Peltier cooling as electrical current flows through the means for controllably reducing the effective electrical resistance.

45. A thermoelectric device with electrical current flowing therethrough, comprising;
a first thermoelectric element, including at least,
first means for conducting electricity;
first means for semiconducting electricity, operably connected to the first means for conducting electricity at a first edge thereof;
second means for conducting electricity, operably connected to the first means for semiconducting electricity;
third means for conducting electricity, operably connected to the first means for semiconducting electricity at a second edge thereof;
a second thermoelectric element, including at least,
first means for conducting electricity;
first means for semiconducting electricity, operably connected to the first means for conducting electricity at a first edge thereof;
second means for conducting electricity, disposed within and operably connected to the first means for semiconducting electricity;
third means for conducting electricity, operably connected to the first means for semiconducting electricity at a second edge thereof;
means for controllably reducing the effective electrical resistance between the first means for conducting electricity and the third means for conducting electricity of at least one thermoelectric element below the effective series resistances of the first means for semiconducting electricity by design of the second means for conducting electricity as electrical current flows therethrough, and
means for controllably counteracting the Peltier heating by the Peltier cooling as electrical current flows through the means for controllably reducing the effective electrical resistance.
